(19) United States
(12) Patent Application Publication
(10) Pub. No.: US 2024/0179946 A1
(43) Pub. Date: May 30, 2024

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Takayuki IKEDA, Atsugi (JP); Tatsuya ONUKI, Atsugi (JP)

(21) Appl. No.: 18/274,036

(22) PCT Filed: Jan. 25, 2022
(86) PCT No.: PCT/IB2022/050612

§ 371 Date: Jul. 25, 2023

(30) Foreign Application Priority Data
Feb. 5, 2021 (JP) 2021-017187
Feb. 18, 2021 (JP) 2021-024487
Feb. 19, 2021 (JP) 2021-025502

(51) Int. Cl. H10K 59/121; H10K 50/19

(52) U.S. Cl. CPC H10K 59/1213; H10K 50/19

(57) ABSTRACT

A novel semiconductor device is provided. The semiconductor device includes a first layer; a second layer over the first layer; and a third layer over the second layer. The first layer includes a functional circuit including a first transistor, the second layer includes a plurality of pixel circuits each including a second transistor, the third layer includes a plurality of light-emitting elements, one of the plurality of pixel circuits is electrically connected to one of the plurality of light-emitting elements, the functional circuit has a function of controlling an operation of the pixel circuit, and the pixel circuit has a function of controlling emission luminance of the light-emitting element.

### TECHNICAL FIELD

One embodiment of the present invention relates to a semiconductor device.

Note that one embodiment of the present invention is not limited to the above technical field. Examples of the technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof.

### BACKGROUND ART

In recent years, higher resolution of display apparatuses have been desired. For example, devices for virtual reality (VR), augmented reality (AR), substitutional reality (SR), or mixed reality (MR) are given as devices requiring high-resolution display apparatuses and have been actively developed in recent years. Display apparatuses used for these devices are required to be downsized as well as to have higher resolutions.

VR, AR, SR, and MR are collectively referred to as xR. Examples of a display apparatus for xR include a liquid crystal display apparatus and a light-emitting device including a light-emitting element such as an organic EL (Electro Luminescence) element or a light-emitting diode (LED).

For example, the basic structure of an organic EL element is a structure in which a layer containing a light-emitting organic compound is provided between a pair of electrodes. By applying a voltage to this element, light emission can be obtained from the light-emitting organic compound. A display apparatus using such an organic EL element does not need a backlight that is necessary for a liquid crystal display apparatus and the like; thus, a thin, lightweight, high-contrast, and low-power display apparatus can be achieved. Patent Document 1, for example, discloses an example of a display apparatus using an organic EL element.

### REFERENCE

### Patent Document

[Patent Document 1] Japanese Published Patent Application No. 2002-324673

### SUMMARY OF THE INVENTION

### Problems to be Solved by the Invention

For display apparatuses for xR, reduction in size, low power consumption, and multifunction are required.

An object of one embodiment of the present invention is to provide a downsized display apparatus. An object of one embodiment of the present invention is to provide a display apparatus which can achieve high color reproducibility. An object of one embodiment of the present invention is to provide a high-resolution display apparatus. An object of one embodiment of the present invention is to provide a display apparatus with high emission luminance. An object of one embodiment of the present invention is to provide a highly reliable display apparatus. An object of one embodiment of the present invention is to provide a novel display apparatus.

Note that the description of these objects does not preclude the existence of other objects. One embodiment of the present invention does not have to achieve all these objects. Objects other than these can be derived from the description of the specification, the drawings, the claims, and the like.

### Means for Solving the Problems

(1) One embodiment of the present invention is a semiconductor device including a first layer; a second layer over the first layer; and a third layer over the second layer, in which the first layer includes a functional circuit including a first transistor, the second layer includes a plurality of pixel circuits each including a second transistor, the third layer includes a plurality of light-emitting elements, one of the plurality of pixel circuits is electrically connected to one of the plurality of light-emitting elements, the functional circuit has a function of controlling an operation of the pixel circuit, and the pixel circuit has a function of controlling emission luminance of the light-emitting element.

In (1), Si transistors may be used as the first transistor and the second transistor. The first layer and the second layer may include regions that are connected to each other by Cu—Cu bonding.

In (1), an OS transistor may be used as the second transistor.

(2) Another embodiment of the present invention is a semiconductor device including a first layer; a second layer over the first layer; and a first member over the second layer. The first layer includes a functional circuit, the second layer includes a display portion including a plurality of pixels and a plurality of storage units, each of the plurality of pixels includes a pixel circuit and a light-emitting element over the pixel circuit, the plurality of storage units are arranged along at least part of the outer periphery of the display portion, and the display portion and the plurality of storage units are covered with the first member. In (2), the storage unit is preferably arranged in a sealing region. In (2), the third layer may have a light-transmitting property.

(3) One embodiment of the present invention is a semiconductor device including a first layer; a second layer over the first layer; and a third layer over the second layer. The first layer includes a storage unit including a plurality of memory cells, the second layer includes a functional circuit, the third layer includes a display portion including a plurality of pixels, the functional circuit includes a storage unit driver circuit and a display portion driver circuit, and each of the plurality of pixels includes a pixel circuit and a light-emitting element over the pixel circuit.

In (3), the memory cell includes a first transistor, the functional circuit includes a second transistor, the pixel circuit includes a third transistor. For example, a composition of a first semiconductor layer included in the first transistor and a composition of a second semiconductor layer included in the second transistor may be different from a composition of a third semiconductor layer included in the third transistor.

The above storage unit may include a DRAM. The light-emitting element may be an organic EL element. The light-emitting element may include a tandem structure. The diagonal size of the region the plurality of pixel circuits and the plurality of light-emitting elements is preferably greater than or equal to 0.5 inches and less than or equal to 2.0 inches. In other words, the diagonal size of the display portion is preferably greater than or equal to 0.5 inches and less than or equal to 2.0 inches.

The above functional circuit may include at least one of a CPU, a GPU, a super-resolution circuit, a sensor circuit, a communication circuit, and an input/output circuit. The first member may have a light-transmitting property.

### Effect of the Invention

According to one embodiment of the present invention, a downsized display apparatus can be provided. Alternatively, a display apparatus which can achieve high color reproducibility can be provided. Alternatively, a high-resolution display apparatus can be provided. Alternatively, a display apparatus with high emission intensity can be provided. Alternatively, a highly reliable display apparatus can be provided. Alternatively, a novel display apparatus can be provided.

Note that the description of these effects does not preclude the existence of other effects. Note that one embodiment of the present invention does not need to have all the effects. Effects other than these can be derived from the description of the specification, the drawings, the claims, and the like.

### BRIEF DESCRIPTION OF THE DRAWINGS

FIG. 1A is a perspective view illustrating a structure example of a semiconductor device. FIG. 1B is a block diagram of the semiconductor device.

FIG. 2 is a perspective view illustrating a structure example of a semiconductor device.

FIG. 3 is a block diagram illustrating a structure example of a display portion driver circuit.

FIG. 4A and FIG. 4B1 to FIG. 4B6 are diagrams illustrating structure examples of a display portion.

FIG. 5A and FIG. 5B are diagrams illustrating a structure example of a semiconductor device.

FIG. 6A and FIG. 6B are diagrams illustrating structure examples of a semiconductor device.

FIG. 7 is a perspective view illustrating a structure example of a semiconductor device.

FIG. 8A and FIG. 8B are perspective views illustrating a structure example of a semiconductor device.

FIG. 9A and FIG. 9B are perspective views illustrating a structure example of a semiconductor device.

FIG. 10A and FIG. 10B are perspective views illustrating a structure example of a semiconductor device.

FIG. 11A and FIG. 11B are perspective views illustrating a structure example of a semiconductor device.

FIG. 12A and FIG. 12B are perspective views illustrating a structure example of a semiconductor device.

FIG. 13A and FIG. 13B are perspective views illustrating a structure example of a semiconductor device.

FIG. 14A and FIG. 14B are perspective views illustrating a structure example of a semiconductor device.

FIG. 15A and FIG. 15B are diagrams illustrating a structure example of a semiconductor device.

FIG. 16A and FIG. 16B are diagrams illustrating a structure example of a semiconductor device.

FIG. 17A to FIG. 17C are diagrams illustrating an operation example of a semiconductor device.

FIG. 18 is a cross-sectional view illustrating a structure example of a semiconductor device.

FIG. 19 is a cross-sectional view illustrating a structure example of a semiconductor device.

FIG. 20 is a cross-sectional view illustrating a structure example of a semiconductor device.

FIG. 21 is a cross-sectional view illustrating a structure example of a semiconductor device.

FIG. 22 is a cross-sectional view illustrating a structure example of a semiconductor device.

FIG. 23 is a cross-sectional view illustrating a structure example of a semiconductor device.

FIG. 24 is a cross-sectional view illustrating a structure example of a semiconductor device.

FIG. 25 is a cross-sectional view illustrating a structure example of a semiconductor device.

FIG. 26 is a cross-sectional view illustrating a structure example of a semiconductor device.

FIG. 27 is a cross-sectional view illustrating a structure example of a semiconductor device.

FIG. 28 is a cross-sectional view illustrating a structure example of a semiconductor device.

FIG. 29A to FIG. 29D are diagrams illustrating structure examples of a light-emitting element.

FIG. 30A to FIG. 30D are diagrams illustrating structure examples of a display apparatus.

FIG. 31A to FIG. 31D are diagrams illustrating a structure example of a display apparatus.

FIG. 32A is a top view illustrating a structure example of a transistor. FIG. 32B and FIG. 32C are cross-sectional views illustrating the structure example of the transistor.

FIG. 33A is a diagram showing the classification of crystal structures. FIG. 33B is a graph showing an XRD spectrum of a CAAC-IGZO film. FIG. 33C is an image showing nanobeam electron diffraction patterns of a CAAC-IGZO film.

FIG. 34A to FIG. 34E are diagrams illustrating examples of electronic devices.

### MODE FOR CARRYING OUT THE INVENTION

Hereinafter, embodiments will be described with reference to the drawings. Note that the embodiments can be implemented in many different modes, and it is readily understood by those skilled in the art that modes and details thereof can be changed in various ways without departing from the spirit and scope thereof. Thus, the present invention should not be interpreted as being limited to the following description of the embodiments.

In this specification and the like, a semiconductor device refers to a device that utilizes semiconductor characteristics, and means a circuit including a semiconductor element (e.g., a transistor, a diode, or a photodiode), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display apparatus, a light-emitting apparatus, a lighting device, an electronic device, and the like themselves may be semiconductor devices or may each include a semiconductor device.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch is controlled to be in an on state or an off state. That is, a switch has a function of controlling whether or not current flows by being in a conduction state (on state) or a non-conduction state (off state).

For example, in the case where X and Y are functionally connected, one or more circuits that allow functional connection between X and Y (e.g., a logic circuit (an inverter, a NAND circuit, a NOR circuit, or the like); a signal converter circuit (a digital-analog converter circuit, an analog-digital converter circuit, a gamma correction circuit, or the like); a potential level converter circuit (a power supply circuit (a step-up circuit, a step-down circuit, or the like), a level shifter circuit for changing the potential level of a signal, or the like); a voltage source; a current source; a switching circuit; an amplifier circuit (a circuit that can increase signal amplitude, the amount of current, or the like, an operational amplifier, a differential amplifier circuit, a source follower circuit, a buffer circuit, or the like); a signal generation circuit; a memory circuit; a control circuit; or the like) can be connected between X and Y. For instance, even if another circuit is interposed between X and Y, X and Y are regarded as being functionally connected when a signal output from X is transmitted to Y.

Note that an explicit description that X and Y are electrically connected includes the case where X and Y are electrically connected (i.e., the case where X and Y are connected with another element or another circuit interposed therebetween) and the case where X and Y are directly connected (i.e., the case where X and Y are connected without another element or another circuit interposed therebetween).

It can be expressed as, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order”. Alternatively, it can be expressed as “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in that order”. Alternatively, it can be expressed as “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided in this connection order”. When the connection order in a circuit configuration is defined by an expression similar to the above examples, a source (or a first terminal or the like) and a drain (or a second terminal or the like) of a transistor can be distinguished from each other to specify the technical scope. Note that these expressions are examples and the expression is not limited to these expressions. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has functions of both components: a function of the wiring and a function of the electrode. Thus, electrical connection in this specification includes, in its category, such a case where one conductive film has functions of a plurality of components.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. Therefore, in this specification and the like, a “capacitor” includes not only a circuit element that has a pair of electrodes and a dielectric between the electrodes, but also parasitic capacitance generated between wirings, gate capacitance generated between a gate and one of a source and a drain of a transistor, and the like. The terms “capacitor”, “parasitic capacitance”, “gate capacitance”, and the like can be replaced with the term “capacitance” and the like; conversely, the term “capacitance” can be replaced with the terms “capacitor”, “parasitic capacitance”, “gate capacitance”, and the like. The term “a pair of electrodes” of a “capacitor” can be replaced with “a pair of conductors”, “a pair of conductive regions”, “a pair of regions”, and the like. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain depending on the conductivity type (n-channel type or p-channel type) of the transistor and the levels of potentials applied to the three terminals of the transistor. Thus, the terms “source” and “drain” can be replaced with each other in this specification and the like. Furthermore, in this specification and the like, expressions “one of a source and a drain” (or a first electrode or a first terminal) and “the other of the source and the drain” (or a second electrode or a second terminal) are used in the description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate, for example, in this specification and the like.

In this specification and the like, a “node” can be referred to as a terminal, a wiring, an electrode, a conductive layer, a conductor, an impurity region, or the like depending on the circuit configuration, the device structure, or the like. Furthermore, a terminal, a wiring, or the like can be referred to as a “node.”

Ordinal numbers such as “first”, “second”, and “third” in this specification and the like are used to avoid confusion among components. Thus, the ordinal numbers do not limit the number of components. In addition, the ordinal numbers do not limit the order of components. For example, a “first” component in one embodiment in this specification and the like can be referred to as a “second” component in other embodiments, the scope of claims, or the like. Furthermore, for example, a “first” component in one embodiment in this specification and the like can be omitted in other embodiments, the scope of claims, or the like.

In this specification and the like, terms for describing arrangement, such as “over”, “under”, “above”, and “below” are sometimes used for convenience to describe the positional relation between components with reference to drawings. The positional relation between components is changed as appropriate in accordance with a direction in which each component is described. Thus, the positional relation is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°.

The term “over” or “under” does not necessarily mean that a component is placed directly over or directly under and directly in contact with another component. For example, the expression “electrode B over insulating layer A” does not necessarily mean that the electrode B is formed over and in direct contact with the insulating layer A, and does not exclude the case where another component is provided between the insulating layer A and the electrode B.

In this specification and the like, the terms “film”, “layer”, and the like can be interchanged with each other depending on the situation. For example, the term “conductive layer” can be changed into the term “conductive film” in some cases. As another example, the term “insulating film” can be changed into the term “insulating layer” in some cases. Alternatively, the term “film,” “layer,” or the like is not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In addition, in this specification and the like, the term such as “electrode,” “wiring,” or “terminal” does not limit the function of a component. For example, an “electrode” is used as part of a wiring in some cases, and vice versa. Furthermore, the term “electrode” or “wiring” also includes the case where a plurality of “electrodes” or “wirings” are formed in an integrated manner, for example. For example, a “terminal” is used as part of a “wiring” or an “electrode” in some cases, and vice versa. Furthermore, the term “terminal” also includes the case where a plurality of “electrodes”, “wirings”, “terminals”, or the like are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, “terminal”, or the like is sometimes replaced with the term “region”, for example.

In addition, in this specification and the like, the term such as “wiring,” “signal line,” or “power supply line” can be interchanged with each other depending on the case or the situation. For example, the term “wiring” can be changed into the term “signal line” in some cases. As another example, the term “wiring” can be changed into the term “power supply line” or the like in some cases. Conversely, the term such as “signal line” or “power supply line” can be changed into the term “wiring” in some cases. The term “power supply line” or the like can be changed into the term “signal line” or the like in some cases. Conversely, the term “signal line” or the like can be changed into the term “power supply line” or the like in some cases. Moreover, the term “potential” that is applied to a wiring can be sometimes changed into the term such as “signal” depending on the case or the situation. Conversely, the term “signal” or the like can be changed into the term “potential” in some cases.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

Embodiments described in this specification are described with reference to the drawings. Note that the embodiments can be implemented in many different modes, and it will be readily understood by those skilled in the art that the modes and details can be changed in various ways without departing from the spirit and scope thereof. Therefore, the present invention should not be interpreted as being limited to the description in the embodiments. Note that in the structures of the invention in the embodiments, the same reference numerals are used in common for the same portions or portions having similar functions in different drawings, and repeated description thereof is omitted in some cases. Moreover, some components are omitted in a perspective view, a top view, and the like for easy understanding of the diagrams in some cases.

In addition, in the drawings in this specification, the size, the layer thickness, or the region is exaggerated for clarity in some cases. Therefore, embodiments of the present invention are not limited to the size, aspect ratio, and the like illustrated in the drawings. Note that the drawings schematically illustrate ideal examples, and embodiments of the present invention are not limited to shapes, values, and the like illustrated in the drawings. For example, variation in signal, voltage, or current due to noise or variation in signal, voltage, or current due to difference in timing can be included.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

In this specification and the like, when a plurality of components are denoted by the same reference numerals, and in particular need to be distinguished from each other, an identification sign such as “A”, “b”, “_1”, “[n]”, or “[m,n]” are sometimes added to the reference numerals.

### Embodiment 1

A semiconductor device of one embodiment of the present invention will be described. Note that the semiconductor device of one embodiment of the present invention can function as a display apparatus.

### <Structure Example of Semiconductor Device 100A>

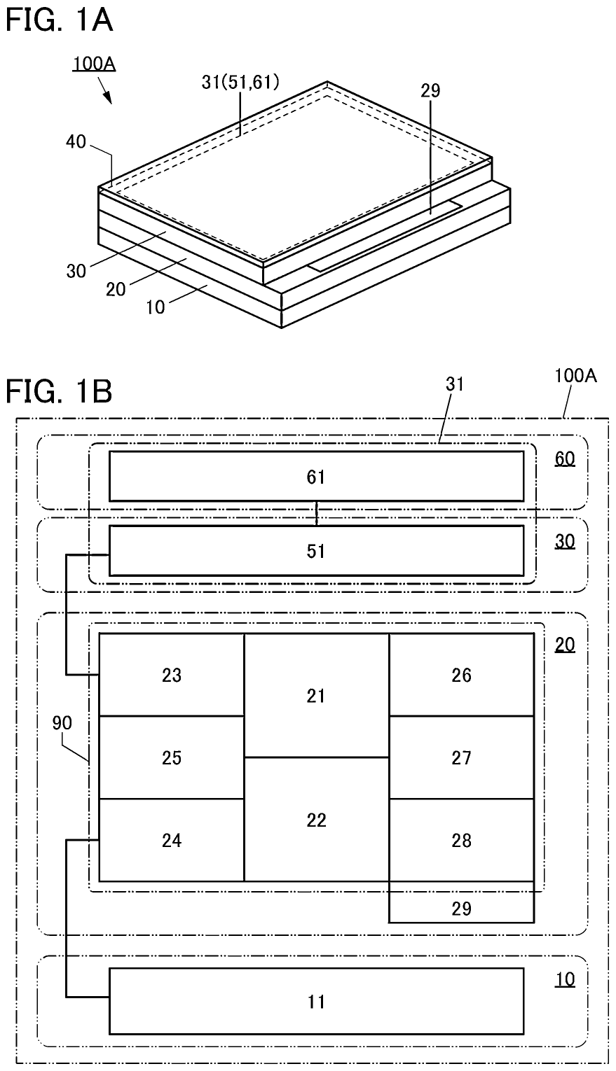

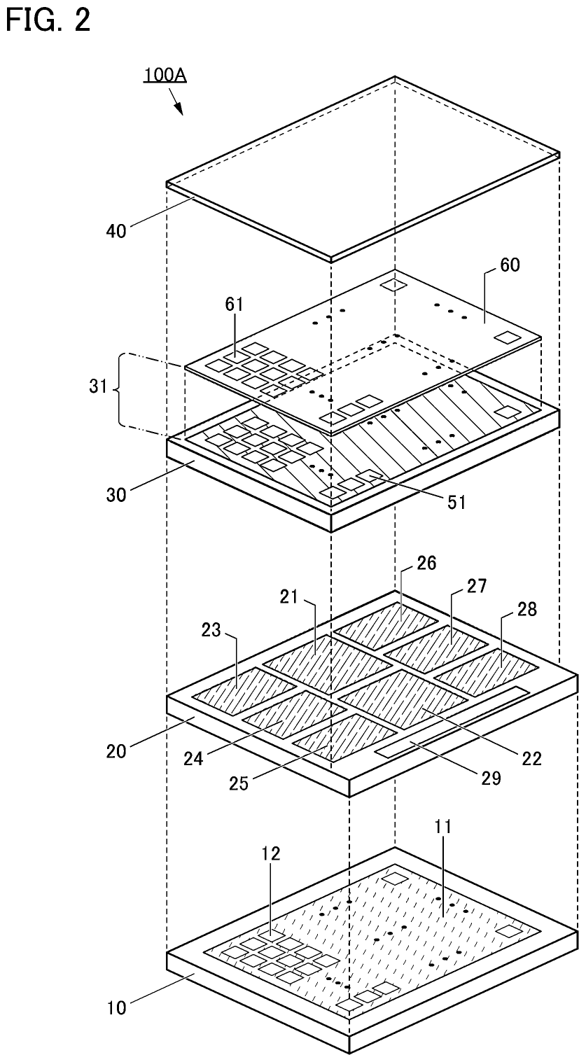

FIG. 1A and FIG. 2 are perspective views of a semiconductor device 100A of one embodiment of the present invention. FIG. 1B is a block diagram illustrating a structure of the semiconductor device 100A. The semiconductor device 100A includes a layer 20 over a layer 10, a layer 30 over the layer 20, and a sealing substrate 40 over the layer 30. The layer 30 includes a plurality of pixel circuits 51, and a layer 60 is provided between the sealing substrate 40 and the plurality of pixel circuits 51. In FIG. 2, the layer 10, the layer 20, the layer 30, the layer 60, the sealing substrate 40, and the like are separated and illustrated for easy understanding of the structure of the semiconductor device 100A.

The layer 10 includes a storage unit 11. The storage unit 11 includes a plurality of memory cells 12. The memory cell 12 functions as a memory element. Various storage systems of storage devices can be used for the storage unit 11. For example, a DRAM (Dynamic Random Access Memory), an SRAM (Static Random Access Memory), a phase-change memory (PCM), a resistive random access memory (ReRAM), a magnetoresistive random access memory (MRAM), a ferroelectric random access memory (FeRAM), an antiferroelectric memory or the like may be used.

In addition, a flash memory may be used as the storage unit 11. In addition, a NOSRAM (Nonvolaite Oxide Semiconductor Random Access Memory) or a DOSRAM (Dynamic Oxide Semiconductor Random Access Memory) may be used as the storage unit 11, for example. NOSRAM and DOSRAM are each one kind of storage devices using a transistor including an oxide semiconductor in a channel formation region (hereinafter also referred to as an “OS transistor”).

The storage unit 11 may include a plurality of kinds of storage devices. For example, a nonvolatile storage device and a volatile storage device may be provided. The storage unit 11 has a function of holding various programs used in the semiconductor device 100A and data and the like necessary for operation of the semiconductor device 100A.

The layer 20 includes a functional circuit 90 and a terminal portion 29. The functional circuit 90 includes a CPU (Central Processing Unit) 21, a GPU (Graphics Processing Unit) 22, a display portion driver circuit 23, a storage unit driver circuit 24, a super-resolution circuit 25, a sensor circuit 26, a communication circuit 27, and an input/output circuit 28.

Note that the functional circuit 90 does not necessarily include all of the circuits, and may include another structure. For example, a potential generating circuit that generate a plurality of different potentials, and/or a power management circuit for controlling supply and stop of electrical power for each circuit included in the semiconductor device 100A may be provided. The supply and stop of electrical power may be performed per circuit included in the CPU 21. For example, power consumption can be reduced by stopping supply of electrical power to a circuit, which is determined to be not used for a while, of the circuits included in the CPU 21, and restarting the supply of electrical power to the circuit as needed. Data necessary for restarting supply of electrical power may be stored in a storage circuit in the CPU 21, the storage unit 11, or the like before stopping the circuit. By storing data necessary for recovery of the circuit, high-speed recovery of the circuit stopped can be performed. Note that supply of a clock signal may be stopped to stop the circuit operation.

The functional circuit 90 may include DSP (Digital Signal Processor) and/or FPGA (Field Programmable Gate Array), for example.

The CPU 21 has a function of controlling operations of the GPU 22 and the circuit provided in the layer 20, following the program stored in the storage unit 11. The GPU 22 has a function of performing arithmetic processing for generating image data. Furthermore, the GPU 22 can perform a large number of matrix operations (product-sum operations) in parallel and thus, can perform arithmetic operation using a neural network at high speed, for example. The GPU 22 has a function of correcting image data using correction data stored in the storage unit 11, for example. For example, the GPU 22 has a function of generating image data in which brightness, hue, and/or contrast, or the like is corrected.

The display portion driver circuit 23 is electrically connected to the plurality of pixel circuits 51 included in the layer 30, and has a function of supplying image data to the plurality of pixel circuits 51. Any of various circuits such as a shift register, a level shifter, an inverter, a latch, an analog switch, and a logic circuit can be used as the display portion driver circuit 23.

The layer 60 is provided to overlap with the layer 30. The layer 60 includes a plurality of light-emitting elements 61. One light-emitting element 61 and one pixel circuit 51 are electrically connected to each other and function as one pixel. The pixel circuit 51 controls the emission luminance of the light-emitting element 61. In addition, the display portion 31 is formed using a plurality of pixels. In other words, the display portion 31 includes a plurality of pixels. The layer 60 may be included in the layer 30. In this case, it can be said that the display portion 31 is included in the layer 30. The pixel circuit 51 and the light-emitting element 61 are described later.

The super-resolution circuit 25 has a function of determining a potential of any pixel included in the display portion 31 by a product-sum operation of weights and potentials of pixels in the periphery of the pixel. The super-resolution circuit 25 has a function of upconverting image data with a lower definition than that of the display portion 31. The super-resolution circuit 25 has a function of downconverting image data with a higher definition than that of the display portion 31.

Note that upconversion and downconversion of image data can be performed by the GPU 22; however, providing the super-resolution circuit 25 can reduce the load on the GPU 22. For example, the GPU 22 executes processing up to 2K definition (or 4K definition) and the super-resolution circuit 25 performs upconversion to 4K definition (or 8K definition), whereby the load on the GPU 22 can be reduced. Consequently, the operating speed of the semiconductor device 100A can be increased.

The storage portion driver circuit 24 is electrically connected to the storage unit 11 included in the layer 10, and has a function of writing and reading data in and out of the storage unit 11.

The sensor circuit 26 has a function of obtaining information on one or more of the senses of sight, hearing, touch, taste, and smell of a human. Specifically, the sensor circuit 26 has at least one of functions of sensing or measuring force, displacement, position, speed, acceleration, angular velocity, rotational frequency, distance, light, magnetism, temperature, sound, time, electric field, current, voltage, electric power, radiation, humidity, gradient, oscillation, a smell, and infrared rays. The sensor circuit 26 may have a function other than the functions.

The communication circuit 27 has a wireless or wired communication function. In particular, the communication circuit 27 preferably has a wireless communication function, in which case the number of parts such as a connection cable can be decreased.

In the case where the communication circuit 27 has a wireless communication function, the communication circuit 27 can perform communication via an antenna. As a communication protocol or a communication technology, a communications standard such as LTE (Long Term Evolution), GSM (Global System for Mobile Communication: registered trademark), EDGE (Enhanced Data Rates for GSM Evolution), CDMA2000 (Code Division Multiple Access 2000), or W-CDMA (registered trademark), or an IEEE communications standard such as Wi-Fi (registered trademark), Bluetooth (registered trademark), or ZigBee (registered trademark) can be used.

The communication circuit 27 can perform input/output of information by connecting the semiconductor device 100A to another device via a computer network such as the Internet, which is an infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network).

The input/output circuit 28 has a function of distributing signals supplied to the semiconductor device 100A through the terminal portion 29 to circuits such as the CPU 21 and/or the GPU 22. In addition, the input/output circuit 28 has a function of distributing signals supplied to the semiconductor device 100A through the communication circuit 27 to the circuits such as the CPU 21 and/or the GPU 22.

The input/output circuit 28 has a function of outputting signals to the outside through the terminal portion 29. The input/output circuit 28 has function of outputting signals to the outside through the communication circuit 27.

Since the FPC (Flexible printed circuits) or the like is electrically connected to the terminal portion 29, the layer 30 and the sealing substrate 40 are not formed in the region overlapping with the terminal portion 29.

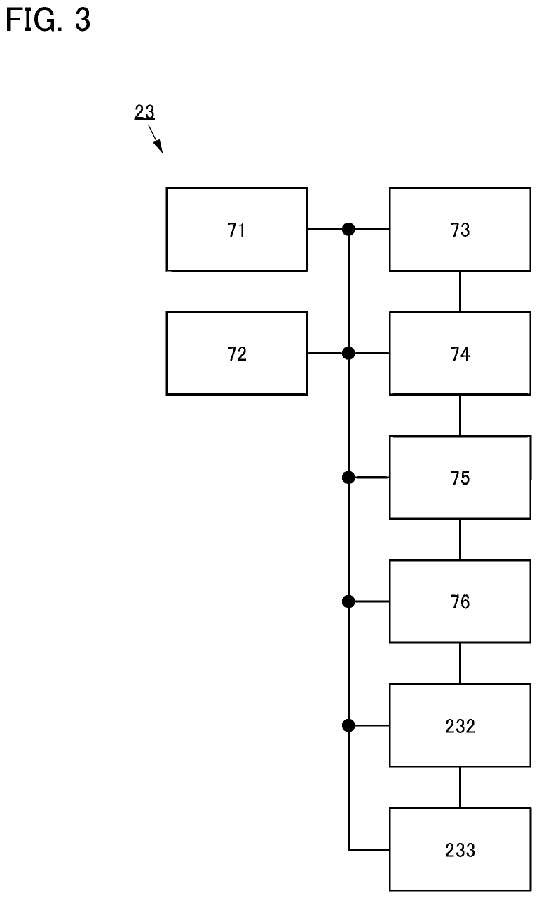

FIG. 3 is a block diagram illustrating a structure example of the display portion driver circuit 23. The display portion driver circuit 23 includes a control circuit 71, a timing controller 72, a serial-parallel conversion circuit 73, a latch circuit 74, a DAC 75, an amplifier circuit 76, a first driver circuit 232, and a second driver circuit 233. Note that the display portion driver circuit 23 does not necessarily include all of the structures, or may include a structure other than the structures.

The control circuit 71 is electrically connected to the timing controller 72, the serial-parallel conversion circuit 73, the latch circuit 74, the DAC 75, the amplifier circuit 76, the first driver circuit 232, and the second driver circuit 233 and has a function of controlling the operation of the display portion driver circuit 23. For example, the control circuit 71 controls the output characteristics of the DAC 75, the stop of the amplifier circuit 76 while a displayed image is not updated, and the like. In the case where the display portion 31 is divided into a plurality of subpanels and is driven, the control circuit 71 has a function of controlling the operation of each subpanel. The control circuit 71 may further have a function of controlling the setting conditions of weights used in the GPU 22, the super-resolution circuit 25, and the like, for each subpanel.

The timing controller 72 has a function of controlling the timing of updating a display image in accordance with the frame frequency. In the case where the display portion 31 is divided into a plurality of subpanels and driven, the timing controller 72 has a function of controlling the timing of updating image displayed, for each subpanel.

The serial-parallel conversion circuit 73 has a function of distributing digital image signals input by a serial-communication method to each signal line (e.g., a wiring 237 described later). The distributed digital image signal is temporarily stored in the latch circuit 74 and then is converted into an analog image signal by the DAC 75. The analog image signal is amplified by the amplifier circuit 76 and supplied to the signal line.

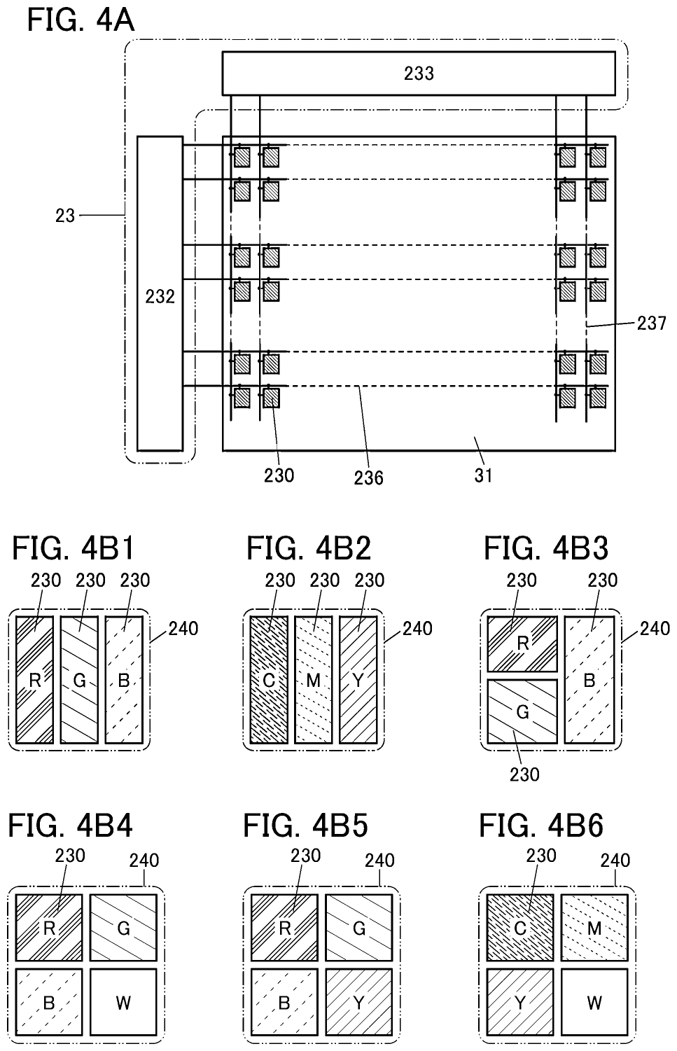

FIG. 4A is a block diagram illustrating a connection relation between the display portion driver circuit 23 and the display portion 31.

The display portion driver circuit 23 includes the first driver circuit 232 and the second driver circuit 233. A circuit included in the first driver circuit 232 functions as, for example, a scan line driver circuit. A circuit included in the second driver circuit 233 functions as, for example, a signal line driver circuit. Some sort of circuit may be provided to face the first driver circuit 232 with the display portion 31 placed therebetween. Some sort of circuit may be provided to face the second driver circuit 233 with the display portion 31 placed therebetween.

The display portion driver circuit 23 is referred to as a “peripheral driver circuit” in some cases. Any of various circuits such as a shift register, a level shifter, an inverter, a latch, an analog switch, and a logic circuit can be used as the peripheral driver circuit. In the peripheral driver circuit, a transistor, a capacitor, and the like can be used.

The display portion 31 includes m wirings 236 (m is an integer of 1 or more) which are arranged substantially parallel to each other and whose potentials are controlled by the circuit included in the first driver circuit 232, and n wirings 237 (n is an integer of 1 or more) which are arranged substantially parallel to each other and whose potentials are controlled by the circuit included in the second driver circuit 233. The wiring 236 is electrically connected to the first driver circuit 232. The wiring 237 is electrically connected to the second driver circuit 233.

The display portion 31 includes a plurality of pixels 230 arranged in a matrix. For example, the pixel 230 that controls red light, the pixel 230 that controls green light, and the pixel 230 that controls blue light are allowed to collectively function as one pixel 240 and the amount of light (emission luminance) emitted from each pixel 230 is controlled, whereby full-color display can be performed. Thus, each of the three pixels 230 functions as a subpixel. That is, three subpixels control the emission amount or the like of red light, green light, and blue light (see FIG. 4B1). The light colors controlled by the three subpixels are not limited to a combination of red (R), green (G), and blue (B) and may be cyan (C), magenta (M), and yellow (Y) (see FIG. 4B2). The areas of the three subpixels are not necessarily equal. In the case where the emission efficiency, the reliability, and the like are different depending on emission colors, the areas of subpixels may be different depending on emission colors (see FIG. 4B3). Note that the arrangement of the subpixels in FIG. 4B3 may be called “S stripe arrangement”.

Four subpixels may collectively function as one pixel. For example, a subpixel that controls white light (W) may be added to the three subpixels that control red light, green light, and blue light (see FIG. 4B4). The addition of the subpixel that controls white light can increase the luminance of a display region. Alternatively, a subpixel that controls yellow light may be added to the three subpixels that control red light, green light, and blue light (see FIG. 4B5). Alternatively, a subpixel that controls white light may be added to the three subpixels that control cyan light, magenta light, and yellow light (see FIG. 4B6).

When the number of subpixels functioning as one pixel is increased and subpixels that control light of red, green, blue, cyan, magenta, yellow, and the like are used in an appropriate combination, the reproducibility of halftones can be increased. Therefore, the color reproducibility can be improved.

The display apparatus of one embodiment of the present invention can reproduce the color gamut of various standards. For example, the display apparatus of one embodiment of the present invention can reproduce the color gamut of the PAL (Phase Alternating Line) standard and the NTSC (National Television System Committee) standard used for TV broadcasting; the sRGB (standard RGB) standard and the Adobe RGB standard widely used for display apparatuses used in electronic devices such as personal computers, digital cameras, and printers; the ITU-R BT.709 (International Telecommunication Union Radiocommunication Sector Broadcasting Service (Television) 709) standard used for HDTV (High Definition Television, also referred to Hi-Vision); the DCI-P3 (Digital Cinema Initiatives P3) standard used for digital cinema projection; the ITU-R BT.2020 (REC.2020 (Recommendation 2020)) standard used for UHDTV (Ultra High Definition Television, also referred to as Super Hi-Vision); and the like.

Using the pixels 240 arranged in a matrix of 1920×1080, the display portion 31 can achieve full color display with a definition of a so-called full hi-vision (also referred to as 2K definition, 2KIK, 2K, or the like). For example, using the pixels 240 arranged in a matrix of 3840×2160, the display portion 31 can achieve full color display with a definition of ultra hi-vision (also referred to as 4K definition, 4K2K, 4K, or the like). For example, using the pixels 240 arranged in a matrix of 7680×4320, the display portion 31 can achieve full color display with a definition of super hi-vision (also referred to as 8K definition, 8K4K, 8K, or the like). By increasing the number of pixels 240, the display portion 31 that can perform full-color display with 16K or 32K definition can also be obtained.

The pixel density (resolution) of the display portion 31 is preferably higher than or equal to 1000 ppi and lower than or equal to 10000 ppi. For example, the resolution may be higher than or equal to 2000 ppi and lower than or equal to 6000 ppi, or higher than or equal to 3000 ppi and lower than or equal to 5000 ppi.

Note that there is no particular limitation on the screen ratio (aspect ratio) of the display portion 31. For example, the display portion 31 of the semiconductor device 100A is compatible with a variety of screen ratios such as 1:1 (a square), 4:3, 16:9, and 16:10.

In the case where the semiconductor device 100A is used as a display apparatus for xR, the display portion 31 can have a screen diagonal greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the display portion 31 may have a screen diagonal of 1.5 inches or approximately 1.5 inches. When the display portion 31 has a screen diagonal less than or equal to 2.0 inches, preferably, approximately 1.5 inches, the number of times of light exposure treatment using a light exposure apparatus (typified by a scanner apparatus) can be one; thus, the productivity of a manufacturing process can be improved.

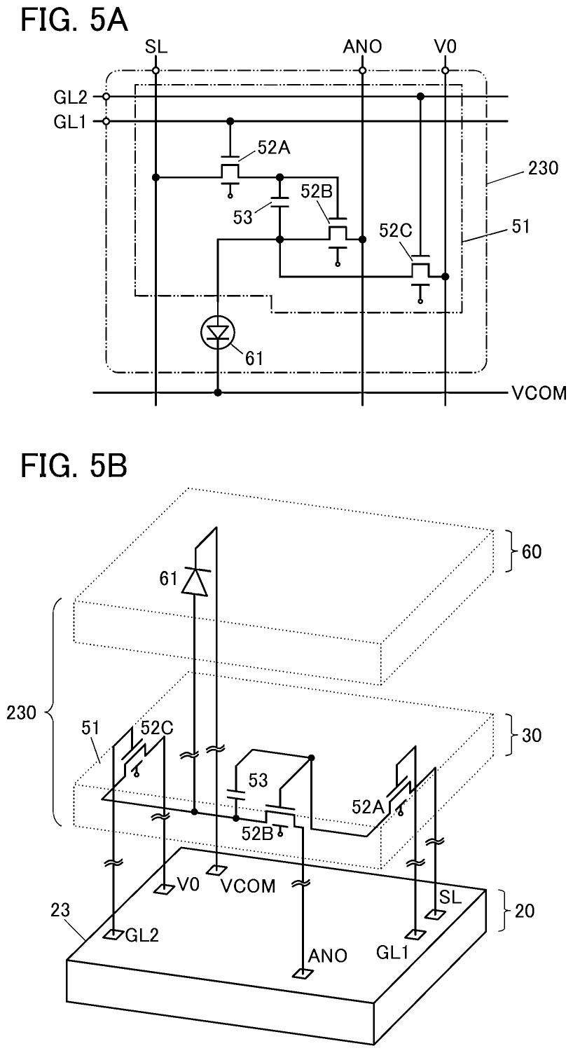

In FIG. 5, an example of a circuit configuration of the pixel 230 is illustrated. The pixels 230 each include the pixel circuit 51 and the light-emitting element 61. FIG. 5A illustrates the connection of the elements included in the pixel 230. FIG. 5B schematically illustrates the vertical positional relation between the layer 20 including the display portion driver circuit 23, the layer 30 including the pixel circuit 51, and the layer 60 including the light-emitting element 61.

The pixel circuit 51 illustrated as an example in FIGS. 5A and 5B includes a transistor 52A, a transistor 52B, a transistor 52C, and a capacitor 53. The transistor 52A, the transistor 52B, and the transistor 52C can be OS transistors. Each of the OS transistors of the transistor 52A, the transistor 52B, and the transistor 52C preferably includes a back gate electrode, in which case the back gate electrode can be supplied with the same signal as the gate electrode or the back gate electrode can be supplied with a signal different from that of the gate electrode.

The transistor 52B includes a gate electrode electrically connected to the transistor 52A, a first terminal electrically connected to the light-emitting element 61, and a second terminal electrically connected to a wiring ANO. The wiring ANO is a wiring for supplying a potential for supplying current to the light-emitting element 61.

The transistor 52A includes a first terminal electrically connected to the gate electrode of the transistor 52B and a second terminal electrically connected to a wiring SL which functions as a source line, and has a function of controlling its conduction state or non-conduction state on the basis of the potential of a wiring GL1 which functions as a gate line.

The transistor 52C includes a first terminal electrically connected to a wiring VO and a second terminal electrically connected to the light-emitting element 61, and has a function of controlling its conduction state or non-conduction state on the basis of the potential of a wiring GL2 which functions as a gate line. The wiring VO is a wiring for supplying a reference potential and a wiring for outputting current flowing through the pixel circuit 51 to the display portion driver circuit 23.

The capacitor 53 includes a conductive film electrically connected to the gate electrode of the transistor 52B and a conductive film electrically connected to the second electrode of the transistor 52C.

The light-emitting element 61 includes a first electrode electrically connected to the first terminal of the transistor 52B and a second electrode electrically connected to a wiring VCOM. The wiring VCOM is a wiring for supplying a potential for supplying current to the light-emitting element 61.

Accordingly, the intensity of light emitted from the light-emitting element 61 can be controlled in accordance with an image signal supplied to the gate electrode of the transistor 52B. Furthermore, variations in the gate-source potential of the transistor 52B can be inhibited by the reference potential of the wiring VO supplied through the transistor 52C.

A current value that can be used for setting of pixel parameters can be output from the wiring VO. Specifically, the wiring VO can function as a monitor line for outputting a current flowing through the transistor 52B or a current flowing through the light-emitting element 61 to the outside. A current output to the wiring VO may be converted into a voltage by a source follower circuit or the like.

As the light-emitting element 61, a self-luminous display element such an LED (Light Emitting Diode) or an OLED (Organic Light Emitting Diode. Also referred to as “organic EL element” or “OEL”) can be used. In addition, as the light-emitting element 61, a self-luminous type light-emitting element such as a micro LED, a QLED (Quantum-dot Light Emitting Diode) or a semiconductor laser may be used.

Note that in the structure example illustrated as an example in FIG. 5B, the wirings electrically connecting the pixel circuit 51 and the display portion driver circuit 23 can be shortened, so that wiring resistances of the wirings can be reduced. In addition, the parasitic capacitances of the wirings can be lowered. Thus, data can be written at high speed, which enables high-speed driving of the display portion 31. Therefore, even when the number of the pixel circuits 51 is increased, a sufficient frame period can be ensured, and thus, the pixel density of the display portion 31 can be increased. In addition, the increased pixel density of the display portion 31 can increase the resolution of an image displayed on the display portion 31. For example, the pixel density of the display portion 31 can be higher than or equal to 1000 ppi, higher than or equal to 5000 ppi, or higher than or equal to 7000 ppi. Thus, the semiconductor device 100A can be used in display apparatuses for xR such as AR or VR, for example. The semiconductor device 100A of one embodiment of the present invention can be favorably used for an electronic device whose display portion is close to a user, such as an HMD.

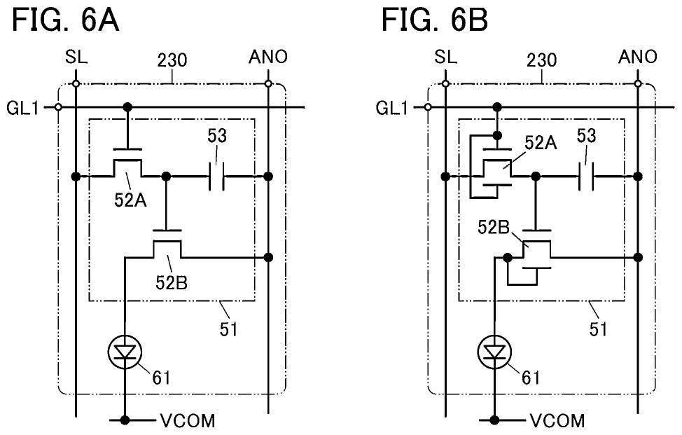

FIG. 6A illustrates a variation example of the circuit configuration of the pixel 230 illustrated in FIG. 5A. The circuit configuration in FIG. 6A is a configuration excluding the transistor 52C, the wiring GL2, and the wiring VO from the circuit configuration illustrated in FIG. 5A.

For example, as illustrated in FIG. 6B, a transistor including a backgate may be used as the transistor 52A and the backgate and the gate may be electrically connected to each other. In addition, as in the transistor 52B illustrated in FIG. 6B, the back gate and one of the source and the drain of the transistor may be electrically connected to each other.

As described above, the semiconductor device 100A of one embodiment of the present invention has a structure in which the display portion 31, the functional circuit 90, and the storage unit 11 are stacked. The display portion 31, the functional circuit 90, and the storage unit 11 are stacked, whereby the semiconductor device 100A can be downsized. Furthermore, when the display portion driver circuit 23 is provided so as to overlap with the display portion 31, the width of the bezel around the display portion 31 can be extremely small; thus, the area of the display portion 31 can be increased. Thus, the definition of the display portion 31 can be increased. Consequently, the display quality of the semiconductor device 100A can be improved.

Under a fixed definition of the display portion 31, the occupation area per pixel can be increased. Thus, the emission luminance of the display portion 31 can be increased. Furthermore, the pixel aperture ratio can be increased. For example, the pixel aperture ratio can be greater than or equal to 40% and less than 100%, preferably greater than or equal to 50% and less than or equal to 95%, further preferably greater than or equal to 60% and less than or equal to 95%. By enlarging the occupation area per pixel, the density of current supplied to the pixels can be lowered. Accordingly, the load applied to the pixel is reduced, so that the reliability of the semiconductor device 100A can be increased.

In addition, the display portion 31, the functional circuit 90, and the storage unit 11 are stacked, whereby the wiring for electrical connection between them can be shortened. Thus, the wiring resistance and the parasitic capacitance can be lowered, and the operation speed of the semiconductor device 100A can be increased. In addition, power consumption of the semiconductor device 100A is reduced.

For example, when a matrix arithmetic operation is performed in the GPU 22, a large amount of data used for the arithmetic operation and data of the arithmetic operation are temporarily in the storage unit 11. As the GPU 22 is closer to the storage unit 11, a delay time is reduced, and high-speed arithmetic processing is possible.

In particular, a preferred structure is the structure in which the layer 20 including the functional circuit 90 is placed between the layer 30 including the display portion 31 and the layer 10 including the storage unit 11, because the structure can shorten both wirings connecting the display portion 31 to the display portion driver circuit 23 and wirings connecting the storage unit 11 and the storage unit driver circuit 24.

Although not illustrated, the layer 10 in the semiconductor device 100A is preferably in contact with a material having a high thermal conductivity (e.g., a metal material such as a copper or aluminum).

### Variation Example

Next, a variation example of the semiconductor device 100A is described. In order to reduce repeated description, different points from the semiconductor device 100A are mainly described. The description of the semiconductor device 100A can be referred to for parts that are not described below.

### Variation Example 1

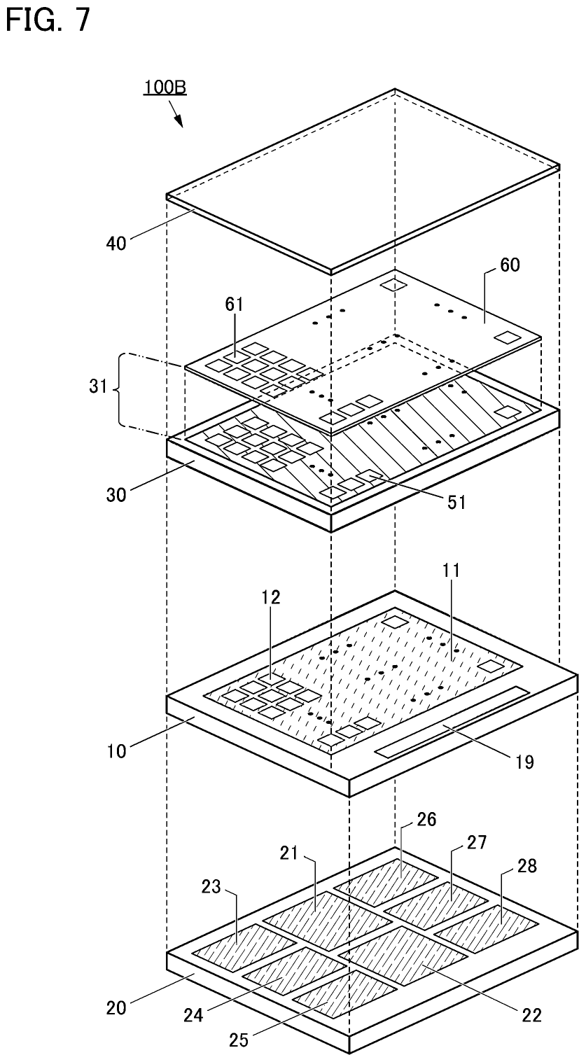

FIG. 7 illustrates a semiconductor device 100B, which is a variation example of the semiconductor device 100A. FIG. 7 is a perspective view of the semiconductor device 100B of one embodiment of the present invention. In FIG. 7, the layer 10, the layer 20, the layer 30, the layer 60, the sealing substrate 40, and the like are separated and illustrated for easy understanding of the structure of the semiconductor device 100B.

The semiconductor device 100B is different from the semiconductor device 100A in the stacking order of the layer 10 and the layer 20. Specifically, the semiconductor device 100B includes the layer 10 over the layer 20, the layer 30 over the layer 10, and the sealing substrate 40 over the layer 30. In addition, the semiconductor device 100B includes a terminal portion 19 over the layer 10 instead of the terminal portion 29 over the layer 20. Although not illustrated, the layer 20 in the semiconductor device 100B is preferably in contact with a heat-radiation body. Note that the heat-radiation body refers to one having a function of releasing heat generated in the semiconductor device 100B to the outside of the semiconductor device 100B.

The semiconductor device of one embodiment of the present invention can change the stacking order of layers depending on the purpose or the usage.

### Variation Example 2

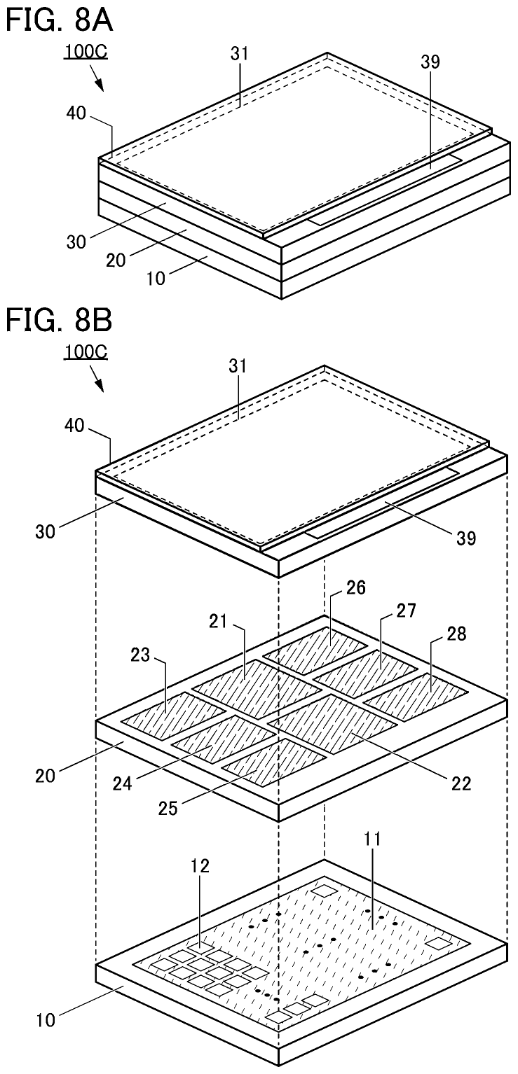

FIG. 8 illustrates a semiconductor device 100C, which is a variation example of the semiconductor device 100A. FIG. 8A and FIG. 8B are perspective views of the semiconductor device 100C of one embodiment of the present invention. In FIG. 8B, the layer 10, the layer 20, and the layer 30 are separated and illustrated for easy understanding of the structure of the semiconductor device 100C.

The semiconductor device 100C includes a terminal portion 39 in the layer 30 instead of the terminal portion 29, without including the terminal portion 29 in the layer 20.

### Variation Example 3

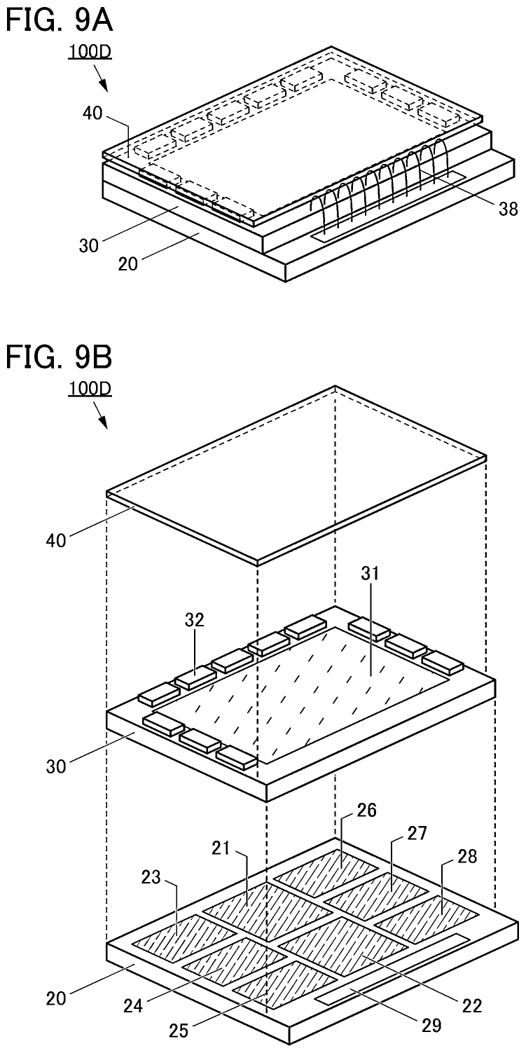

FIG. 9 illustrates a semiconductor device 100D, which is a variation example of the semiconductor device 100A. FIG. 9A and FIG. 9B are perspective views of the semiconductor device 100D of one embodiment of the present invention. In FIG. 9B, the layer 20, the layer 30, and the sealing substrate 40 are separated and illustrated for easy understanding of the structure of the semiconductor device 100D.

The semiconductor device 100D does not include the layer 10, and includes a plurality of memory chips 32 serving as the storage unit 11 in the periphery of the display portion 31 over the layer 30, instead of the layer 10. The plurality of memory chips 32 are arranged along the outer periphery of the display portion 31. The semiconductor device 100D includes the memory chips 32 arranged in three sides of the display portion 31, and the layer 30 and the layer 20 are electrically connected to each other with a plurality of wires 38 in the other one side. Note that the wires 38 may be formed by a wire bonding method.

As the memory chip 32, a variety of memory devices such as a DRAM, an SRAM, or a flash memory can be used. The memory chips 32 can be mounted on the layer 30 by any of a variety of materials and methods, such as anisotropic conductive adhesive, ball bonding, and wire bonding. Alternatively, the memory chips 32 may be mounted on the layer 30 by Cu—Cu bonding (in which Cu pads on both sides are exposed and are in contact with each other at the bonding interface to establish electrical conduction) or a bond using a bump and TSV (Through Silicon Via).

The memory chip 32 is preferably arranged at a position overlapping with a sealing material 712 (also referred to as a “sealant”. The sealing material 712 is described below) with which the layer 30 and the sealing substrate 40 are attached to each other. A region where the layer 30, the sealing material 712, and the sealing substrate 40 overlap with each other is also referred to as a “sealing region”. The memory chips 32 are provided in the sealing region, whereby the memory chips 32 can be arranged efficiently.

In the case where the memory chips 32 overlap with the sealing material, the display portion 31 and the memory chips 32 are covered with the sealing substrate 40. Covering the memory chips 32 with the sealing substrate 40 can prevent outside impurities and the like from diffusing into the memory chips 32.

### Variation Example 4

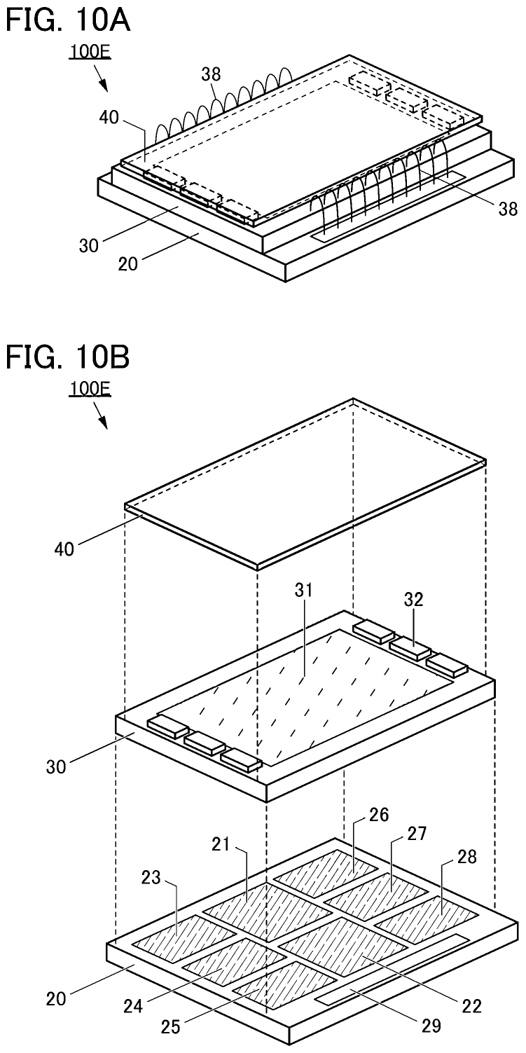

FIG. 10 illustrates a semiconductor device 100E, which is a variation example of the semiconductor device 100D. FIG. 10A and FIG. 10B are perspective views of the semiconductor device 100E of one embodiment of the present invention. In FIG. 10B, the layer 20, the layer 30, and the sealing substrate 40 are separated and illustrated for easy understanding of the structure of the semiconductor device 100E. Note that the layer 60 is not illustrated.

In the semiconductor device 100E, the memory chips 32 are arranged at two opposite sides of four sides adjacent to the display portion 31 and the wires 38 for electrically connecting the layer 30 and the layer 20 are arranged at the other two sides.

By increasing the number of the wires 38 for electrically connecting the layer 30 and the layer 20, the signal transmission speed between the layer 30 and the layer 20 can be increased.

### Variation Example 5

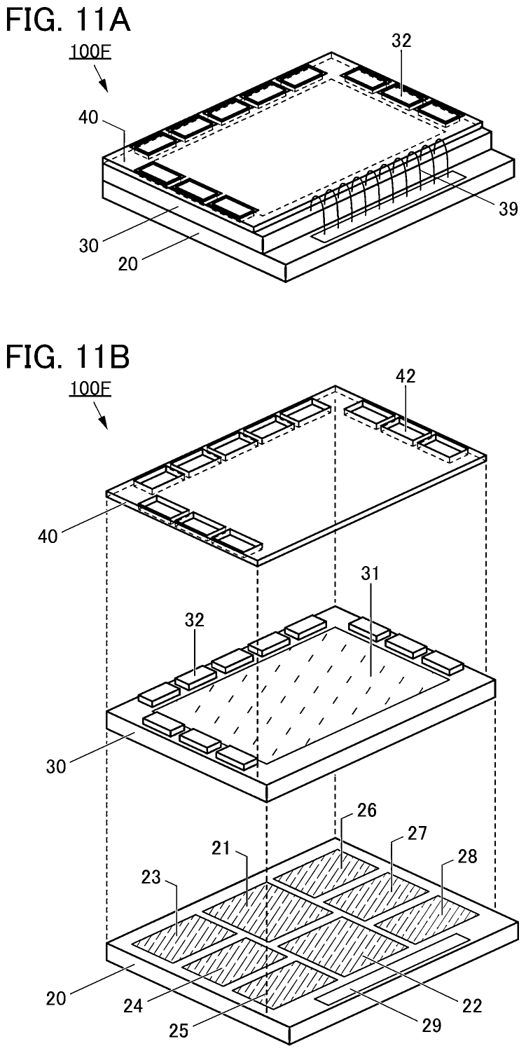

FIG. 11 illustrates a semiconductor device 100F, which is a variation example of the semiconductor device 100D. FIG. 11A and FIG. 11B are perspective views of the semiconductor device 100F of one embodiment of the present invention. In FIG. 11B, the layer 20, the layer 30, the sealing substrate 40, and the like are separated and illustrated for easy understanding of the structure of the semiconductor device 100F. Note that the layer 60 is not illustrated. The sealing substrate 40 included in the semiconductor device 100F includes a plurality of cutout portions 42. The cutout portions 42 are provided at positions overlapping with the memory chips 32.

In the semiconductor device 100F, the sealing substrate 40 and the layer 30 are attached to each other so that the memory chips 32 fit in the cutout portions 42. The semiconductor device 100E can be thinner than the semiconductor device 100D.

### Variation Example 6

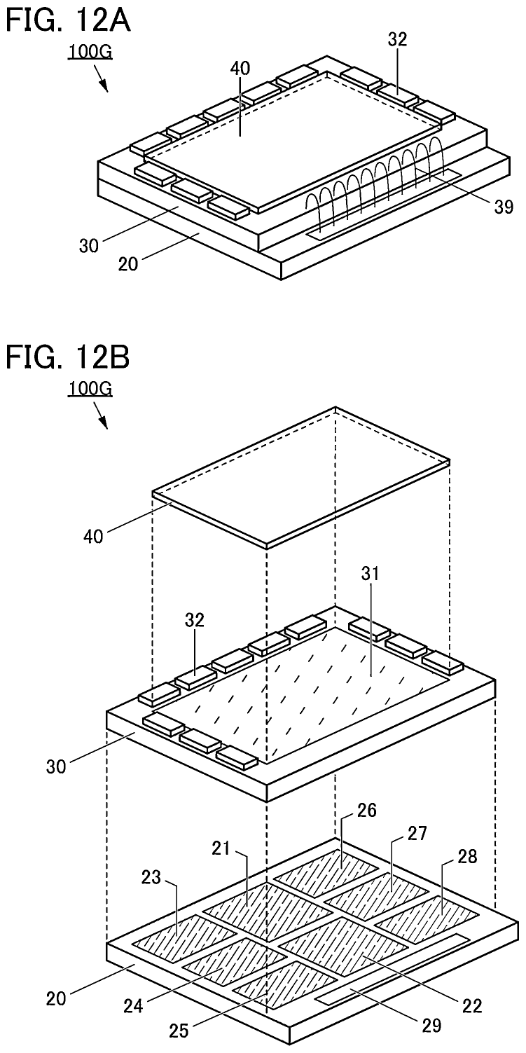

FIG. 12 illustrates a semiconductor device 100G, which is a variation example of the semiconductor device 100D. FIG. 12A and FIG. 12B are perspective views of the semiconductor device 100G of one embodiment of the present invention. In FIG. 12B, the layer 20, the layer 30, the sealing substrate 40, and the like are separated and illustrated for easy understanding of the structure of the semiconductor device 100G. Note that the layer 60 is not illustrated.

The semiconductor device 100G is different from the semiconductor device 100D in that the sealing substrate 40 overlaps with the display portion 31 without overlapping with the memory chip 32.

Since the sealing substrate 40 overlaps with the display portion 31 without overlapping with the memory chip 32, the thickness of the semiconductor device 100G can be reduced. Furthermore, the weight of the semiconductor device 100G can be reduced because the sealing substrate 40 becomes small.

### Variation Example 7

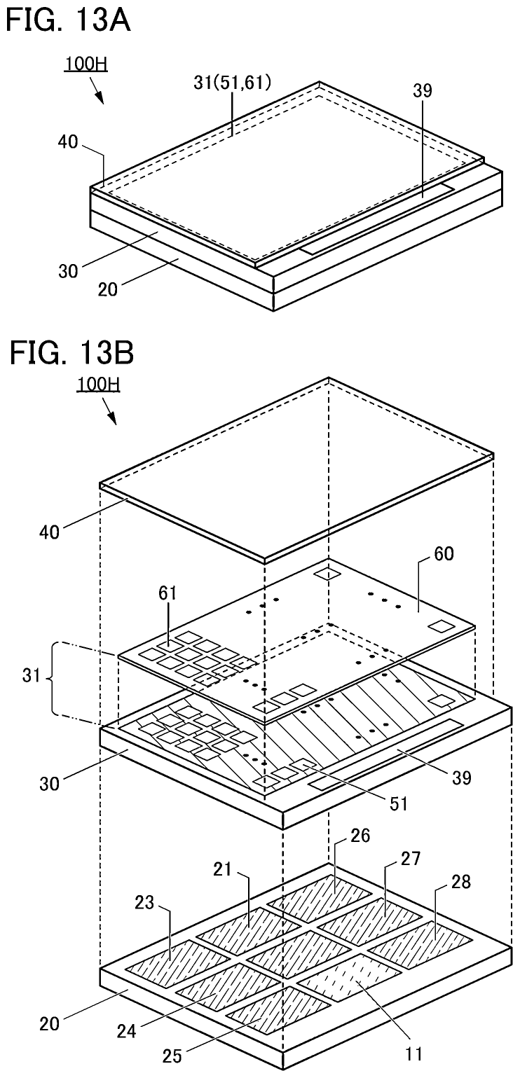

FIG. 13 illustrates a semiconductor device 100H, which is a variation example of the semiconductor device 100C. FIG. 13A and FIG. 13B are perspective views of the semiconductor device 100H. The semiconductor device 100H is different from the semiconductor device 100C in not including the layer 10. In FIG. 13B, the layer 20, the layer 30, the sealing substrate 40, and the like are separated and illustrated for easy understanding of the structure of the semiconductor device 100H.

The semiconductor device 100H is different from the semiconductor device 100C in that the layer 20 includes the storage unit 11. Since the layer 10 is not provided, the thickness of the semiconductor device 100H can be reduced. In addition, the layer 10 is not provided, so that the weight of the semiconductor device 100H can be reduced.

### Variation Example 8

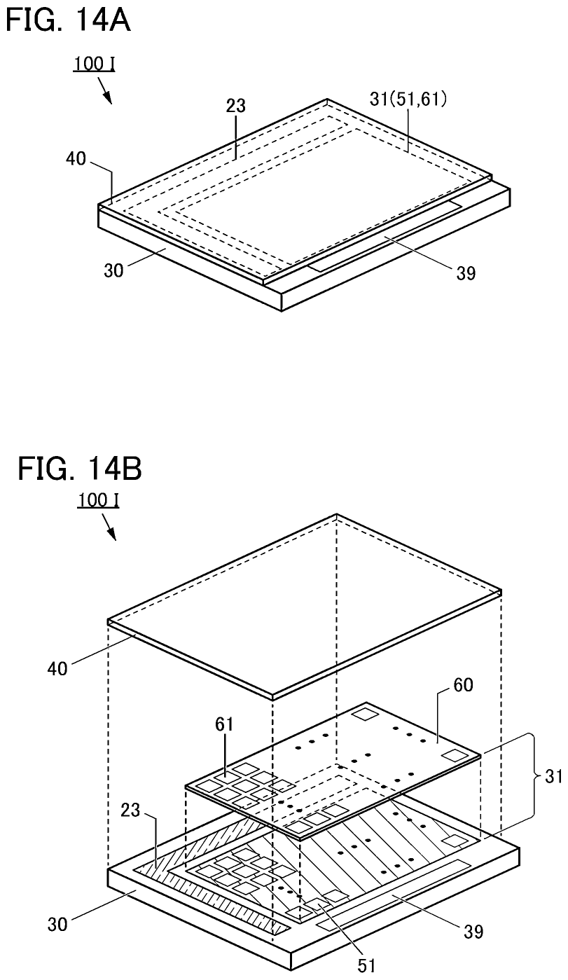

FIG. 14 illustrates a semiconductor device 100I, which is a variation example of the semiconductor device 100H. FIG. 14A and FIG. 14B are perspective views of the semiconductor device 100I. The semiconductor device 100I is different from the semiconductor device 100H in not including the layer 20. In FIG. 14B, the layer 30, the sealing substrate 40, and the like are separated and illustrated for easy understanding of the structure of the semiconductor device 100I.

The semiconductor device 100I includes the display portion driver circuit 23 and the pixel circuit 51 in the layer 30. A functional circuit necessary for the layer 30 may be formed depending on the purpose and/or the usage. An unnecessary functional circuit is not provided depending on the purpose and/or the usage, whereby power consumption and manufacturing cost of the semiconductor device can be reduced. Furthermore, the thickness of the semiconductor device can be reduced, and thus the weight of the semiconductor device can be reduced.

The structures described in this embodiment can be used in an appropriate combination with any of the structures described in the other embodiments and the like.

### Embodiment 2

In this embodiment, a structure example in which the display portion 31 included in the layer 30 is divided into a plurality of subpanels 35 is described.

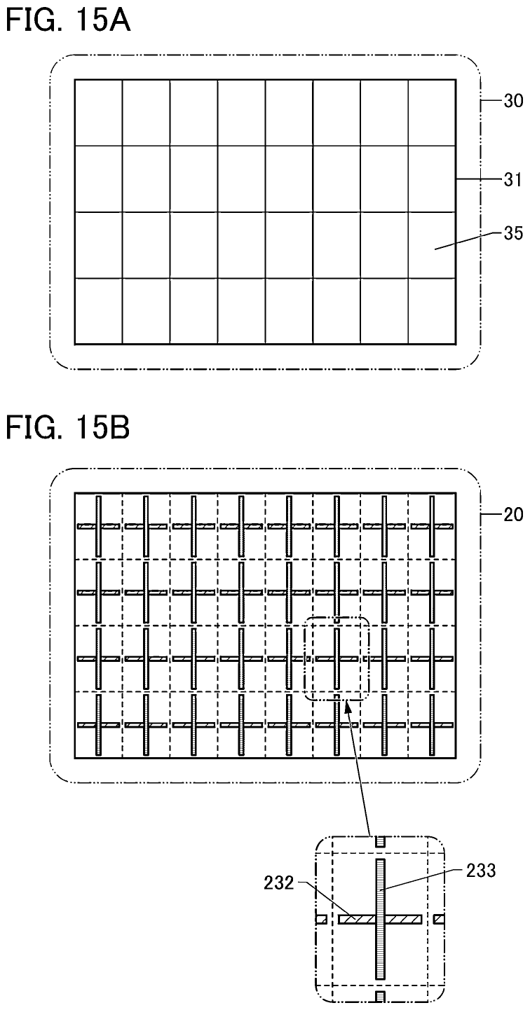

FIG. 15A illustrates a structure example where the display portion 31 is divided into 32 subpanels 35. FIG. 15A illustrates the subpanels 35 arranged in a matrix of four rows and eight columns. By dividing the display portion 31 into the plurality of subpanels 35, operation of the subpanels 35 in a region in which a display image is not needed to be updated can be stopped. In other words, only the subpanels 35 in a region in which a display image is needed to be updated can be operated. Thus, the power consumption of the semiconductor device can be reduced.

The pixel circuit 51 is formed using an OS transistor having extremely low off-state current, so that data written to a pixel can be retained for a long time. Therefore, frame frequency of display can be set to an arbitrary value (can be variable). Furthermore, the display portion 31 can be driven per subpanel 35. Therefore, the frame frequency can be set per subpanel 35.

In the case where the display portion 31 is divided into the plurality of subpanels 35, the first driver circuit 232 and the second driver circuit 233 that correspond to each subpanel 35 are provided in the layer 20. FIG. 15B illustrates an example in which the first driver circuit 232 and the second driver circuit 233 are provided in a region overlapping with the subpanel 35. Note that in FIG. 15B, a position corresponding to the outer edge portion of the subpanel 35 is illustrated by a dashed line. Although the first driver circuit 232 and the second driver circuit 233 provided per subpanel 35 are arranged so as to be intersect with each other at or near the center of the subpanel 35 in the example of FIG. 15B, one embodiment of the present invention is not limited thereto.

In the case where the layer 10 including the storage unit 11 is provided between the layer 20 and the layer 30, the memory cells 12 are not placed in a region of the layer 10 overlapping with the first driver circuit 232 and the second driver circuit 233. In this manner, the first driver circuit 232 and the second driver circuit 233 can be electrically connected to the subpanel 35 through the layer 10 in a short distance.

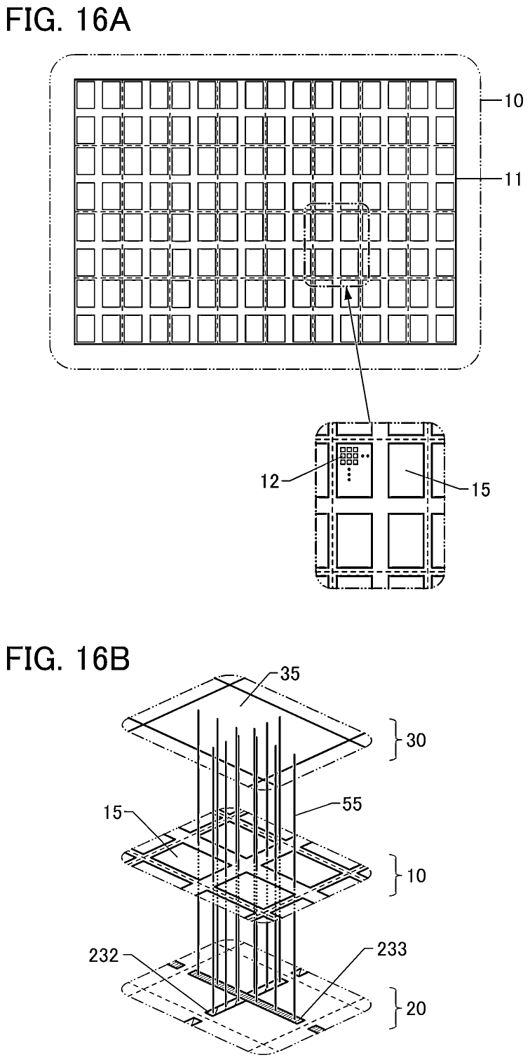

FIG. 16A illustrate a structure example of the layer 10. In FIG. 16A, a position corresponding to an outer edge portion of the subpanel 35 is illustrated by a dashed line. FIG. 16A illustrates an example in which a plurality of memory cells 12 are divided into four memory cell groups 15 in a region overlapping with the subpanel 35. Furthermore, a region between adjacent memory cell groups 15 is a region overlapping with the first driver circuit 232 and the second driver circuit 233 included in the layer 20 and is not provided with the memory cells 12.

FIG. 16B is a perspective view illustrating a region overlapping with one subpanel 35 in the layer 10, the layer 20, and the layer 30. By not providing the memory cells 12 in a region overlapping with the first driver circuit 232 and the second driver circuit 233 included in the layer 20, a conductor 55 that electrically connect the first driver circuit 232 and the second driver circuit 233 to the subpanel 35 can be extended in the stacking direction of the layer 10, the layer 20, and the layer 30. Therefore, since the first driver circuit 232 and the second driver circuit 233 can be connected to the subpanel 35 in an extremely short distance, the wiring resistance and the parasitic capacitance can be reduced and high-speed operation can be performed. In addition, since the degradation of an image signal is small, the display quality of the semiconductor device is improved. Moreover, the power consumption of the semiconductor device can be reduced. Note that the conductor 55 is formed with a conductor, TSV, or the like provided in the layers.

In the semiconductor device of one embodiment of the present invention, data communication between the GPU 22 and the storage unit 11 can be performed in parallel by using a large number of wirings. Accordingly, the semiconductor device of one embodiment of the present invention can operate at high speed. In the semiconductor device of one embodiment of the present invention, it is unnecessary to compress image data that is processed arithmetically by the GPU 22 and stored in the storage unit 11 in accordance with a communication standard such as HDMI (registered trademark), MIPI (registered trademark), or Display port. Accordingly, the semiconductor device of one embodiment of the present invention can operate at high speed and reduce its power consumption.

The structures described in this embodiment can be used in an appropriate combination with any of the structures described in the other embodiments and the like.

### Embodiment 3

The semiconductor device of one embodiment of the present invention may include a display correction system. The display correction system can reduce display defects based on defective pixels, such as bright spots and dark spots, by correcting current I_{EL} flowing to the light-emitting element 61.

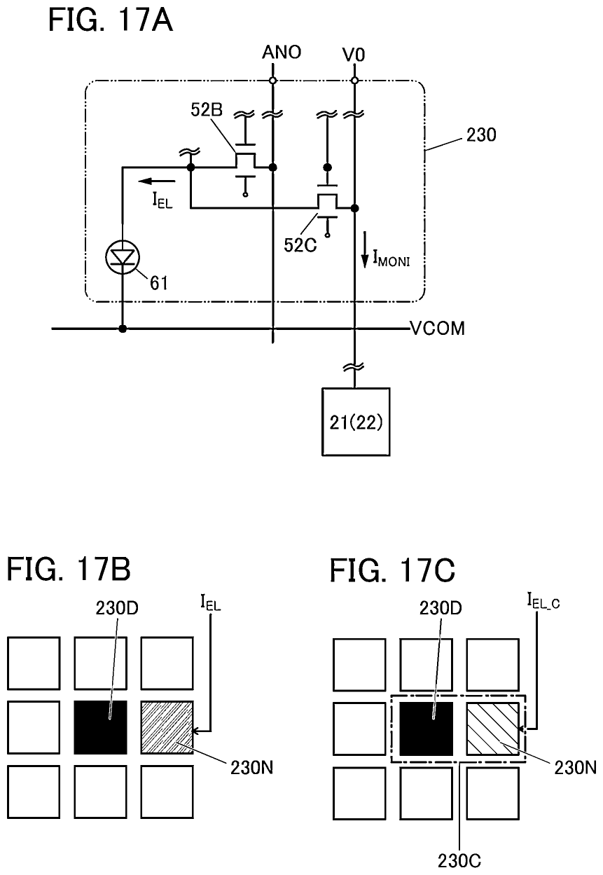

A circuit diagram illustrated in FIG. 17A illustrates an extracted part of the pixel circuit 51 illustrated in FIG. 5A. The current I_{EL} flowing to the light-emitting element 61 is extremely large in a defective pixel causing a bright spot, as compared with pixels displaying normally. The current I_{EL} in a defective pixel causing a dark spot is extremely small as compared with pixels displaying normally.

The CPU 21 periodically obtains data of monitor current I_{MONI} that flows through the transistor 52C. The amount of monitor current I_{MONI} is converted into digital data that can be processed in the CPU 21 and arithmetic processing is performed with the digital data in the CPU 21 or the GPU 22. A defective pixel is estimated by the arithmetic processing in the CPU 21 or the GPU 22, and correction is performed so that a display defect due to the defective pixel is less likely to be seen. For example, in the case where a pixel 230D illustrated in FIG. 17B is a defective pixel, the current I_{EL} that flows to an adjacent pixel 230N is corrected.

For example, the correction can estimated by executing an arithmetic operation based on an artificial neural network such as a deep neural network (DNN), a convolutional neural network (CNN), a recurrent neural network (RNN), an autoencoder, a deep Boltzmann machine (DBM), or a deep belief network (DBN).

By the above correction, the current I_{EL} flowing to an adjacent pixel 230N is corrected to a current I_{EL_C}, whereby a defective pixel 230D and the pixel 230N are combined to a pixel 230C for displaying (see FIG. 17C). By performing display as the pixel 230C, defective display such as a bright spot or a dark spot due to a defective pixel is made difficult to recognize, and can be close to a normal image.

Note that in the semiconductor device of one embodiment of the present invention, data that is being processed arithmetically can be held in the storage unit 11 in the above arithmetic processing. The semiconductor device of one embodiment of the present invention is particularly effective, because the display portion 31, the functional circuit 90, and the storage unit 11 are provided proximately to each other and high-speed operation can be achieved in arithmetic processing of numerous amount of arithmetic operations based on artificial neural network.

The structures described in this embodiment can be used in an appropriate combination with any of the structures described in the other embodiments and the like.

### Embodiment 4

In this embodiment, cross-sectional structure examples of a semiconductor device of one embodiment of the present invention will be described.

### <<Semiconductor Device 100A>>

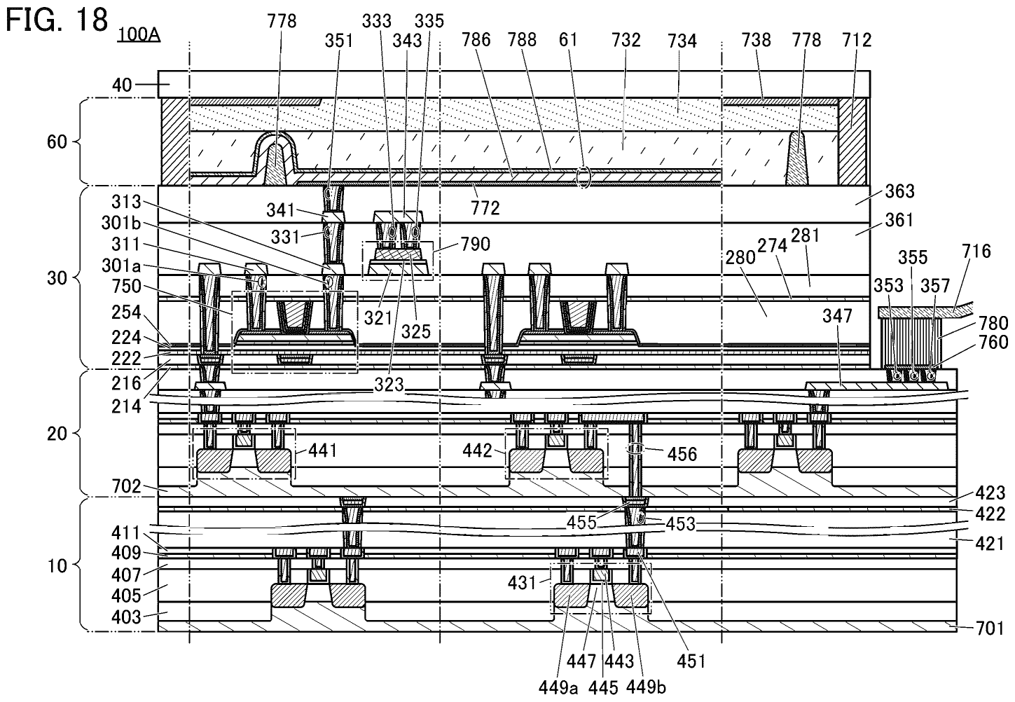

FIG. 18 is a cross-sectional view illustrating a structural example of the semiconductor device 100A and illustrates part of the semiconductor device 100A. As described above, the semiconductor device 100A includes the layer 10, the layer 20, the layer 30, the layer 60, and the sealing substrate 40.

### [Layer 10]

The layer 10 includes a substrate 701, and a transistor 431 is provided over the substrate 701. The transistor 431 is a transistor included in the memory cell 12, for example.

As the substrate 701, a single crystal semiconductor substrate such as a single crystal silicon substrate can be used, for example. Note that a semiconductor substrate other than a single crystal semiconductor substrate may be used as the substrate 701.

The transistor 431 includes a conductor 443 having a function as a gate electrode, an insulator 445 having a function as a gate insulator, and part of the substrate 701. The part of the substrate 701 functions as a region (a semiconductor region 447) including a channel formation region, a source region (one of a low-resistance region 449a and a low-resistance region 449b), and a drain region (the other of the low-resistance region 449a and the low-resistance region 449b) of the transistor 431. Note that the transistor 431 may be a p-channel transistor or an n-channel transistor.

In the case where a single crystal silicon substrate is used as the substrate 701, the transistor 431 is a transistor including silicon in a channel formation region (also referred to as a “Si transistor”).

The transistor 431 is electrically isolated from other transistors by an element isolation layer 403. FIG. 18 illustrates the case where the transistor 431 is electrically isolated from other transistors by the element isolation layer 403. The element isolation layer 403 can be formed by a LOCOS (LOCal Oxidation of Silicon) method, an STI (Shallow Trench Isolation) method, or the like.

Here, in the transistor 431, the semiconductor region 447 has a projecting shape. Moreover, the conductor 443 is provided to cover the side surface and the top surface of the semiconductor region 447 with the insulator 445 placed therebetween. Note that FIG. 18 does not illustrate the state where the conductor 443 covers the side surface of the semiconductor region 447. A material adjusting the work function can be used for the conductor 443.

A transistor having a projecting semiconductor region, like the transistor 431, can be referred to as a fin-type transistor because the projecting portion of a semiconductor substrate is utilized. An insulator having a function of a mask for forming the projecting portion may be provided in contact with an upper portion of the projecting portion. Although FIG. 18 illustrates the structure in which the projecting portion is formed by processing part of the substrate 701, a semiconductor having a projecting shape may be formed by processing an SOI substrate.

Note that the structure of the transistor 431 illustrated in FIG. 18 is an example; the structure of the transistor 431 is not limited thereto and can be changed as appropriate in accordance with the circuit configuration, an operation method for the circuit, or the like. For example, the transistor 431 may be a planar transistor.

An insulator 405, an insulator 407, an insulator 409, and an insulator 411 are provided over the substrate 701, in addition to the element isolation layer 403 and the transistor 431. A conductor 451 is embedded in the insulator 405, the insulator 407, the insulator 409, and the insulator 411. Here, the top surface of the conductor 451 and the top surface of the insulator 411 can be substantially level with each other.

An insulator 421 and an insulator 422 are provided over the conductor 451 and the insulator 411. A conductor 453 is embedded in the insulator 421 and the insulator 422. Here, the top surface of the conductor 453 and the top surface of the insulator 422 can be substantially level with each other.

An insulator 423 is provided over the conductor 453 and the insulator 422. A conductor 455 is embedded in the insulator 423. Here, the top surface of the conductor 455 and the top surface of the insulator 423 can be substantially level with each other.

Note that the layer 10 may be a multilayer wiring layer in which an insulator, a conductor, and the like are stacked, as necessary, for example.

### [Layer 20]

The layer 20 includes a substrate 702, and a transistor 441 and a transistor 442 are provided over the substrate 702. The transistor 441 is, for example, a transistor included in the display portion driver circuit 23. The transistor 442 is, for example, a transistor included in the storage unit driver circuit 24.

A single crystal semiconductor substrate such as a single crystal silicon substrate can be used as the substrate 702, like the substrate 701. Note that a semiconductor substrate other than a single crystal semiconductor substrate may be used as the substrate 702. The layer 20 can have a structure similar to that of the layer 10. Thus, detailed description of the layer 20 is omitted here.

In FIG. 18, the transistor 442 in the layer 20 is electrically connected to the transistor 431 in the layer 10 through the conductor 456. The conductor 456 functions as a TSV. Note that the layer 10 and the layer 20 may be electrically connected to each other through a bump or the like.

The layer 20 includes a conductor 760. The conductor 760 is a conductor included in the terminal portion 29. FIG. 18 illustrates an example in which the conductor 760 is electrically connected to an FPC 716 (Flexible Printed Circuit) with an anisotropic conductor 780 placed therebetween. A variety of signals or the like are supplied to the semiconductor device 100A through the FPC 716.

The conductor 760 is electrically connected to a conductor 347 included in the layer 20 through a conductor 353, a conductor 355, and a conductor 357. Although FIG. 18 illustrates three conductors, which are the conductor 353, the conductor 355, and the conductor 357, as conductors electrically connecting the conductor 760 and the conductor 347, one embodiment of the present invention is not limited thereto. The number of the conductors electrically connecting the conductor 760 to the conductor 347 may be one, two, four or more. Providing a plurality of conductors electrically connecting the conductor 760 and the conductor 347 can reduce the contact resistance.

### [Layer 30]

The layer 30 is provided over the layer 20. The layer 30 includes the insulator 214 and a transistor 750 is provided over the insulator 214. The transistor 750 is, for example, a transistor in the pixel circuit 51. An OS transistor can be suitably used as the transistor 750. The OS transistor has a feature of extremely low off-state current. Consequently, the retention time for image data or the like can be increased, so that the frequency of the refresh operation can be reduced. Thus, the power consumption of the semiconductor device 100A can be reduced.

A conductor 301 (a conductor 301a and a conductor 301b) is embedded in the insulator 254, the insulator 280, the insulator 274, and the insulator 281. The conductor 301a is electrically connected to one of a source and a drain of the transistor 750, and the conductor 301b is electrically connected to the other of the source and the drain of the transistor 750. Here, the top surfaces of the conductor 301a and the conductor 301b and the top surface of the insulator 281 can be substantially level with each other.

A conductor 311, a conductor 313, a conductor 331, a capacitor 790, a conductor 333, and a conductor 335 are embedded in the insulator 361. The conductor 311 and the conductor 313 are electrically connected to the transistor 750 and have a function of a wiring. The conductor 333 and the conductor 335 are electrically connected to the capacitor 790. Here, the top surfaces of the conductor 331, the conductor 333, and the conductor 335 and the top surface of the insulator 361 can be substantially level with each other.

A conductor 341, a conductor 343, and a conductor 351 are embedded in the insulator 363. Here, the top surface of the conductor 351 and the top surface of the insulator 363 can be substantially level with each other.

The insulator 405, the insulator 407, the insulator 409, the insulator 411, the insulator 421, the insulator 422, the insulator 423, the insulator 214, the insulator 280, the insulator 274, the insulator 281, the insulator 361, and the insulator 363 each have a function of an interlayer film and may also have a function of a planarization film that covers unevenness thereunder. For example, the top surface of the insulator 363 may be planarized by planarization treatment using a chemical mechanical polishing (CMP) method or the like to have the increased planarity.

As illustrated in FIG. 18, the capacitor 790 includes a lower electrode 321 and an upper electrode 325. An insulator 323 is provided between the lower electrode 321 and the upper electrode 325. In other words, the capacitor 790 has a stacked-layer structure in which the insulator 323 functioning as a dielectric is provided between the pair of electrodes. Although FIG. 18 illustrates the example in which the capacitor 790 is provided over the insulator 281, the capacitor 790 may be provided over an insulator different from the insulator 281.

In the example illustrated in FIG. 18, the conductor 301a and the conductor 301b are formed in the same layer. In the illustrated example, the conductor 311, the conductor 313, and the lower electrode 321 are formed in the same layer. In the illustrated example, the conductor 331, the conductor 333, and the conductor 335 are formed in the same layer. In the illustrated example, the conductor 341 and the conductor 343 are formed in the same layer. In the illustrated example, the conductor 353, the conductor 355, and the conductor 357 are formed in the same layer. Forming a plurality of conductors in the same layer simplifies the manufacturing process of the semiconductor device 100A and can reduce the manufacturing cost of the semiconductor device 100A. Note that these conductors may be formed in different layers or may contain different types of materials.

### [Layer 60]

The layer 60 is provided over the layer 30. The layer 60 includes the light-emitting element 61. The light-emitting element 61 includes the conductor 772, the EL layer 786, and the conductor 788. The EL layer 786 contains an organic compound or an inorganic compound such as quantum dots.

Examples of materials that can be used as an organic compound include a fluorescent material and a phosphorescent material. Examples of materials that can be used as quantum dots include a colloidal quantum dot material, an alloyed quantum dot material, a core-shell quantum dot material, and a core quantum dot material.

The conductor 772 is electrically connected to the other of the source and the drain of the transistor 750 through the conductor 351, the conductor 341, the conductor 331, the conductor 313, and the conductor 301b. The conductor 772 is formed over the insulator 363 and has a function of a pixel electrode.

A material that transmits visible light or a material that reflects visible light can be used for the conductor 772. As a light-transmitting material, for example, an oxide material containing indium and zinc; an oxide material containing indium, gallium, and zinc (also referred to as “IGZO”); an oxide material containing indium and tin (also referred to as “ITO”); an oxide material containing indium, tin, and silicon (also referred to as “ITSO”), or the like may be used. As a reflective material, for example, a material containing aluminum, silver, or the like may be used.

For example, in the case where light emitted from the light-emitting element 61 is emitted from the conductor 788 side, the conductor 772 preferably includes a reflective material. For example, the conductor 772 may have a single-layer structure or a stacked-layer structure of a plurality of layers. For example, in the case where the conductor 772 is used as an anode, a three-layer structure in which silver is sandwiched between two layers of ITO may be provided.

In the case where silicon nitride is included in a formation surface to be in contact with the conductor 772, the conductor 772 may have a three-layer structure in which aluminum, titanium oxide, and ITO (or ITSO) are stacked in this order over the formation surface. Alternatively, in the case where silicon nitride is included in a formation surface to be in contact with the conductor 772, the conductor 772 may have a two-layer structure in which aluminum and IGZO are stacked in this order over the formation surface.

Note that the conductor 301, the conductor 331, the conductor 351, the conductor 353, the conductor 355, the conductor 357, the conductor 453, the conductor 456, the conductor 760, and the like may have the same structure as a conductor 245 described in another embodiment. For example, the conductor 351 electrically connected to the light-emitting element 61 may be a conductor containing tungsten and titanium nitride. Specifically, a structure in which a side surface of the insulator 363 is adjacent to tungsten with titanium nitride placed therebetween may be employed.

Although not illustrated in FIG. 18, an optical member (optical substrate) such as a polarizing member, a retardation member, or an anti-reflection member can be provided in the semiconductor device 100A, for example.

In the semiconductor device 100A illustrated in FIG. 18, the light-emitting element 61 can be a light-emitting element having a top-emission structure in which a reflective material is used for the conductor 772, a light-transmitting material is used for the conductor 788, and thereby light is emitted to the conductor 788 side. Note that the light-emitting element 61 may have a bottom-emission structure in which light is emitted to the conductor 772 side or a dual-emission structure in which light is emitted towards both the conductor 772 and the conductor 788. In addition, a structure body 778 is provided.

### [Sealing Substrate 40]

The sealing substrate 40 is provided above the layer 30 to cover the display portion 31 and the layer 60. The sealing substrate 40 is bonded to the layer 30 with the sealing material 712 (also referred to as a “sealant”). In the case where the light-emitting element 61 has a top-emission structure or a dual emission structure, a light-transmitting material is used for the sealing substrate 40.

Providing the sealing substrate 40 can prevent entry of impurities into the layer 60, and thus, the reliability of the semiconductor device 100A can be increased.

The light-blocking layer 738 is provided on the layer 60 side. The light-blocking layer 738 has a function of blocking light emitted from adjacent regions. In addition, the light-blocking layer 738 has a function of preventing external light from reaching the transistor 750 or the like.

The light-blocking layer 738 is covered with the insulator 734. The insulator 734 is provided as needed. Although a solid sealing structure in which a filler layer 732 is provided between the light-emitting element 61 and the insulator 734 in this embodiment, a hollow sealing structure in which the filler layer 732 is not provided may be employed. In the case where the semiconductor device 100A has a hollow sealing structure, a portion corresponding to the filler layer 732 may be filled with an impurity gas containing a Group 18 element (a rare gas (noble gas)) and/or nitrogen. In the case where light emitted from the light-emitting element 61 is emitted toward the sealing substrate 40 side, a material having a light-transmitting property is preferably used for the filler layer 732.

Note that a transistor including any of various semiconductors can be used as the transistor included in the semiconductor device of one embodiment of the present invention. For example, a transistor including a single crystal semiconductor, a polycrystalline semiconductor, a microcrystalline semiconductor, or an amorphous semiconductor in a channel formation region can be used. Furthermore, a compound semiconductor (e.g., SiGe or GaAs) or an oxide semiconductor can be used, as well as a single-element semiconductor including mainly a single element.

Note that as the transistor included in the semiconductor device of one embodiment of the present invention, a transistor with any of a variety of structures can be used. For example, a transistor having any of a variety of structures such as a planar type, a FIN-type, a TRI-GATE type, a top-gate type, a bottom-gate type, and a double-gate type (with gates placed above and below a channel) can be used. A MOS transistor, a junction transistor, a bipolar transistor, or the like can be used as the transistor of one embodiment of the present invention.

### Variation Example 1

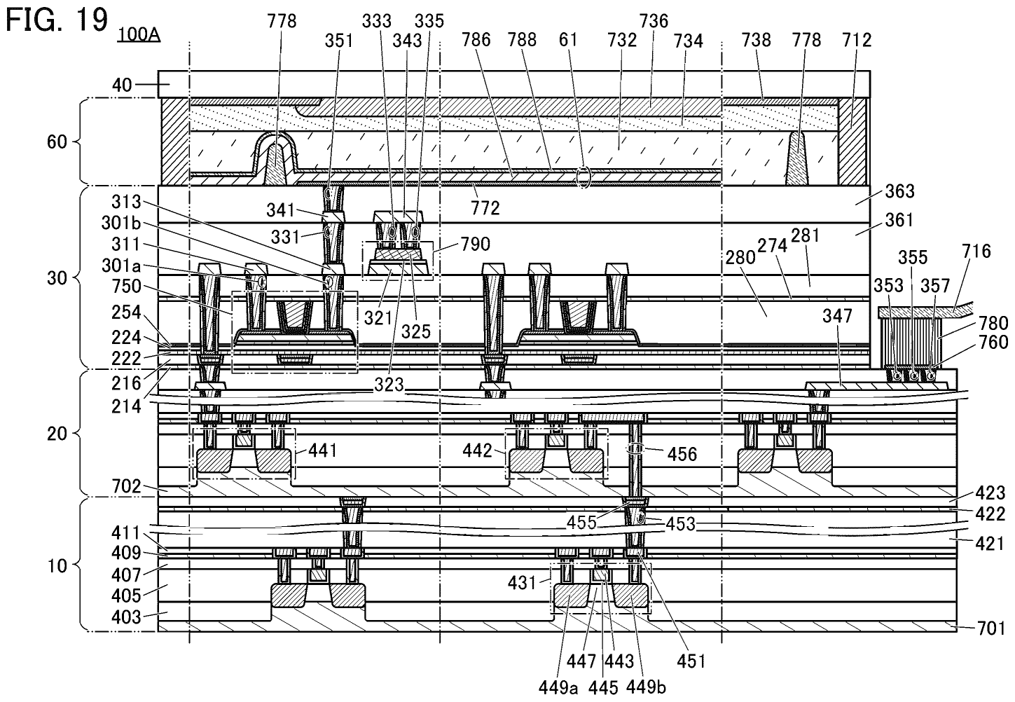

FIG. 19 illustrates a variation example of the semiconductor device 100A illustrated in FIG. 18. The semiconductor device 100A illustrated in FIG. 19 is different from the semiconductor device 100A illustrated in FIG. 18 in that a coloring layer 736 is provided. Note that the coloring layer 736 is provided to have a region overlapping with the light-emitting element 61. Providing the coloring layer 736 can improve the color purity of light extracted from the light-emitting element 61. Thus, the semiconductor device 100A can display high-quality images. Furthermore, all the light-emitting elements 61, for example, in the semiconductor device 100A can be light-emitting elements that emit white light; hence, the EL layers 786 are not necessarily formed so as to correspond to each color, leading to higher definition of the semiconductor device 100A.

The light-emitting element 61 can have a micro optical resonator (microcavity) structure. Thus, light of predetermined colors (e.g., RGB) can be extracted without a coloring layer, and the semiconductor device 100A can perform color display. The structure without a coloring layer can prevent light absorption by the coloring layer. As a result, the semiconductor device 100A can display high-luminance images, and power consumption of the semiconductor device 100A can be reduced. A structure in which a coloring layer is not provided can be employed even when the EL layer 786 is formed into an island shape for each pixel or into a stripe shape for each pixel column, i.e., the EL layers 786 are formed separately so as to correspond to each color. Note that the luminance of the semiconductor device 100A can be, for example, higher than or equal to 500 cd/m² and lower than or equal to 20000 cd/m², preferably higher than or equal to 1000 cd/m² and lower than or equal to 20000 cd/m², further preferably higher than or equal to 5000 cd/m² and lower than or equal to 20000 cd/m².

### <<Semiconductor Device 100C>>

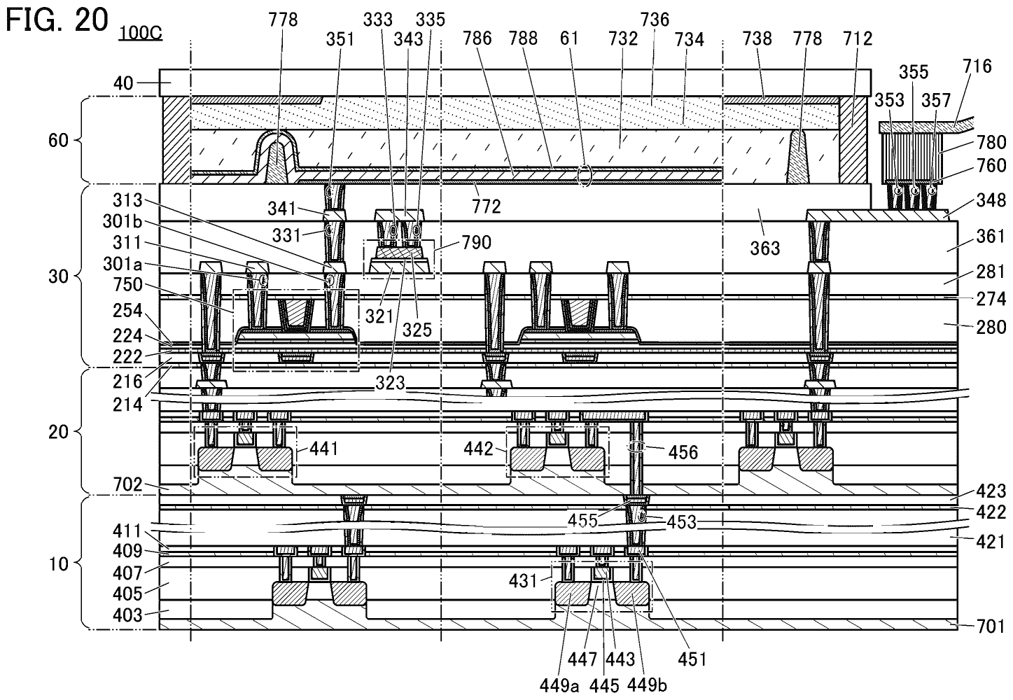

FIG. 20 illustrates a cross-sectional structure example of the semiconductor device 100C, which is a variation example of the semiconductor device 100A. In the cross-sectional structure example of the semiconductor device 100C illustrated in FIG. 20, a conductor 348 is provided over the insulator 361 included in the layer 30 instead of the conductor 347.

The conductor 348 is electrically connected to the conductor 760 through the conductor 353, the conductor 355, and the conductor 357. The conductor 348 functions like the conductor 347.

### Variation Example 1

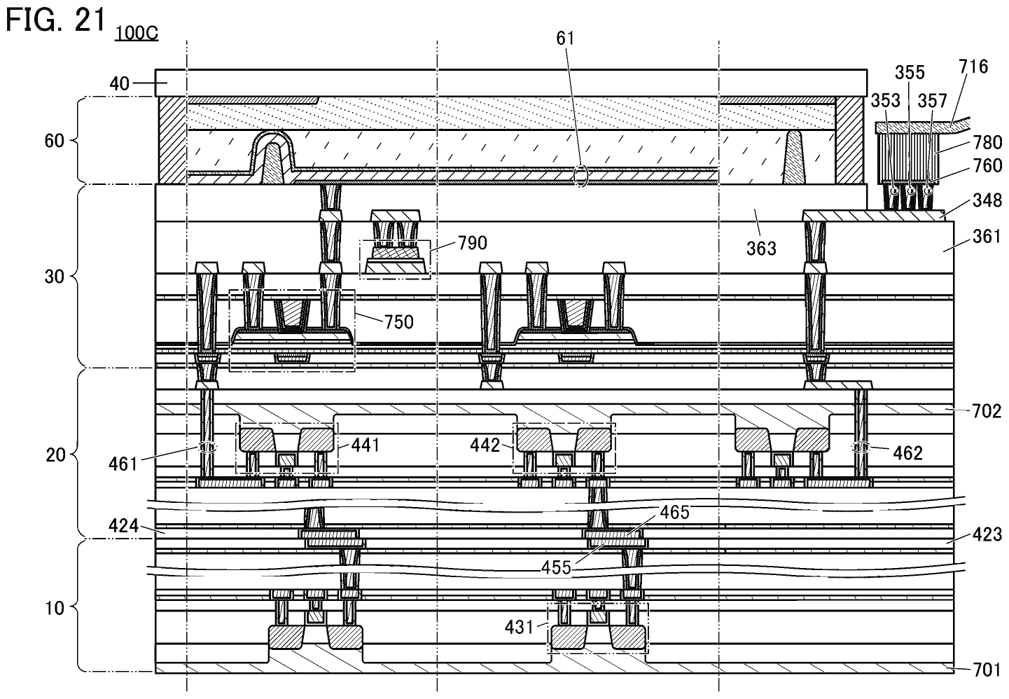

FIG. 21 illustrates a cross-sectional structure example in which the layer 30 overlaps with the layer 10 with the layer 20 placed therebetween. FIG. 21 illustrates a variation example of the semiconductor device 100C. In FIG. 21, the layer 20 is provided over and overlap with the layer 10 so that the transistor included in the layer 20 and the transistor included in the layer 10 can face each other. The layer 30 is provided on the substrate 702 side in the layer 20.

The conductor included in the layer 10 and the conductor included in the layer 20 can be electrically connected to each other by Cu—Cu bonding, for example. In FIG. 21, for example, the conductor 455 included in the layer 10 and the conductor 465 included in the layer 20 are electrically connected to each other by Cu—Cu bonding. In that case, the conductor 455 and the conductor 465 are formed using conductors containing Cu (copper). Preferably, the insulator 423 in which the conductor 455 is embedded and the insulator 424 in which the conductor 465 is embedded are both insulators containing the same element. For example, the insulator 423 and the insulator 424 may be silicon oxide or silicon oxynitride. When the insulator 423 and the insulator 424 are insulators containing the same element, the bonding strength of the layer 10 and the layer 20 increases. Before the layer 10 and the layer 20 are bonded to each other, the planarity of surfaces of the layers is preferably improved by performing CMP treatment on the surfaces to be bonded of the layers.

Note that the bonding position between the conductor 455 and the conductor 465 completely matches with each other or not, depending on the positional alignment in bonding. The case where the conductor 455 and the conductor 465 does not completely match with each other is illustrated in FIG. 21.

In FIG. 21, the conductor included in the layer 20 and the conductor included in the layer 30 may be electrically connected to each other through a TSV. For example, the conductor 461 and the conductor 462 included in the layer 20 are both TSVs that penetrate through the substrate 702.

### Variation Example 2

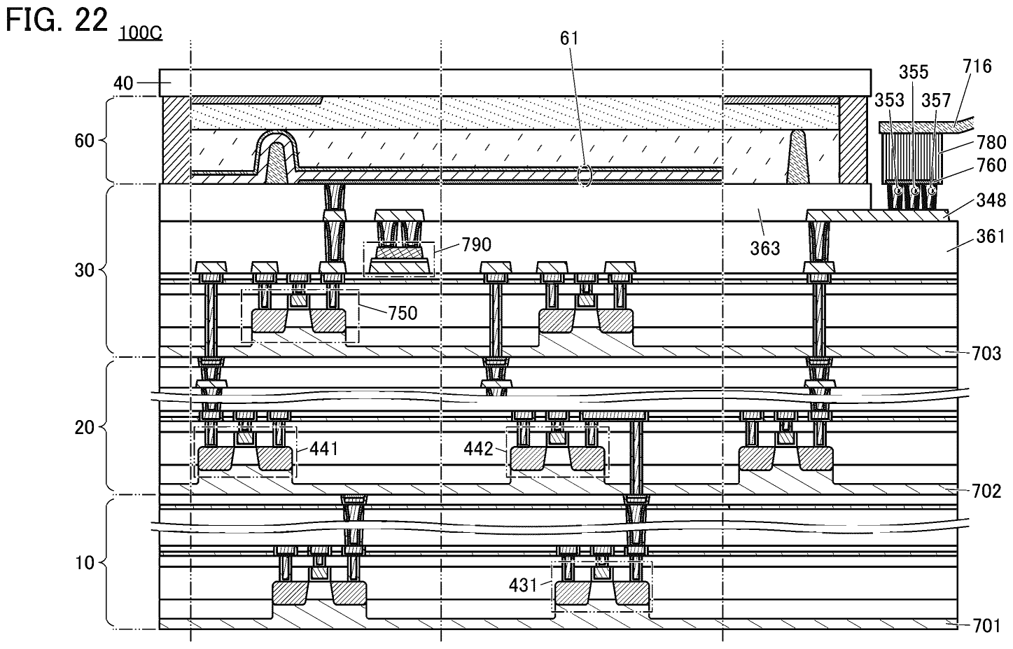

FIG. 22 illustrates a variation example of the semiconductor device 100C. In the cross-sectional structure example in FIG. 22, the transistors included in the layer 30 are Si transistors. In FIG. 22, the layer 30 includes a substrate 703, and the transistor 750 is provided over the substrate 703. The substrate 703 is, for example, a single crystal silicon substrate. Accordingly, the transistor 750 illustrated in FIG. 22 includes single crystal silicon in a semiconductor layer where a channel is formed. Note that a substrate similar to the substrate 701 and the substrate 702 can be used as the substrate 703. The layer 30 in the semiconductor device 100C illustrated in FIG. 22 includes, in addition to components similar to those of the layer 20, the insulator 361, the insulator 363, the conductor 348, the capacitor 790, and the like.

Also in the semiconductor device 100A, the semiconductor device 100B, the semiconductor device 100D to the semiconductor device 100G, transistors (e.g., a Si transistor) other than OS transistors may be used for the transistors included in the layer 30. As the transistors included in the layer 10, the layer 20, and the layer 30, any of various transistors can be used depending on the purpose or usage.

### Variation Example 3

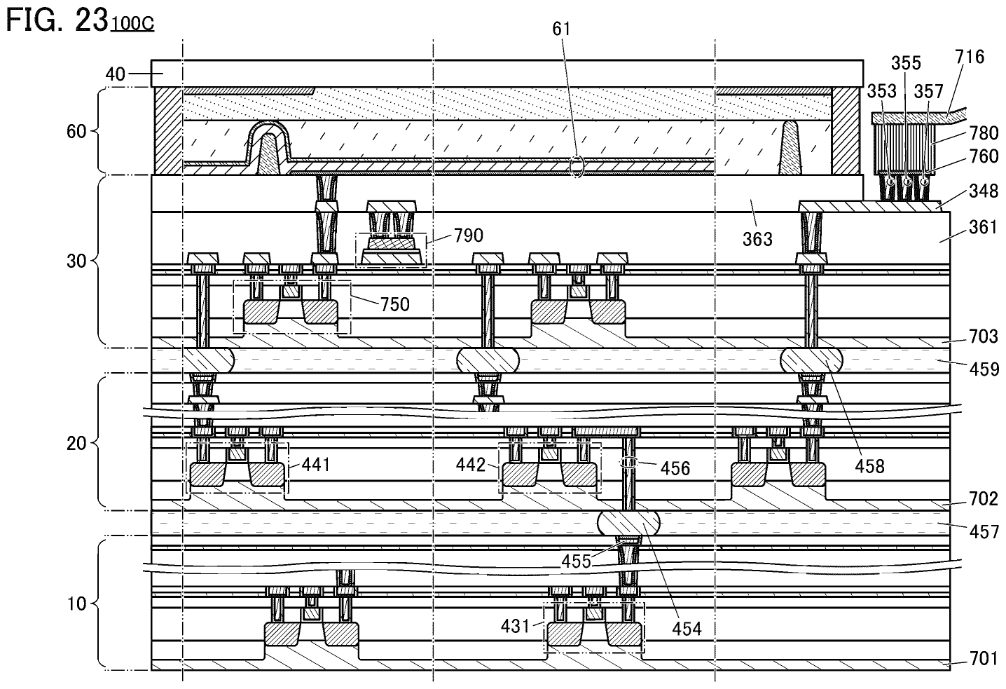

As illustrated in FIG. 23, a bump 454 and an adhesive layer 457 may be provided between the layer 10 and the layer 20. The layer 10 and the layer 20 are fixed by the adhesive layer 457 and electrically connected to each other by the bump 454. In FIG. 23, the conductor 456 and the conductor 455 are electrically connected to each other through the bump 454. Similarly, a bump 458 and an adhesive layer 459 may be provided between the layer 20 and the layer 30. The layer 20 and the layer 30 are fixed to each other with the adhesive layer 459 and electrically connected to each other by the bump 458. Note that the number of the bumps 454 electrically connecting the layer 10 and the layer 20 to each other is not limited to one, and may be more than one. The number of the bumps 458 electrically connecting the layer 20 and the layer 30 to each other is not limited to one, and may be more than one.

### <<Semiconductor Device 100H>>

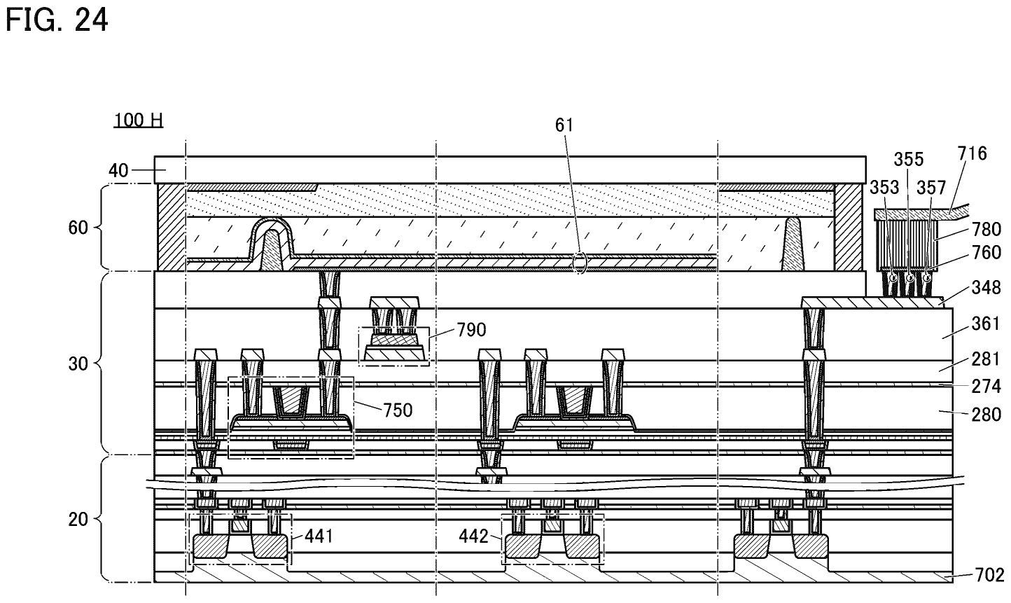

FIG. 24 illustrates a cross-sectional structure example of the semiconductor device 100H, which is a variation example of the semiconductor device 100C. FIG. 24 corresponds to a cross-sectional structure in which the layer 10 is removed from the cross-sectional structure example of the semiconductor device 100C illustrated in FIG. 20. Since the semiconductor device 100H does not include the layer 10, a component such as the conductor 456 for electrically connecting the layer 10 and the layer 20, does not need to be provided.

### Variation Example 1

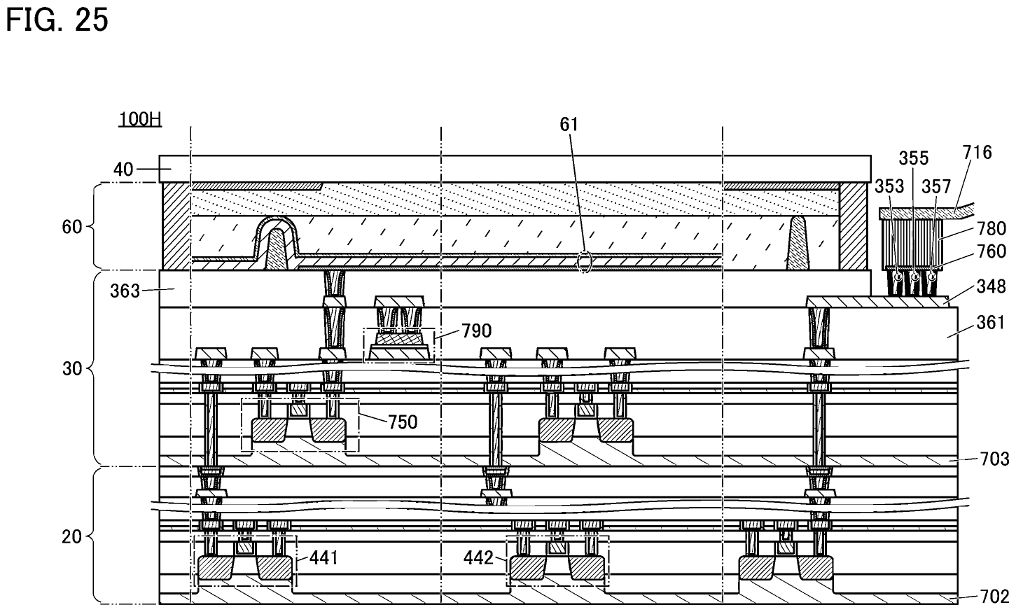

FIG. 25 illustrates a variation example of the semiconductor device 100H. In the cross-sectional structure example in FIG. 25, the transistors included in the layer 30 are Si transistors. The layer 30 in FIG. 25 can have a structure similar to that of the layer 30 illustrated in FIG. 22.

### Variation Example 2

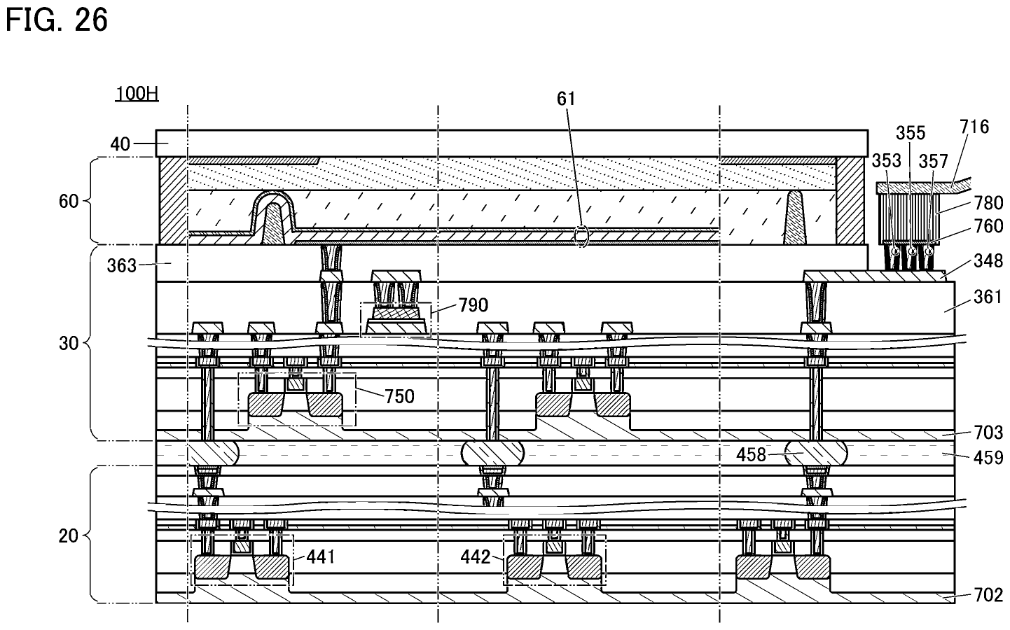

In the case of the structure illustrated in FIG. 25, the bump 458 and the adhesive layer 459 may be provided between the layer 20 and the layer 30 as illustrated in FIG. 26. The layer 20 and the layer 30 are fixed to each other with the adhesive layer 459, and electrically connected to each other by the bump 458. The number of the bumps 458 electrically connecting the layer 20 and the layer 30 to each other is not limited to one, and may be more than one as in the structure example illustrated in FIG. 23.

### Variation Example 3

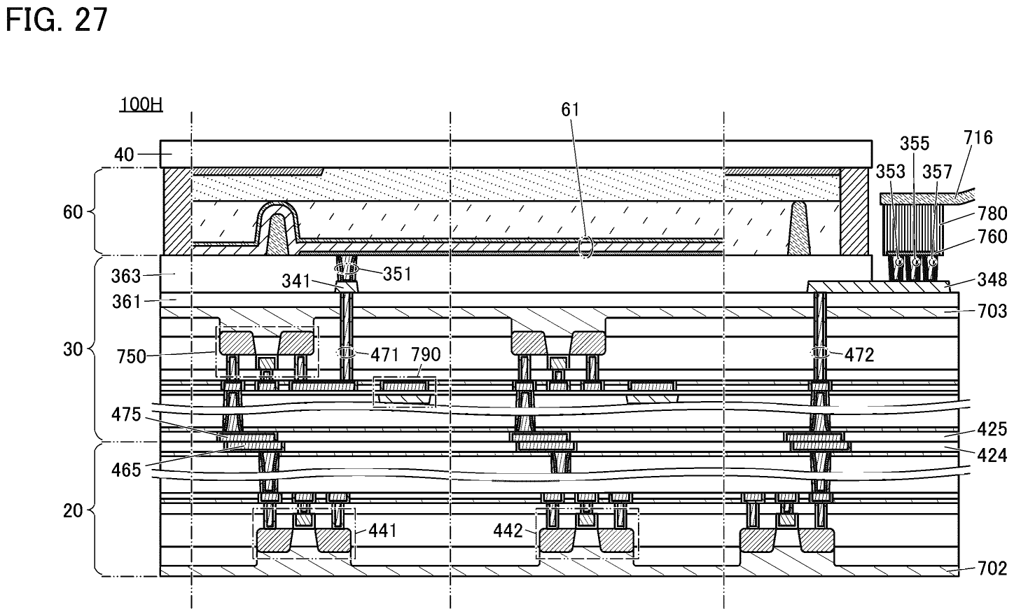

In the case where the transistor included in the layer 30 is a Si transistor, the layer 30 may be provided over and overlap with the layer 20 so that the transistor included in the layer 30 the transistor included in the layer 20 can face each other (see FIG. 27). In the layer 30 illustrated in FIG. 27, the insulator 361 and the insulator 363 are provided over the substrate 703. The conductor 348 is provided over the insulator 361. In addition, the conductor 341 and the conductor 351 are embedded in the insulator 363.

The conductor included in the layer 20 and the conductor included in the layer 30 can be electrically connected to each other by Cu—Cu bonding, for example. In FIG. 27, for example, the conductor 465 included in the layer 20 and the conductor 475 included in the layer 30 are electrically connected to each other by Cu—Cu bonding. In that case, the conductor 465 and the conductor 475 are formed using conductors containing Cu (copper). Preferably, the insulator 424 in which the conductor 465 is embedded and the insulator 425 in which the conductor 475 is embedded are both insulators containing the same element. For example, the insulator 424 and the insulator 425 may be silicon oxide or silicon oxynitride. When the insulator 424 and the insulator 425 are insulators containing the same element, the bonding strength of the layer 20 and the layer 30 is increased. Before the layer 20 and the layer 30 are bonded to each other, the planarity of surfaces of the layers is preferably improved by performing CMP treatment on the surfaces to be bonded of the layers.

Note that the bonding position between the conductor 465 and the conductor 475 completely matches with each other or not, depending on the positional alignment in bonding. The case where the conductor 465 and the conductor 475 does not completely match with each other is illustrated in FIG. 27.

In FIG. 27, a TSV may be provided for the layer 30. The conductor 471 and the conductor 472 in FIG. 27 are both TSVs that penetrate through the substrate 703. In FIG. 27, the conductor 471 is electrically connected to the conductor 341. The conductor 472 is electrically connected to the conductor 348.

### <<Semiconductor Device 100I>>

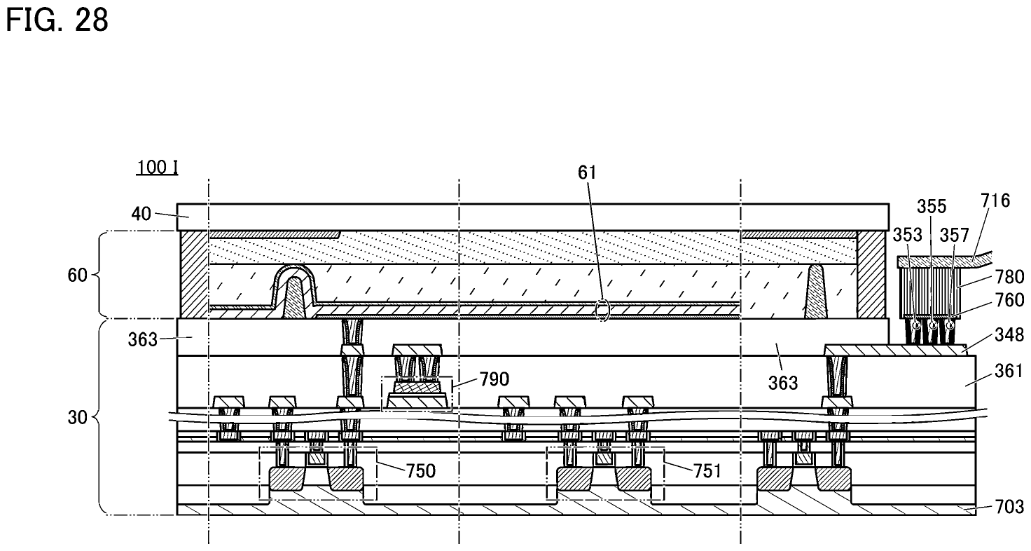

FIG. 28 illustrates a cross-sectional structure example of the semiconductor device 100I. The semiconductor device 100I illustrated in FIG. 28 is a variation example of the semiconductor device 100H illustrated in FIG. 25. Accordingly, FIG. 28 illustrates a cross-sectional structure example of the case where Si transistors are used for the transistors included in the layer 30.

As described in the above embodiment, the semiconductor device 100I includes the display portion driver circuit 23 and the pixel circuit 51 in the layer 30. The transistor 750 in FIG. 28 is a transistor included in the pixel circuit 51, for example. The transistor 751 in FIG. 28 is, for example, a transistor included in the display portion driver circuit 23.

A functional circuit necessary for the layer 30 may be formed depending on the purpose and/or the usage. An unnecessary functional circuit is not provided depending on the purpose and/or the usage, whereby power consumption and manufacturing cost of the semiconductor device can be reduced. Furthermore, the thickness of the semiconductor device can be reduced, and thus the weight of the semiconductor device can be reduced.

The structures described in this embodiment can be used in an appropriate combination with any of the structures described in the other embodiments and the like.

### Embodiment 5

In this embodiment, the light-emitting element 61 (also referred to as “light-emitting device”) is described.

### <Structure Example of Light-Emitting Element>

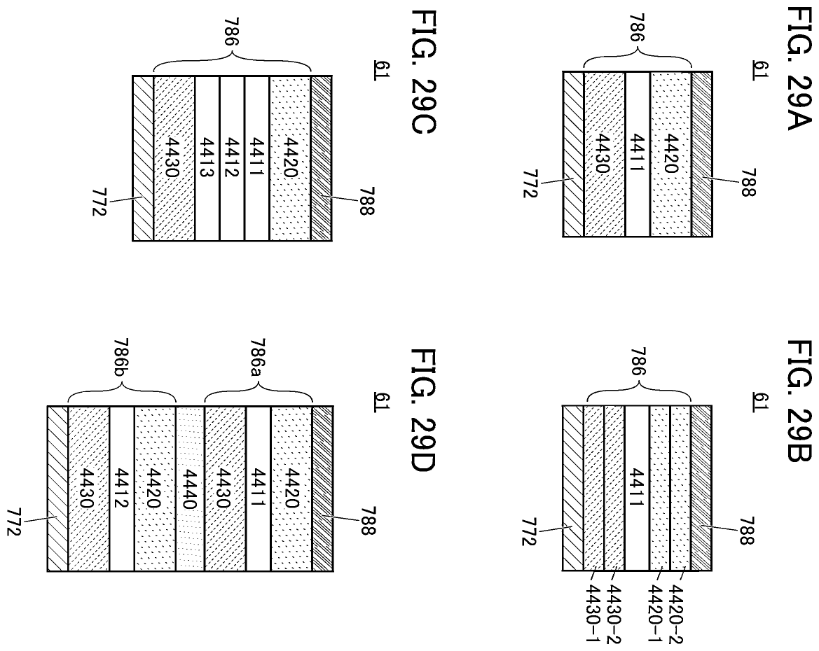

As illustrated in FIG. 29A, the light-emitting element 61 includes the EL layer 786 between a pair of electrodes (the conductor 772 and the conductor 788). The EL layer 786 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between the pair of electrodes, can serve as a single light-emitting unit, and the structure in FIG. 29A is referred to as a single structure in this specification and the like.

FIG. 29B illustrates a variation example of the EL layer 786 included in the light-emitting element 61 illustrated in FIG. 29A. Specifically, the light-emitting element 61 illustrated in FIG. 29B includes a layer 4430-1 over the conductor 772, a layer 4430-2 over the layer 4430-1, the light-emitting layer 4411 over the layer 4430-2, a layer 4420-1 over the light-emitting layer 4411, a layer 4420-2 over the layer 4420-1, and the conductor 788 over the layer 4420-2. For example, when the conductor 772 functions as an anode and the conductor 788 functions as a cathode, the layer 4430-1 functions as a hole-injection layer, the layer 4430-2 functions as a hole-transport layer, the layer 4420-1 functions as an electron-transport layer, and the layer 4420-2 functions as an electron-injection layer. Alternatively, when the conductor 772 functions as a cathode and the conductor 788 functions as an anode, the layer 4430-1 functions as an electron-injection layer, the layer 4430-2 functions as an electron-transport layer, the layer 4420-1 functions as a hole-transport layer, and the layer 4420-2 functions as a hole-injection layer. With such a layer structure, carriers can be efficiently injected to the light-emitting layer 4411, and the efficiency of the recombination of carriers in the light-emitting layer 4411 can be enhanced.

Note that the structure in which a plurality of light-emitting layers (the light-emitting layer 4411, a light-emitting layer 4412, and a light-emitting layer 4413) are provided between the layer 4420 and the layer 4430 as illustrated in FIG. 29C is also an example of the single structure.

The structure in which a plurality of light-emitting units (an EL layer 786a and an EL layer 786b) are connected in series with an intermediate layer (charge-generation layer) 4440 placed therebetween as illustrated in FIG. 29D is referred to as a tandem structure or a stack structure in this specification and the like. The tandem structure enables a light-emitting element capable of high luminance light emission.

In the case where the light-emitting element 61 has the tandem structure illustrated in FIG. 29D, the EL layer 786a and the EL layer 786b may emit light of the same color. For example, emission colors of both the EL layer 786a and the EL layer 786b may be green. Note that when the display portion 31 includes three subpixels of R, G, and B and the subpixels each include a light-emitting element, the light-emitting element of each subpixel may have a tandem structure. Specifically, the EL layer 786a and the EL layer 786b in the subpixel of R each contain a material capable of emitting red light, the EL layer 786a and the EL layer 786b in the subpixel of G each contain a material capable of emitting green light, and the EL layer 786a and the EL layer 786b in the subpixel of B each contain a material capable of emitting blue light. In other words, the light-emitting layer 4411 and the light-emitting layer 4412 may contain the same material. When the emission colors of the EL layer 786a and the EL layer 786b are the same color, the current density per unit emission luminance can be reduced. Thus, the reliability of the light-emitting element 61 can be increased.

The emission color of the light-emitting element can be red, green, blue, cyan, magenta, yellow, white, or the like depending on the material that constitutes the EL layer 786. Furthermore, the color purity can be further increased when the light-emitting element has a microcavity structure.

The light-emitting layer may contain two or more light-emitting substances that emit light of red (R), green (G), blue (B), yellow (Y), orange (O), or the like. The light-emitting element that emits white light (also referred to as “white light-emitting device”) preferably contains two or more kinds of light-emitting substances in the light-emitting layer. To obtain white light emission, two or more kinds of light-emitting substances are selected such that their emission colors are complementary. For example, when the emission color of a first light-emitting layer and the emission color of a second light-emitting layer have a relationship of complementary colors, it is possible to obtain the light-emitting element which emits white light as a whole. This can apply to a light-emitting element including three or more light-emitting layers.

The light-emitting layer preferably contains two or more light-emitting substances that emit light of red (R), green (G), blue (B), yellow (Y), orange (O), or the like. Alternatively, the light-emitting layer preferably contains two or more light-emitting substances that each emit light containing two or more of spectral components of R, G, and B.

### <Formation Method of Light-Emitting Element 61>

A method for forming the light-emitting element 61 is described below.

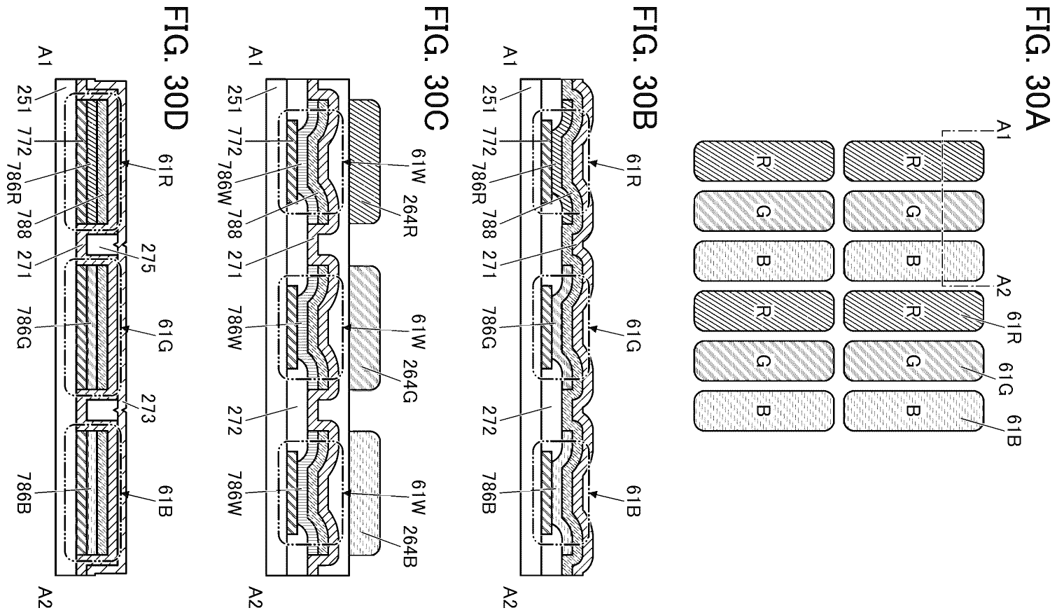

FIG. 30A illustrates a schematic top view of the light-emitting element 61. The light-emitting element 61 includes a plurality of light-emitting elements 61R exhibiting red, a plurality of light-emitting elements 61G exhibiting green, and a plurality of light-emitting elements 61B exhibiting blue. In FIG. 30A, light-emitting regions of the light-emitting elements are denoted by R, G, and B to easily differentiate the light-emitting elements. Note that the structure of the light-emitting element 61 illustrated in FIG. 30A may be referred to as an SBS (Side By Side) structure. Although the structure illustrated in FIG. 30A has three colors of red (R), green (G), and blue (B), one embodiment of the present invention is not limited thereto. For example, the structure may have four or more colors.

The light-emitting elements 61R, the light-emitting elements 61G, and the light-emitting elements 61B are arranged in a matrix. FIG. 30A illustrates what is called a stripe arrangement, in which the light-emitting elements of the same color are arranged in one direction. Note that the arrangement method of the light-emitting elements is not limited thereto; another arrangement method such as a delta arrangement, a zigzag arrangement, or a PenTile arrangement may also be used.

As the light-emitting element 61R, the light-emitting element 61G, and the light-emitting element 61B, an organic EL device such as an OLED (Organic Light Emitting Diode) or a QLED (Quantum-dot Light Emitting Diode) is preferably used. As a light-emitting substance contained in the EL element, a substance that emits fluorescence (a fluorescent material), a substance that emits phosphorescence (a phosphorescent material), an inorganic compound (e.g., a quantum dot material), a substance that exhibits thermally activated delayed fluorescence (a thermally activated delayed fluorescent (TADF) material), and the like can be given.

FIG. 30B is a schematic cross-sectional view taken along dashed-dotted line A1-A2 in FIG. 30A. FIG. 30B illustrates a cross section of the light-emitting element 61R, the light-emitting element 61G, and the light-emitting element 61B. The light-emitting element 61R, the light-emitting element 61G, and the light-emitting element 61B are each provided over an insulating layer 251 and include a conductor 772 functioning as a pixel electrode and a conductor 788 functioning as a common electrode. For the insulating layer 251, one or both of an inorganic insulating film and an organic insulating film can be used. An inorganic insulating film is preferably used as the insulating layer 251. As the inorganic insulating film, for example, an oxide insulating film and a nitride insulating film such as a silicon oxide film, a silicon oxynitride film, a silicon nitride oxide film, a silicon nitride film, an aluminum oxide film, an aluminum oxynitride film, or a hafnium oxide film can be given.

The light-emitting element 61R includes an EL layer 786R between the conductor 772 functioning as a pixel electrode and the conductor 788 functioning as a common electrode. The EL layer 786R contains at least a light-emitting organic compound that emits light with an intensity in a red wavelength range. An EL layer 786G included in the light-emitting element 61G contains at least a light-emitting organic compound that emits light with an intensity in a green wavelength range. An EL layer 786B included in the light-emitting element 61B contains at least a light-emitting organic compound that emits light with an intensity in a blue wavelength range.

The EL layer 786R, the EL layer 786G, and the EL layer 786B may each include one or more of an electron-injection layer, an electron-transport layer, a hole-injection layer, and a hole-transport layer in addition to the layer containing a light-emitting organic compound (the light-emitting layer).

The conductor 772 functioning as a pixel electrode is provided in each of the light-emitting elements. The conductor 788 functioning as a common electrode is provided as a continuous layer shared by the light-emitting elements. A conductive film that transmits visible light is used for either the conductor 772 functioning as a pixel electrode or the conductor 788 functioning as a common electrode, and a reflective conductive film is used for the other. When the conductor 772 functioning as a pixel electrode has a light-transmitting property and the conductor 788 functioning as a common electrode has a reflective property, a bottom-emission display apparatus can be obtained, whereas when the conductor 772 functioning as a pixel electrode has a reflective property and the conductor 788 functioning as a common electrode has a light-transmitting property, a top-emission display apparatus can be obtained. Note that when both the conductor 772 functioning as a pixel electrode and the conductor 788 functioning as a common electrode have a light-transmitting property, a dual-emission display apparatus can be obtained.

An insulating layer 272 is provided to cover end portions of the conductor 772 functioning as a pixel electrode. End portions of the insulating layer 272 are preferably tapered. For the insulating layer 272, a material similar to the material that can be used for the insulating layer 251 can be used.

The EL layer 786R, the EL layer 786G, and the EL layer 786B each include a region in contact with a top surface of the conductor 772 functioning as a pixel electrode and a region in contact with a surface of the insulating layer 272. End portions of the EL layer 786R, the EL layer 786G, and the EL layer 786B are positioned over the insulating layer 272.

As illustrated in FIG. 30B, there is a gap between the EL layers of two light-emitting elements for different colors. In this manner, the EL layer 786R, the EL layer 786G, and the EL layer 786B are preferably provided so as not to be in contact with each other. This suitably prevents unintentional light emission (also referred to as crosstalk) from being caused by a current flowing through two adjacent EL layers. As a result, the contrast can be increased to achieve a display apparatus with high display quality.

The EL layer 786R, the EL layer 786G, and the EL layer 786B can be formed separately by a vacuum evaporation method or the like using a shadow mask such as a metal mask. Alternatively, these layers may be formed separately by a photolithography method. The use of the photolithography method achieves a display apparatus with high resolution, which is difficult to obtain in the case of using a metal mask.

In this specification and the like, a device formed using a metal mask or an FMM (fine metal mask, high-resolution metal mask) is sometimes referred to as a device having an MM (metal mask) structure. In this specification and the like, a device formed without using a metal mask or an FMM is sometimes referred to as a device having an MML (metal maskless) structure.

A protective layer 271 is provided over the conductor 788 functioning as a common electrode so as to cover the light-emitting element 61R, the light-emitting element 61G, and the light-emitting element 61B. The protective layer 271 has a function of preventing diffusion of impurities such as water into the light-emitting elements from above.

The protective layer 271 can have, for example, a single-layer structure or a stacked-layer structure at least including an inorganic insulating film. As the inorganic insulating film, for example, an oxide film or a nitride film such as a silicon oxide film, a silicon oxynitride film, a silicon nitride oxide film, a silicon nitride film, an aluminum oxide film, an aluminum oxynitride film, or a hafnium oxide film can be given. Alternatively, a semiconductor material such as indium gallium oxide or indium gallium zinc oxide (IGZO) may be used for the protective layer 271. Note that the protective layer 271 may be formed by an atomic layer deposition (ALD) method, a chemical vapor deposition (CVD) method, or a sputtering method. Although the protective layer 271 includes an inorganic insulating film in this example, one embodiment of the present invention is not limited thereto. For example, the protective layer 271 may have a stacked-layer structure of an inorganic insulating film and an organic insulating film.

Note that in this specification, a nitride oxide refers to a compound that contains more nitrogen than oxygen. An oxynitride refers to a compound that contains more oxygen than nitrogen. The content of each element can be measured by Rutherford backscattering spectrometry (RBS), for example.

In the case where an indium gallium zinc oxide is used for the protective layer 271, the indium gallium zinc oxide can be processed by a wet etching method or a dry etching method. For example, in the case where IGZO is used as the protective layer 271, a chemical solution of oxalic acid, phosphoric acid, a mixed chemical solution (e.g., a mixed chemical solution of phosphoric acid, acetic acid, nitric acid, and water, which is also referred to as a mixed acid aluminum etchant), or the like can be used. Note that the volume ratio of phosphoric acid, acetic acid, nitric acid, and water mixed in the mixed acid aluminum etchant can be 53.3:6.7:3.3:36.7 or in the neighborhood thereof.

FIG. 30C illustrates an example different from the above. Specifically, in FIG. 30C, light-emitting elements 61W that emit white light are provided. The light-emitting elements 61W each include an EL layer 786W that emits white light between the conductor 772 functioning as a pixel electrode and the conductor 788 functioning as a common electrode.

The EL layer 786W can have, for example, a structure in which two or more light-emitting layers that are selected so as to emit light of complementary colors are stacked. It is also possible to use a stacked EL layer in which a charge-generation layer is provided between light-emitting layers.

FIG. 30C illustrates three light-emitting elements 61W arranged side by side. A coloring layer 264R is provided above the left light-emitting element 61W. The coloring layer 264R functions as a band path filter that transmits red light. Similarly, a coloring layer 264G that transmits green light is provided above the middle light-emitting element 61W, and a coloring layer 264B that transmits blue light is provided above the right light-emitting element 61W. Thus, the display apparatus can display an image with colors.

Here, the EL layer 786W and the conductor 788 functioning as a common electrode are each separated between adjacent two light-emitting elements 61W. This can prevent unintentional light emission from being caused by a current flowing through the EL layers 786W of adjacent two light-emitting elements 61W. Particularly when stacked EL layers in which a charge-generation layer is provided between two light-emitting layers are used as the EL layer 786W, crosstalk is more significant as the resolution increases, i.e., as the distance between adjacent pixels decreases, leading to lower contrast. Thus, the above structure can achieve a display apparatus having both high resolution and high contrast.

The EL layer 786W and the conductor 788 functioning as a common electrode are preferably isolated by a photolithography method. This can decrease the distance between light-emitting elements, achieving a display apparatus with a higher aperture ratio than that formed using, for example, a shadow mask such as a metal mask.

Note that in the case of a bottom-emission light-emitting element, a coloring layer may be provided between the conductor 772 functioning as a pixel electrode and the insulating layer 251.

FIG. 30D illustrates an example different from the above. Specifically, in FIG. 30D, the insulating layers 272 are not provided between the light-emitting element 61R, the light-emitting element 61G, and the light-emitting element 61B. With such a structure, the display apparatus can have a high aperture ratio. The protective layer 271 covers side surfaces of the EL layer 786R, the EL layer 786G, and the EL layer 786B. With this structure, impurities (typically, water) can be inhibited from entering the EL layer 786R, the EL layer 786G, and the EL layer 786B through their side surfaces. In the structure illustrated in FIG. 30D, the top shapes of the conductor 772, the EL layer 786R, and the conductor 788 are substantially the same. This structure can be formed in such a manner that the conductor 772, the EL layer 786R, and the conductor 788 are formed and collectively processed using a resist mask or the like. In this process, the EL layer 786R and the conductor 788 are processed using the conductor 788 as a mask, and thus this process can be called self-alignment patterning. Although the EL layer 786R is described here, the EL layer 786G and the EL layer 786B can each have a similar structure.

In FIG. 30D, a protective layer 273 is further provided over the protective layer 271. For example, the protective layer 271 can be formed with an apparatus that can deposit a film with excellent coverage (typically, an ALD apparatus), and the protective layer 273 can be formed with an apparatus that can deposit a film with coverage inferior to that of the protective layer 271 (typically, a sputtering apparatus), whereby a region 275 can be provided between the protective layer 271 and the protective layer 273. In other words, the regions 275 are positioned between the EL layer 786R and the EL layer 786G and between the EL layer 786G and the EL layer 786B.

Note that the region 275 includes, for example, any one or more selected from air, nitrogen, oxygen, carbon dioxide, and Group 18 elements (typically, helium, neon, argon, xenon, and krypton). Furthermore, for example, a gas used during the deposition of the protective layer 273 is sometimes included in the region 275. For example, in the case where the protective layer 273 is deposited using a sputtering method, any one or more of the above-described Group 18 elements is sometimes included in the region 275. In the case where a gas is included in the region 275, a gas can be identified with a gas chromatography method or the like. Alternatively, in the case where the protective layer 273 is deposited using a sputtering method, a gas used in the sputtering is sometimes contained in the protective layer 273. In this case, an element such as argon is sometimes detected when the protective layer 273 is analyzed by an energy dispersive X-ray analysis (EDX analysis) or the like.

In the case where the refractive index of the region 275 is lower than that of the protective layer 271, light emitted from the EL layer 786R, the EL layer 786G, or the EL layer 786B is reflected at the interface between the protective layer 271 and the region 275. Thus, light emitted from the EL layer 786R, the EL layer 786G, or the EL layer 786B can be inhibited from entering an adjacent pixel in some cases. This can inhibit color mixture of light emitted from adjacent pixels and thus can improve the display quality of the display apparatus.

In the case of the structure illustrated in FIG. 30D, a region between the light-emitting element 61R and the light-emitting element 61G or a region between the light-emitting element 61G and the light-emitting element 61B (hereinafter simply referred to as a distance between the light-emitting elements) can be small. Specifically, the distance between the light-emitting elements can be less than or equal to 1 μm, preferably less than or equal to 500 nm, further preferably less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus includes a region in which an interval between the side surface of the EL layer 786R and the side surface of the EL layer 786G or an interval between the side surface of the EL layer 786G and the side surface of the EL layer 786B is less than or equal to 1 μm, preferably less than or equal to 0.5 μm (500 nm), further preferably less than or equal to 100 nm.

In the case where the region 275 includes a gas, the light-emitting elements can be isolated from each other and color mixing of light or crosstalk between the light-emitting elements can be inhibited.

Alternatively, the region 275 may be filled with a filler. Examples of the filler include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. Alternatively, a photoresist may be used as the filler. The photoresist used as the filler may be a positive photoresist or a negative photoresist.

When the white-light-emitting device (having a single structure or a tandem structure) and a light-emitting device having an SBS structure are compared to each other, the light-emitting device having an SBS structure can have lower power consumption than the white-light-emitting device. To reduce power consumption, a light-emitting device having an SBS structure is preferably used. Meanwhile, the white-light-emitting device is preferable in terms of lower manufacturing cost or higher manufacturing yield because the manufacturing process of the white-light-emitting device is simpler than that of a light-emitting device having an SBS structure.

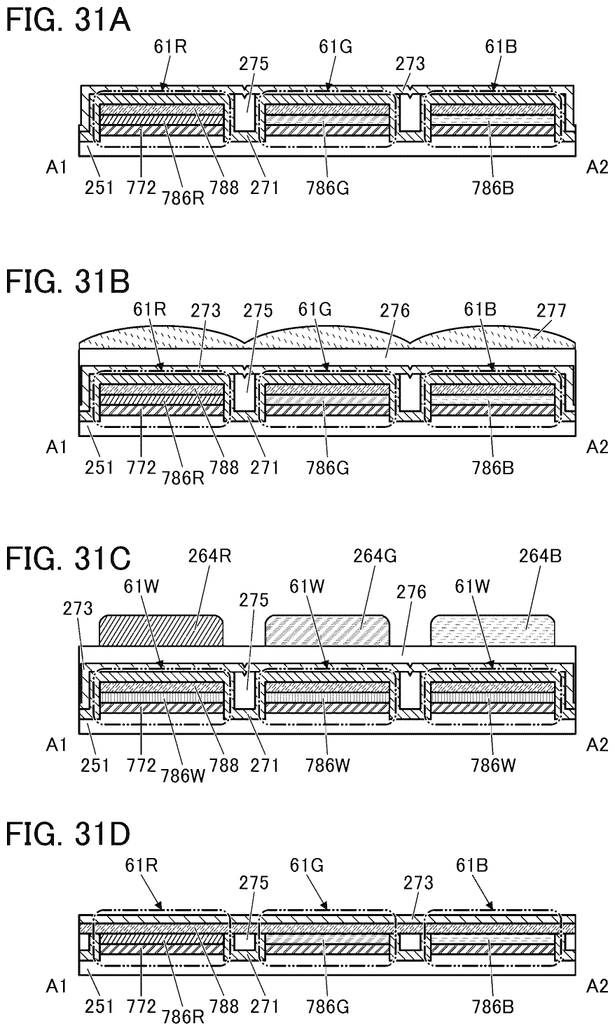

FIG. 31A illustrates an example different from the above. Specifically, the structure illustrated in FIG. 31A is different from the structure illustrated in FIG. 30D in the structure of the insulating layer 251. The insulating layer 251 has a recessed portion in its top surface that is formed by being partially etched when the light-emitting element 61R, the light-emitting element 61G, and the light-emitting element 61B are processed. In addition, the protective layer 271 is formed in the recessed portion. In other words, in the cross-sectional view, a region is provided, in which the bottom surface of the protective layer 271 is positioned below the bottom surface of the conductor 772. With the region, impurities (typically, water or the like) can be suitably inhibited from entering the light-emitting element 61R, the light-emitting element 61G, and the light-emitting element 61B from the bottom. It is likely that the recessed portion can be formed when impurities (also referred to as residue) that could be attached to the side surfaces of the light-emitting element 61R, the light-emitting element 61G, and the light-emitting element 61B in processing of the light-emitting elements are removed by e.g., wet etching. After the residue is removed, the side surfaces of the light-emitting elements are covered with the protective layer 271, whereby a highly reliable display apparatus can be provided.

FIG. 31B illustrates an example different from the above. Specifically, the structure illustrated in FIG. 31B includes an insulating layer 276 and a microlens array 277 in addition to the structure illustrated in FIG. 31A. The insulating layer 276 functions as an adhesive layer. Note that when the refractive index of the insulating layer 276 is lower than that of the microlens array 277, the microlens array 277 can condense light emitted from the light-emitting element 61R, the light-emitting element 61G, and the light-emitting element 61B. This can increase the light extraction efficiency of the display apparatus. In particular, this is suitable, because a user can see bright images when the user sees the display surface from the front of the display apparatus. As the insulating layer 276, a variety of curable adhesives, e.g., a photocurable adhesive such as an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-component resin may be used. An adhesive sheet or the like may be used.

FIG. 31C illustrates an example different from the above. Specifically, the structure illustrated in FIG. 31C includes three light-emitting elements 61W instead of the light-emitting element 61R, the light-emitting element 61G, and the light-emitting element 61B in the structure illustrated in FIG. 31A. In addition, the insulating layer 276 is provided over the three light-emitting elements 61W, and the coloring layer 264R, the coloring layer 264G, and the coloring layer 264B are provided over the insulating layer 276. Specifically, the coloring layer 264R that transmits red light is provided at a position overlapping with the left light-emitting element 61W, the coloring layer 264G that transmits green light is provided at a position overlapping with the middle light-emitting element 61W, and the coloring layer 264B that transmits blue light is provided at a position overlapping with the right light-emitting element 61W. Thus, the semiconductor device can display an image with colors. The structure illustrated in FIG. 31C is also a variation example of the structure illustrated in FIG. 30C.

FIG. 31D illustrates an example different from the above. Specifically, in the structure illustrated in FIG. 31D, the protective layer 271 is provided adjacent to the side surfaces of the conductor 772 and the EL layer 786. The conductor 788 is provided as a continuous layer shared by the light-emitting elements. In the structure illustrated in FIG. 31D, the region 275 is preferably filled with a filler.

Furthermore, the color purity of emitted light can be further increased when the light-emitting element 61 has a microcavity structure. In order that the light-emitting element 61 has a microcavity structure, a product (optical path length) of a distance d between the conductor 772 and the conductor 788 and a refractive index n of the EL layer 786 is set to m times half of a wavelength λ (m is an integer of 1 or more). The distance d can be obtained by Formula 1.

d=m×λ/(2×n) Formula 1

According to Formula 1, in the light-emitting element 61 having the microcavity structure, the distance d is determined in accordance with the wavelength (emission color) of emitted light. The distance d corresponds to the thickness of the EL layer 786. Thus, the EL layer 786G is provided to have a larger thickness than the EL layer 786B, and the EL layer 786R is provided to have a larger thickness than the EL layer 786G in some cases.

To be exact, the distance d is a distance from a reflection region in the conductor 772 functioning as a reflective electrode to a reflection region in the conductor 788 functioning as a transflective electrode. For example, in the case where the conductor 772 is a stack of silver and ITO that is a transparent conductive film and the ITO is positioned on the EL layer 786 side, the distance d suitable for the emission color can be set by adjusting the thickness of the ITO. That is, even when the EL layer 786R, the EL layer 786G, and the EL layer 786B have the same thickness, the distance d suitable for the emission color can be obtained by adjusting the thickness of the ITO.

However, it is sometimes difficult to determine the exact position of the reflection region in each of the conductor 772 and the conductor 788. In this case, it is assumed that the effect of the microcavity structure can be fully obtained with a certain position in each of the conductor 772 and the conductor 788 being supposed as the reflection region.

The light-emitting element 61 includes a hole-transport layer, a hole-transport layer, a light-emitting layer, an electron-transport layer, an electron-injection layer, and the like. Note that a specific structure example of the light-emitting element 61 will be described in another embodiment. In order to increase the outcoupling efficiency in the microcavity structure, the optical path length from the conductor 772 functioning as a reflective electrode to the light-emitting layer is preferably set to an odd multiple of λ/4. In order to achieve this optical path length, the thicknesses of the layers in the light-emitting element 61 are preferably adjusted as appropriate.

In the case where light is emitted from the conductor 788 side, the reflectance of the conductor 788 is preferably higher than the transmittance thereof. The light transmittance of the conductor 788 is preferably higher than or equal to 2% and lower than or equal to 50%, further preferably higher than or equal to 2% and lower than or equal to 30%, still further preferably higher than or equal to 2% and lower than or equal to 10%. When the transmittance of the conductor 788 is set low (the reflectance is set high), the effect of the microcavity structure can be enhanced.

The structures described in this embodiment can be used in an appropriate combination with any of the structures described in the other embodiments and the like.

### Embodiment 6

In this embodiment, transistors that can be used in the semiconductor device of one embodiment of the present invention will be described.

### <Structure Example of Transistor>

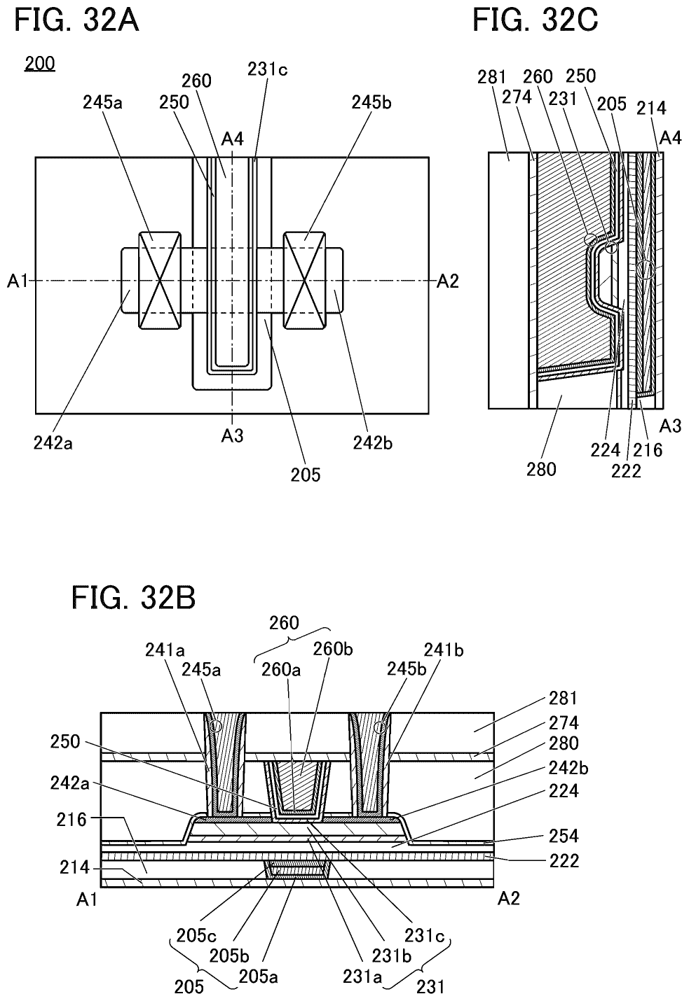

FIG. 32A, FIG. 32B, and FIG. 32C are a top view and cross-sectional views of a transistor 200 that can be used in the semiconductor device of one embodiment of the present invention and the periphery of the transistor 200. The transistor 200 can be used in the semiconductor device of one embodiment of the present invention. For example, the transistor 200 can be used as the transistor included in the layer 30.

FIG. 32A is a top view of the transistor 200. FIG. 32B and FIG. 32C are cross-sectional views of the transistor 200. Here, FIG. 32B is a cross-sectional view of a portion indicated by the dashed-dotted line A1-A2 in FIG. 32A and is a cross-sectional view of the transistor 200 in the channel length direction. FIG. 32C is a cross-sectional view of a portion indicated by the dashed-dotted line A3-A4 in FIG. 32A and is a cross-sectional view of the transistor 200 in the channel width direction. Note that some components are omitted in the top view of FIG. 32A for clarity of the drawing.

As illustrated in FIG. 32, the transistor 200 includes a metal oxide 231a placed over a substrate (not illustrated); a metal oxide 231b placed over the metal oxide 231a; a conductor 242a and a conductor 242b that are placed apart from each other over the metal oxide 231b; the insulator 280 that is placed over the conductor 242a and the conductor 242b and has an opening between the conductor 242a and the conductor 242b; a conductor 260 placed in the opening; an insulator 250 placed between the conductor 260 and the metal oxide 231b, the conductor 242a, the conductor 242b, and the insulator 280; and a metal oxide 231c placed between the insulator 250 and the metal oxide 231b, the conductor 242a, the conductor 242b, and the insulator 280. Here, as illustrated in FIG. 32B and FIG. 32C, preferably, the top surface of the conductor 260 is substantially aligned with the top surfaces of the insulator 250, the insulator 254, the metal oxide 231c, and the insulator 280. Hereinafter, the metal oxide 231a, the metal oxide 231b, and the metal oxide 231c may be collectively referred to as a metal oxide 231. The conductor 242a and the conductor 242b may be collectively referred to as a conductor 242.

In the transistor 200 illustrated in FIG. 32, side surfaces of the conductor 242a and the conductor 242b on the conductor 260 side are substantially perpendicular. Note that the transistor 200 illustrated in FIG. 32 is not limited thereto, and the angle formed between the side surfaces and the bottom surfaces of the conductor 242a and the conductor 242b may be greater than or equal to 10° and less than or equal to 80°, preferably greater than or equal to 30° and less than or equal to 60°. The side surfaces of the conductor 242a and the conductor 242b that face each other may have a plurality of surfaces.

As illustrated in FIG. 32, the insulator 254 is preferably placed between the insulator 280 and the insulator 224, the metal oxide 231a, the metal oxide 231b, the conductor 242a, the conductor 242b, and the metal oxide 231c. Here, as illustrated in FIG. 32B and FIG. 32C, the insulator 254 is preferably in contact with the side surface of the metal oxide 231c, the top surface and the side surface of the conductor 242a, the top surface and the side surface of the conductor 242b, the side surfaces of the metal oxide 231a and the metal oxide 231b, and the top surface of the insulator 224.

In the transistor 200, three layers of the metal oxide 231a, the metal oxide 231b, and the metal oxide 231c are stacked in and around the region where the channel is formed (hereinafter also referred to as channel formation region); however, the present invention is not limited thereto. For example, a two-layer structure of the metal oxide 231b and the metal oxide 231c or a stacked-layer structure of four or more layers may be employed. Although the conductor 260 is illustrated to have a stacked-layer structure of two layers in the transistor 200, the present invention is not limited thereto. For example, the conductor 260 may have a single-layer structure or a stacked-layer structure of three or more layers. Furthermore, each of the metal oxide 231a, the metal oxide 231b, and the metal oxide 231c may have a stacked-layer structure of two or more layers.

For example, in the case where the metal oxide 231c has a stacked-layer structure including a first metal oxide and a second metal oxide over the first metal oxide, the first metal oxide preferably has a composition similar to that of the metal oxide 231b and the second metal oxide preferably has a composition similar to that of the metal oxide 231a.

Here, the conductor 260 functions as a gate electrode of the transistor, and the conductor 242a and the conductor 242b each function as a source electrode or a drain electrode. As described above, the conductor 260 is formed to be embedded in the opening of the insulator 280 and the region interposed between the conductor 242a and the conductor 242b. Here, the positions of the conductor 260, the conductor 242a, and the conductor 242b are selected in a self-aligned manner with respect to the opening of the insulator 280. In other words, in the transistor 200, the gate electrode can be placed between the source electrode and the drain electrode in a self-aligned manner. Thus, the conductor 260 can be formed without an alignment margin, resulting in a reduction in the area occupied by the transistor 200. Accordingly, the display apparatus can have higher resolution. In addition, the display apparatus can have a narrow bezel.

As illustrated in FIG. 32, the conductor 260 preferably includes a conductor 260a provided on the inner side of the insulator 250 and a conductor 260b provided to be embedded on the inner side of the conductor 260a.

The transistor 200 preferably includes the insulator 214 placed over the substrate (not illustrated); the insulator 216 placed over the insulator 214; a conductor 205 placed to be embedded in the insulator 216; the insulator 222 placed over the insulator 216 and the conductor 205; and the insulator 224 placed over the insulator 222. The metal oxide 231a is preferably placed over the insulator 224.

The insulator 274 and the insulator 281 functioning as interlayer films are preferably placed over the transistor 200. Here, the insulator 274 is preferably placed in contact with the top surfaces of the conductor 260, the insulator 250, the insulator 254, the metal oxide 231c, and the insulator 280.

The insulator 222, the insulator 254, and the insulator 274 preferably have a function of inhibiting diffusion of at least one of hydrogen (e.g., a hydrogen atom and a hydrogen molecule). For example, the insulator 222, the insulator 254, and the insulator 274 preferably have a lower hydrogen permeability than the insulator 224, the insulator 250, and the insulator 280. Moreover, the insulator 222 and the insulator 254 preferably have a function of inhibiting diffusion of oxygen (e.g., at least one of an oxygen atom and an oxygen molecule). For example, the insulator 222 and the insulator 254 preferably have a lower oxygen permeability than the insulator 224, the insulator 250, and the insulator 280.

Here, the insulator 224, the metal oxide 231, and the insulator 250 are separated from the insulator 280 and the insulator 281 by the insulator 254 and the insulator 274. This can inhibit entry of impurities such as hydrogen contained in the insulator 280 and the insulator 281 and excess oxygen into the insulator 224, the metal oxide 231, and the insulator 250.

A conductor 245 (a conductor 245a and a conductor 245b) that is electrically connected to the transistor 200 and functions as a plug is preferably provided. Note that an insulator 241 (an insulator 241a and an insulator 241b) is provided in contact with the side surface of the conductor 245 functioning as a plug. In other words, the insulator 241 is provided in contact with the inner wall of an opening in the insulator 254, the insulator 280, the insulator 274, and the insulator 281. In addition, a structure may be employed in which a first conductor of the conductor 245 is provided in contact with the side surface of the insulator 241 and a second conductor of the conductor 245 is provided on the inner side of the first conductor. Here, the top surface of the conductor 245 and the top surface of the insulator 281 can be substantially level with each other. Although the transistor 200 has a structure in which the first conductor of the conductor 245 and the second conductor of the conductor 245 are stacked, the present invention is not limited thereto. For example, the conductor 245 may have a single-layer structure or a stacked-layer structure of three or more layers. In the case where a component has a stacked-layer structure, layers may be distinguished by ordinal numbers corresponding to the formation order.

In the transistor 200, a metal oxide functioning as an oxide semiconductor (hereinafter also referred to as an oxide semiconductor) is preferably used as the metal oxide 231 including the channel formation region (the metal oxide 231a, the metal oxide 231b, and the metal oxide 231c). For example, it is preferable to use a metal oxide having a band gap of 2 eV or more, preferably 2.5 eV or more as the metal oxide to be the channel formation region of the metal oxide 231.

The metal oxide preferably contains at least indium (In) or zinc (Zn). In particular, indium (In) and zinc (Zn) are preferably contained. In addition to them, an element M is preferably contained. As the element M, one or more of aluminum (Al), gallium (Ga), yttrium (Y), tin (Sn), boron (B), titanium (Ti), iron (Fe), nickel (Ni), germanium (Ge), zirconium (Zr), molybdenum (Mo), lanthanum (La), cerium (Ce), neodymium (Nd), hafnium (Hf), tantalum (Ta), tungsten (W), magnesium (Mg), and cobalt (Co) can be used. In particular, the element M is preferably one or more of aluminum (Al), gallium (Ga), yttrium (Y), and tin (Sn). Furthermore, the element M preferably contains one or both of gallium (Ga) and tin (Sn).

As illustrated in FIG. 32B, the metal oxide 231b in a region that does not overlap with the conductor 242 sometimes has a smaller thickness than the metal oxide 231b in a region that overlaps with the conductor 242. The thin region is formed when part of the top surface of the metal oxide 231b is removed at the time of forming the conductor 242a and the conductor 242b. When a conductive film to be the conductor 242 is formed, a low-resistance region is sometimes formed on the top surface of the metal oxide 231b in the vicinity of the interface with the conductive film. Removing the low-resistance region positioned between the conductor 242a and the conductor 242b on the top surface of the metal oxide 231b in the above manner can prevent formation of the channel in the region.

According to one embodiment of the present invention, a display apparatus that includes small-size transistors and has high resolution can be provided. A display apparatus that includes a transistor with a high on-state current and has high luminance can be provided. A display apparatus that includes a transistor operating at high speed and thus operates at high speed can be provided. A display apparatus that includes a transistor having stable electrical characteristics and is highly reliable can be provided. A display apparatus that includes a transistor with a low off-state current and has low power consumption can be provided.

The structure of the transistor 200 that can be used in the display apparatus of one embodiment of the present invention is described in detail.

The conductor 205 is placed to include a region overlapping with the metal oxide 231 and the conductor 260. Furthermore, the conductor 205 is preferably provided to be embedded in the insulator 216.

The conductor 205 includes a conductor 205a, a conductor 205b, and a conductor 205c. The conductor 205a is provided in contact with the bottom surface and a side wall of the opening provided in the insulator 216. The conductor 205b is provided to be embedded in a recessed portion formed by the conductor 205a. Here, the top surface of the conductor 205b is lower in level than the top surface of the conductor 205a and the top surface of the insulator 216. The conductor 205c is provided in contact with the top surface of the conductor 205b and the side surface of the conductor 205a. Here, the top surface of the conductor 205c is substantially level with the top surface of the conductor 205a and the top surface of the insulator 216. That is, the conductor 205b is surrounded by the conductor 205a and the conductor 205c.

Here, for the conductor 205a and the conductor 205c, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom and an oxygen molecule).

When the conductor 205a and the conductor 205c are formed using a conductive material having a function of inhibiting diffusion of hydrogen, impurities such as hydrogen contained in the conductor 205b can be inhibited from diffusing into the metal oxide 231 through the insulator 224 and the like. When the conductor 205a and the conductor 205c are formed using a conductive material having a function of inhibiting diffusion of oxygen, the conductivity of the conductor 205b can be inhibited from being lowered because of oxidation. As the conductive material having a function of inhibiting diffusion of oxygen, for example, titanium, titanium nitride, tantalum, tantalum nitride, ruthenium, ruthenium oxide, or the like is preferably used. Thus, the conductor 205a is a single layer or stacked layers of the above conductive materials. For example, titanium nitride is used for the conductor 205a.

For the conductor 205b, a conductive material containing tungsten, copper, or aluminum as its main component is preferably used. For example, tungsten is used for the conductor 205b.

The conductor 260 sometimes functions as a first gate (also referred to as top gate) electrode. The conductor 205 sometimes functions as a second gate (also referred to as bottom gate) electrode. In that case, by changing a potential applied to the conductor 205 not in synchronization with and independently of a potential applied to the conductor 260, Vₜₕ of the transistor 200 can be controlled. In particular, by applying a negative potential to the conductor 205, Vₜₕ of the transistor 200 can be higher than 0 V and the off-state current can be made low. Thus, a drain current at the time when a potential applied to the conductor 260 is 0 V can be lower in the case where a negative potential is applied to the conductor 205 than in the case where the negative potential is not applied to the conductor 205.

The conductor 205 is preferably provided to be larger than the channel formation region in the metal oxide 231. In particular, it is preferable that the conductor 205 extend to the outside beyond an end portion of the metal oxide 231 that intersects with the channel width direction, as illustrated in FIG. 32C. In other words, the conductor 205 and the conductor 260 preferably overlap with each other with the insulator placed therebetween, in a region outside the side surface of the metal oxide 231 in the channel width direction.

With the above structure, the channel formation region of the metal oxide 231 can be electrically surrounded by electric fields of the conductor 260 having a function of the first gate electrode and electric fields of the conductor 205 having a function of the second gate electrode.

Furthermore, as illustrated in FIG. 32C, the conductor 205 extends so as to function as a wiring as well. However, without limitation to this structure, a structure in which a conductor functioning as a wiring is provided below the conductor 205 may be employed.

The insulator 214 preferably functions as a barrier insulating film that inhibits the entry of impurities such as water or hydrogen to the transistor 200 from the substrate side. Accordingly, it is preferable to use, for the insulator 214, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are less likely to pass). Alternatively, it is preferable to use an insulating material having a function of inhibiting diffusion of oxygen (e.g., at least one of an oxygen atom and an oxygen molecule) (an insulating material through which the oxygen is less likely to pass).

For example, aluminum oxide, silicon nitride, or the like is preferably used for the insulator 214. Accordingly, it is possible to inhibit diffusion of impurities such as water or hydrogen to the transistor 200 side from the substrate side through the insulator 214. Alternatively, it is possible to inhibit diffusion of oxygen contained in the insulator 224 and the like to the substrate side through the insulator 214.

The permittivity of each of the insulator 216, the insulator 280, and the insulator 281 functioning as an interlayer film is preferably lower than that of the insulator 214. When a material with a low permittivity is used for an interlayer film, the parasitic capacitance generated between wirings can be reduced. For the insulator 216, the insulator 280, and the insulator 281, for example, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like can be used as appropriate.

The insulator 222 and the insulator 224 have a function of a gate insulator.

Here, the insulator 224 in contact with the metal oxide 231 preferably releases oxygen by heating. In this specification, oxygen that is released by heating is referred to as excess oxygen in some cases. For example, silicon oxide, silicon oxynitride, or the like can be used as appropriate for the insulator 224. When an insulator containing oxygen is provided in contact with the metal oxide 231, oxygen vacancies in the metal oxide 231 can be reduced, leading to improved reliability of the transistor 200.

Specifically, an oxide material that releases part of oxygen by heating is preferably used for the insulator 224. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. Note that the temperature of the film surface in the TDS analysis is preferably in the range of 100° C. to 700° C., both inclusive or 100° C. to 400° C., both inclusive.

As illustrated in FIG. 32C, the insulator 224 is sometimes thinner in a region that overlaps with neither the insulator 254 nor the metal oxide 231b than in the other regions. In the insulator 224, the region that overlaps with neither the insulator 254 nor the metal oxide 231b preferably has a thickness with which the above oxygen can be adequately diffused.

Like the insulator 214 and the like, the insulator 222 preferably functions as a barrier insulating film that inhibits the entry of impurities such as water or hydrogen into the transistor 200 from the substrate side. For example, the insulator 222 preferably has a lower hydrogen permeability than the insulator 224. When the insulator 224, the metal oxide 231, the insulator 250, and the like are surrounded by the insulator 222, the insulator 254, and the insulator 274, the entry of impurities such as water or hydrogen into the transistor 200 from outside can be inhibited.

Furthermore, it is preferable that the insulator 222 have a function of inhibiting diffusion of oxygen (e.g., at least one of an oxygen atom and an oxygen molecule) (it is preferable that the oxygen be less likely to pass through the insulator 222). For example, the insulator 222 preferably has a lower oxygen permeability than the insulator 224. The insulator 222 preferably has a function of inhibiting diffusion of oxygen and impurities, in which case oxygen contained in the metal oxide 231 is less likely to diffuse to the substrate side. Moreover, the conductor 205 can be inhibited from reacting with oxygen contained in the insulator 224 and the metal oxide 231.

As the insulator 222, an insulator containing an oxide of one or both of aluminum and hafnium, which is an insulating material, is preferably used. As the insulator containing an oxide of one or both of aluminum and hafnium, aluminum oxide, hafnium oxide, an oxide containing aluminum and hafnium (hafnium aluminate), or the like is preferably used. In the case where the insulator 222 is formed using such a material, the insulator 222 functions as a layer inhibiting release of oxygen from the metal oxide 231 and entry of impurities such as hydrogen into the metal oxide 231 from the periphery of the transistor 200.

Alternatively, aluminum oxide, bismuth oxide, germanium oxide, niobium oxide, silicon oxide, titanium oxide, tungsten oxide, yttrium oxide, or zirconium oxide may be added to these insulators, for example. Alternatively, these insulators may be subjected to nitriding treatment. Silicon oxide, silicon oxynitride, or silicon nitride may be stacked over the above insulator.

The insulator 222 may be a single layer or a stacked layer using an insulator containing a high-k material, such as aluminum oxide, hafnium oxide, tantalum oxide, zirconium oxide, lead zirconate titanate (PZT), strontium titanate (SrTiO₃), or (Ba,Sr)TiO₃ (BST). With further miniaturization and higher integration of a transistor, a problem such as generation of leakage current may arise because of a thinned gate insulator. When a high-k material is used for the insulator functioning as a gate insulator, a gate potential at the time of operation of the transistor can be reduced while the physical thickness is maintained.

Note that the insulator 222 and the insulator 224 may each have a stacked-layer structure of two or more layers. In that case, without limitation to a stacked-layer structure formed of the same material, a stacked-layer structure formed of different materials may be employed. For example, an insulator similar to the insulator 224 may be provided below the insulator 222.

The metal oxide 231 includes the metal oxide 231a, the metal oxide 231b over the metal oxide 231a, and the metal oxide 231c over the metal oxide 231b. When the metal oxide 231 includes the metal oxide 231a under the metal oxide 231b, it is possible to inhibit diffusion of impurities into the metal oxide 231b from the components formed below the metal oxide 231a. Moreover, when the metal oxide 231 includes the metal oxide 231c over the metal oxide 231b, it is possible to inhibit diffusion of impurities into the metal oxide 231b from the components formed above the metal oxide 231c.

Note that the metal oxide 231 preferably has a stacked-layer structure of a plurality of oxide layers that differ in the atomic ratio of metal atoms. For example, in the case where the metal oxide 231 contains at least indium (In) and the element M, the proportion of the number of atoms of the element M contained in the metal oxide 231a to the number of atoms of all elements that constitute the metal oxide 231a is preferably higher than the proportion of the number of atoms of the element M contained in the metal oxide 231b to the number of atoms of all elements that constitute the metal oxide 231b. In addition, the atomic ratio of the element M to In in the metal oxide 231a is preferably greater than the atomic ratio of the element M to In in the metal oxide 231b. Here, a metal oxide that can be used as the metal oxide 231a or the metal oxide 231b can be used as the metal oxide 231c.

The energy of the conduction band minimum of each of the metal oxide 231a and the metal oxide 231c is preferably higher than the energy of the conduction band minimum of the metal oxide 231b. In other words, the electron affinity of each of the metal oxide 231a and the metal oxide 231c is preferably smaller than the electron affinity of the metal oxide 231b. In this case, a metal oxide that can be used as the metal oxide 231a is preferably used as the metal oxide 231c. Specifically, the proportion of the number of atoms of the element M contained in the metal oxide 231c to the number of atoms of all elements that constitute the metal oxide 231c is preferably higher than the proportion of the number of atoms of the element M contained in the metal oxide 231b to the number of atoms of all elements that constitute the metal oxide 231b. In addition, the atomic ratio of the element M to In in the metal oxide 231c is preferably greater than the atomic ratio of the element M to In in the metal oxide 231b.

Here, the energy level of the conduction band minimum gently changes at junction portions between the metal oxide 231a, the metal oxide 231b, and the metal oxide 231c. In other words, at junction portions between the metal oxide 231a, the metal oxide 231b, and the metal oxide 231c, the energy level of the conduction band minimum continuously changes or the energy levels are continuously connected. This can be achieved by decreasing the density of defect states in a mixed layer formed at the interface between the metal oxide 231a and the metal oxide 231b and the interface between the metal oxide 231b and the metal oxide 231c.

Specifically, when the metal oxide 231a and the metal oxide 231b or the metal oxide 231b and the metal oxide 231c contain the same element (as a main component) in addition to oxygen, a mixed layer with a low density of defect states can be formed. For example, an In—Ga—Zn oxide, a Ga—Zn oxide, gallium oxide, or the like may be used as the metal oxide 231a and the metal oxide 231c, in the case where the metal oxide 231b is an In—Ga—Zn oxide. The metal oxide 231c may have a stacked-layer structure. For example, a stacked-layer structure of an In—Ga—Zn oxide and a Ga—Zn oxide over the In—Ga—Zn oxide or a stacked-layer structure of an In—Ga—Zn oxide and gallium oxide over the In—Ga—Zn oxide can be employed. In other words, the metal oxide 231c may have a stacked-layer structure of an In—Ga—Zn oxide and an oxide that does not contain In.

Specifically, as the metal oxide 231a, a metal oxide with In: Ga:Zn=1:3:4 [atomic ratio] or 1:1:0.5 [atomic ratio] can be used. As the metal oxide 231b, a metal oxide with In: Ga:Zn=4:2:3 [atomic ratio] or 3:1:2 [atomic ratio] can be used. As the metal oxide 231c, a metal oxide with In: Ga:Zn=1:3:4 [atomic ratio], In: Ga:Zn=4:2:3 [atomic ratio], Ga:Zn=2:1 [atomic ratio], or Ga:Zn=2:5 [atomic ratio] can be used. Specific examples of a stacked-layer structure of the metal oxide 231c include a stacked-layer structure of a layer with In: Ga:Zn=4:2:3 [atomic ratio] and a layer with Ga:Zn=2:1 [atomic ratio], a stacked-layer structure of a layer with In: Ga: Zn=4:2:3 [atomic ratio] and a layer with Ga:Zn=2:5 [atomic ratio], and a stacked-layer structure of a layer with In: Ga:Zn=4:2:3 [atomic ratio] and a layer of gallium oxide.

At this time, the metal oxide 231b serves as a main carrier path. When the metal oxide 231a and the metal oxide 231c have the above structure, the density of defect states at the interface between the metal oxide 231a and the metal oxide 231b and the interface between the metal oxide 231b and the metal oxide 231c can be made low. This reduces the influence of interface scattering on carrier conduction, and the transistor 200 can have a high on-state current and high frequency characteristics. Note that in the case where the metal oxide 231c has a stacked-layer structure, not only the effect of reducing the density of defect states at the interface between the metal oxide 231b and the metal oxide 231c, but also the effect of inhibiting diffusion of the constituent element contained in the metal oxide 231c to the insulator 250 side can be expected. Specifically, the metal oxide 231c has a stacked-layer structure in which an oxide not containing In is positioned in the upper layer of the stacked-layer structure, whereby the diffusion of In to the insulator 250 side can be inhibited. Since the insulator 250 functions as a gate insulator, the transistor has defects in characteristics when In diffuses. Thus, the metal oxide 231c having a stacked-layer structure allows a highly reliable display apparatus to be provided.

The conductor 242 (the conductor 242a and the conductor 242b) functioning as the source electrode and the drain electrode is provided over the metal oxide 231b. For the conductor 242, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen.

When the conductor 242 is provided in contact with the metal oxide 231, the oxygen concentration of the metal oxide 231 in the vicinity of the conductor 242 sometimes decreases. In addition, a metal compound layer that contains the metal contained in the conductor 242 and the component of the metal oxide 231 is sometimes formed in the metal oxide 231 in the vicinity of the conductor 242. In such cases, the carrier concentration of the region in the metal oxide 231 in the vicinity of the conductor 242 increases, and the region becomes a low-resistance region.

Here, the region between the conductor 242a and the conductor 242b is formed to overlap with the opening of the insulator 280. Accordingly, the conductor 260 can be placed in a self-aligned manner between the conductor 242a and the conductor 242b.

The insulator 250 functions as a gate insulator. The insulator 250 is preferably placed in contact with the top surface of the metal oxide 231c. For the insulator 250, silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which are thermally stable, are preferable.

As in the insulator 224, the concentration of impurities such as water or hydrogen in the insulator 250 is preferably reduced. The thickness of the insulator 250 is preferably greater than or equal to 1 nm and less than or equal to 20 nm.

A metal oxide may be provided between the insulator 250 and the conductor 260. The metal oxide preferably inhibits oxygen diffusion from the insulator 250 into the conductor 260. Accordingly, oxidation of the conductor 260 due to oxygen in the insulator 250 can be inhibited.

The metal oxide functions as part of the gate insulator in some cases. Therefore, when silicon oxide, silicon oxynitride, or the like is used for the insulator 250, a metal oxide that is a high-k material with a high dielectric constant is preferably used as the metal oxide. When the gate insulator has a stacked-layer structure of the insulator 250 and the metal oxide, the stacked-layer structure can be thermally stable and have a high dielectric constant. Accordingly, a gate potential applied during operation of the transistor can be reduced while the physical thickness of the gate insulator is maintained. In addition, the equivalent oxide thickness (EOT) of the insulator functioning as the gate insulator can be reduced.

Specifically, a metal oxide containing one kind or two or more kinds selected from hafnium, aluminum, gallium, yttrium, zirconium, tungsten, titanium, tantalum, nickel, germanium, magnesium, and the like can be used. It is particularly preferable to use an insulator containing an oxide of one or both of aluminum and hafnium, such as aluminum oxide, hafnium oxide, or an oxide containing aluminum and hafnium (hafnium aluminate).

Although the conductor 260 is illustrated to have a two-layer structure in FIG. 32, the conductor 260 may have a single-layer structure or a stacked-layer structure of three or more layers.

The conductor 260a is preferably formed using the aforementioned conductor having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, it is preferable to use a conductive material having a function of inhibiting diffusion of oxygen (e.g., at least one of an oxygen atom and an oxygen molecule).

When the conductor 260a has a function of inhibiting diffusion of oxygen, the conductivity of the conductor 260b can be inhibited from being lowered by oxidation due to oxygen contained in the insulator 250. As a conductive material having a function of inhibiting oxygen diffusion, for example, tantalum, tantalum nitride, ruthenium, ruthenium oxide, or the like is preferably used.

Moreover, a conductive material containing tungsten, copper, or aluminum as its main component is preferably used for the conductor 260b. The conductor 260 also functions as a wiring and thus is preferably formed using a conductor having high conductivity. For example, a conductive material containing tungsten, copper, or aluminum as its main component can be used. The conductor 260b may have a stacked-layer structure, for example, a stacked-layer structure of titanium or titanium nitride and the above conductive material.

As illustrated in FIG. 32A and FIG. 32C, the side surface of the metal oxide 231 is covered with the conductor 260 in a region where the metal oxide 231b does not overlap with the conductor 242, that is, the channel formation region of the metal oxide 231. Accordingly, electric fields of the conductor 260 functioning as the first gate electrode are likely to act on the side surface of the metal oxide 231. Thus, the on-state current of the transistor 200 can be increased and the frequency characteristics can be improved.

The insulator 254, like the insulator 214 and the like, preferably functions as a barrier insulating film that inhibits the entry of impurities such as water or hydrogen into the transistor 200 from the insulator 280 side. The insulator 254 preferably has a lower hydrogen permeability than the insulator 224, for example. Furthermore, as illustrated in FIG. 32B and FIG. 32C, the insulator 254 is preferably in contact with the side surface of the metal oxide 231c, the top and side surfaces of the conductor 242a, the top and side surfaces of the conductor 242b, side surfaces of the metal oxide 231a and the metal oxide 231b, and the top surface of the insulator 224. Such a structure can inhibit the entry of hydrogen contained in the insulator 280 into the metal oxide 231 through the top surfaces or side surfaces of the conductor 242a, the conductor 242b, the metal oxide 231a, the metal oxide 231b, and the insulator 224.

Furthermore, it is preferable that the insulator 254 have a function of inhibiting diffusion of oxygen (e.g., at least one of an oxygen atom and an oxygen molecule) (it is preferable that the oxygen be less likely to pass through the insulator 254). For example, the insulator 254 preferably has a lower oxygen permeability than the insulator 280 or the insulator 224.

The insulator 254 is preferably formed by a sputtering method. When the insulator 254 is formed by a sputtering method in an oxygen-containing atmosphere, oxygen can be added to the vicinity of a region of the insulator 224 that is in contact with the insulator 254. Thus, oxygen can be supplied from the region to the metal oxide 231 through the insulator 224. Here, with the insulator 254 having a function of inhibiting upward diffusion of oxygen, oxygen can be prevented from diffusing from the metal oxide 231 into the insulator 280. Moreover, with the insulator 222 having a function of inhibiting downward diffusion of oxygen, oxygen diffusion from the metal oxide 231 to the substrate side can be prevented. In the above manner, oxygen is supplied to the channel formation region of the metal oxide 231. Accordingly, oxygen vacancies in the metal oxide 231 can be reduced, so that the transistor can be inhibited from having normally-on characteristics.

As the insulator 254, an insulator containing an oxide of one or both of aluminum and hafnium is preferably formed, for example. Note that as the insulator containing an oxide of one or both of aluminum and hafnium, aluminum oxide, hafnium oxide, an oxide containing aluminum and hafnium (hafnium aluminate), or the like is preferably used.

The insulator 224, the insulator 250, and the metal oxide 231 are covered with the insulator 254 having a barrier property against hydrogen, whereby the insulator 280 is isolated from the insulator 224, the metal oxide 231, and the insulator 250 by the insulator 254. This can inhibit the entry of impurities such as hydrogen from outside of the transistor 200, resulting in favorable electrical characteristics and high reliability of the transistor 200.

The insulator 280 is provided over the insulator 224, the metal oxide 231, and the conductor 242 with the insulator 254 placed therebetween. The insulator 280 preferably includes, for example, silicon oxide, silicon oxynitride, silicon nitride oxide, silicon oxide to which fluorine is added, silicon oxide to which carbon is added, silicon oxide to which carbon and nitrogen are added, or porous silicon oxide. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed.

The concentration of impurities such as water or hydrogen in the insulator 280 is preferably reduced. In addition, the top surface of the insulator 280 may be planarized.

Like the insulator 214 and the like, the insulator 274 preferably functions as a barrier insulating film that inhibits the entry of impurities such as water or hydrogen into the insulator 280 from the above. As the insulator 274, for example, the insulator that can be used as the insulator 214, the insulator 254, and the like can be used.

The insulator 281 functioning as an interlayer film is preferably provided over the insulator 274. As in the insulator 224 or the like, the concentration of impurities such as water or hydrogen in the insulator 281 is preferably reduced.

The conductor 245a and the conductor 245b are placed in openings formed in the insulator 281, the insulator 274, the insulator 280, and the insulator 254. The conductor 245a and the conductor 245b are placed to face each other with the conductor 260 placed therebetween. Note that the top surfaces of the conductor 245a and the conductor 245b may be on the same plane as the top surface of the insulator 281.

The insulator 241a is provided in contact with the inner wall of the opening in the insulator 281, the insulator 274, the insulator 280, and the insulator 254, and the first conductor of the conductor 245a is formed in contact with the side surface of the insulator 241a. The conductor 242a is positioned on at least part of the bottom portion of the opening, and the conductor 245a is in contact with the conductor 242a. Similarly, the insulator 241b is provided in contact with the inner wall of the opening in the insulator 281, the insulator 274, the insulator 280, and the insulator 254, and the first conductor of the conductor 245b is formed in contact with the side surface of the insulator 241b. The conductor 242b is positioned on at least part of the bottom portion of the opening, and the conductor 245b is in contact with the conductor 242b.

The conductor 245a and the conductor 245b are preferably formed using a conductive material containing tungsten, copper, or aluminum as its main component. The conductor 245a and the conductor 245b may have a stacked-layer structure.

In the case where the conductor 245 has a stacked-layer structure, the aforementioned conductor having a function of inhibiting diffusion of impurities such as water or hydrogen is preferably used as the conductor in contact with the metal oxide 231a, the metal oxide 231b, the conductor 242, the insulator 254, the insulator 280, the insulator 274, and the insulator 281. For example, tantalum, tantalum nitride, titanium, titanium nitride, ruthenium, ruthenium oxide, or the like is preferably used. The conductive material having a function of inhibiting diffusion of impurities such as water or hydrogen can be used as a single layer or stacked layers. The use of the conductive material can inhibit oxygen added to the insulator 280 from being absorbed by the conductor 245a and the conductor 245b. Moreover, impurities such as water or hydrogen can be inhibited from entering the metal oxide 231 through the conductor 245a and the conductor 245b from a layer above the insulator 281.

As the insulator 241a and the insulator 241b, for example, the insulator that can be used as the insulator 254 or the like can be used. Since the insulator 241a and the insulator 241b are provided in contact with the insulator 254, impurities such as water or hydrogen in the insulator 280 or the like can be inhibited from entering the metal oxide 231 through the conductor 245a and the conductor 245b. Furthermore, oxygen contained in the insulator 280 can be inhibited from being absorbed by the conductor 245a and the conductor 245b.

Although not illustrated, a conductor functioning as a wiring may be placed in contact with the top surface of the conductor 245a and the top surface of the conductor 245b. For the conductor functioning as a wiring, a conductive material containing tungsten, copper, or aluminum as its main component is preferably used. Furthermore, the conductor may have a stacked-layer structure and may be a stack of titanium or a titanium nitride and the above conductive material, for example. Note that the conductor may be formed to be embedded in an opening provided in an insulator.

### <Materials for Transistor>

Materials that can be used for the transistor will be described.

### [Substrate]

As a substrate where the transistor 200 is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon, germanium, or the like and a compound semiconductor substrate of silicon carbide, silicon germanium, gallium arsenide, indium phosphide, zinc oxide, or gallium oxide. Another example is a semiconductor substrate in which an insulator region is included in the semiconductor substrate, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the elements provided for the substrates include a capacitor, a resistor, a switching element, a light-emitting element, and a memory element.

### [Insulator]

Examples of an insulator include an oxide, a nitride, an oxynitride, a nitride oxide, a metal oxide, a metal oxynitride, and a metal nitride oxide, each of which has an insulating property.

With further miniaturization and higher integration of a transistor, for example, a problem such as generation of leakage current may arise because of a thinned gate insulator. When a high-k material is used for the insulator functioning as a gate insulator, the voltage at the time of operation of the transistor can be reduced while the physical thickness is maintained. By contrast, when a material with a low dielectric constant is used for the insulator functioning as an interlayer film, parasitic capacitance generated between wirings can be reduced. Thus, a material is preferably selected depending on the function of an insulator.

Examples of the insulator having a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including an oxide semiconductor is surrounded by insulators having a function of inhibiting the passage of oxygen and impurities such as hydrogen (e.g., the insulator 214, the insulator 222, the insulator 254, and the insulator 274), the electrical characteristics of the transistor can be stable. An insulator having a function of inhibiting the passage of oxygen and impurities such as hydrogen can be formed to have a single layer or a stacked layer including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting the passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, aluminum titanium nitride, titanium nitride, silicon nitride oxide, or silicon nitride can be used.

An insulator functioning as a gate insulator is preferably an insulator including a region containing oxygen to be released by heating. For example, when a structure is employed in which silicon oxide or silicon oxynitride that includes a region containing oxygen to be released by heating is provided in contact with the metal oxide 231, oxygen vacancies included in the metal oxide 231 can be compensated.

### [Conductor]

For a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. A semiconductor having high electrical conductivity, typified by polycrystalline silicon containing an impurity element such as phosphorus, or silicide such as nickel silicide may be used.

A plurality of conductors formed using any of the above materials may be stacked. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

At least part of this embodiment can be implemented in combination with any of the other embodiments described in this specification as appropriate.

The structures described in this embodiment can be used in an appropriate combination with any of the structures described in the other embodiments and the like.

### Embodiment 7

Described in this embodiment is a metal oxide (hereinafter also referred to as an oxide semiconductor) that can be used in an OS transistor described in the above embodiment.

### <Classification of Crystal Structure>

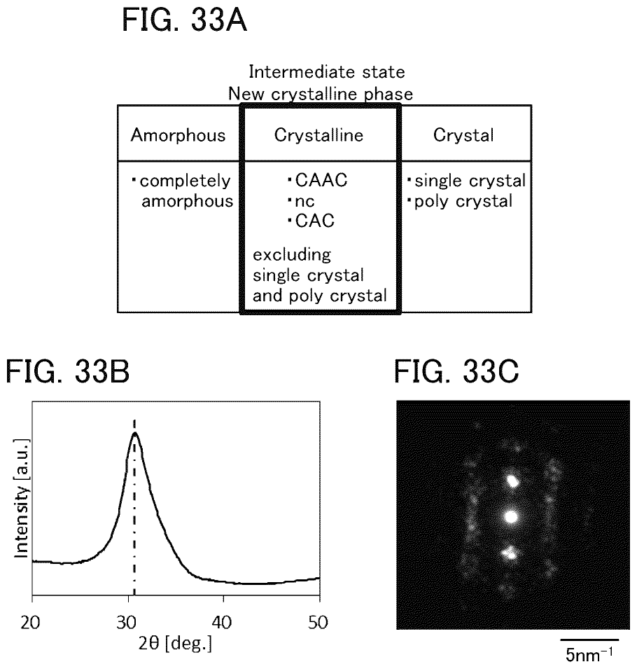

First, the classification of crystal structures of an oxide semiconductor is described with reference to FIG. 33A. FIG. 33A is a diagram showing classification of crystal structures of an oxide semiconductor, typically IGZO (a metal oxide containing In, Ga, and Zn).

As shown in FIG. 33A, an oxide semiconductor is roughly classified into “Amorphous”, “Crystalline”, and “Crystal”. “Amorphous” includes completely amorphous. The term “Crystalline” includes CAAC (c-axis-aligned crystalline), nc (nanocrystalline), and CAC (Cloud-Aligned Composite) (excluding single crystal and poly crystal). Note that in the classification of “Crystalline,” single crystal, poly crystal, and completely amorphous are excluded. The term “Crystal” includes single crystal and poly crystal.

Note that the structures in the thick frame in FIG. 33A are in an intermediate state between “Amorphous” and “Crystal”, and belong to a new crystalline phase. That is, these structures are completely different from “Crystal” and “Amorphous”, which is energetically unstable.

A crystal structure of a film or a substrate can be evaluated with an X-Ray Diffraction (XRD) spectrum. FIG. 33B shows an XRD spectrum, which is obtained using GIXD (Grazing-Incidence XRD) measurement, of a CAAC-IGZO film classified into “Crystalline”. Note that a GIXD method is also referred to as a thin film method or a Seemann-Bohlin method. The XRD spectrum that is shown in FIG. 33B and obtained by GIXD measurement is hereinafter simply referred to as an XRD spectrum. The CAAC-IGZO film in FIG. 33B has a composition in the vicinity of In: Ga:Zn=4:2:3 [atomic ratio]. The CAAC-IGZO film in FIG. 33B has a thickness of 500 nm.

As shown in FIG. 33B, a clear peak indicating crystallinity is detected in the XRD spectrum of the CAAC-IGZO film. Specifically, a peak indicating c-axis alignment is detected at 20 of around 31° in the XRD spectrum of the CAAC-IGZO film. As shown in FIG. 33B, the peak at 20 of around 31° is asymmetric with respect to the axis of the angle at which the peak intensity is detected.

A crystal structure of a film or a substrate can also be evaluated with a diffraction pattern obtained by a nanobeam electron diffraction (NBED) method (such a pattern is also referred to as a nanobeam electron diffraction pattern). FIG. 33C shows a diffraction pattern of a CAAC-IGZO film. FIG. 33C shows a diffraction pattern obtained with the NBED method in which an electron beam is incident in the direction parallel to the substrate. The CAAC-IGZO film in FIG. 33C has a composition in the vicinity of In: Ga:Zn=4:2:3 [atomic ratio]. In the nanobeam electron diffraction method, electron diffraction is performed with a probe diameter of 1 nm.

As shown in FIG. 33C, a plurality of spots indicating c-axis alignment are observed in the diffraction pattern of the CAAC-IGZO film.

### [Structure of Oxide Semiconductor]

Oxide semiconductors may be classified in a manner different from that in FIG. 33A when classified in terms of the crystal structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the CAAC-OS, the nc-OS, and the a-like OS will be described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that the distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than 10 nm. In the case where the crystal region is formed of a large number of minute crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM image, for example.

When the CAAC-OS film is subjected to structural analysis by out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

A crystal structure in which a clear crystal grain boundary is observed is what is called polycrystal. It is highly probable that the grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, reduction in electron mobility due to the crystal grain boundary is less likely to occur. Moreover, since the crystallinity of an oxide semiconductor might be decreased by entry of impurities, formation of defects, and/or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis using out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

[a-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has higher hydrogen concentration in the film than the nc-OS and the CAAC-OS.

### [Structure of Oxide Semiconductor]

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal elements are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. For example, the first region has higher [In] than the second region and has lower [Ga] than the second region. Moreover, the second region has higher [Ga] than the first region and has lower [In] than the first region.

Specifically, the first region includes indium oxide, indium zinc oxide, or the like as its main component. The second region includes gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

In the case where the CAC-OS is used for a transistor, a switching function (on/off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current (Iₒₙ), high field-effect mobility (μ), and excellent switching operation can be achieved.

An oxide semiconductor has various structures with different properties. Two or more kinds of the amorphous oxide semiconductor, the polycrystalline oxide semiconductor, the a-like OS, the CAC-OS, the nc-OS, and the CAAC-OS may be included in the oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor having high reliability can be achieved.

An oxide semiconductor with a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Electric charge trapped by the trap states in the oxide semiconductor takes a long time to disappear and might behave like fixed electric charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in a proximate film be also reduced. Examples of impurities include hydrogen, nitrogen, an alkali metal, an alkaline earth metal, iron, nickel, and silicon.

### <Impurities>

Here, the influence of each impurity in the oxide semiconductor is described.

When silicon and/or carbon, which are each one of Group 14 elements, is contained in the oxide semiconductor, defect states are formed in the oxide semiconductor. Thus, the concentration of silicon and carbon in the oxide semiconductor and the concentration of silicon and carbon in the vicinity of an interface with the oxide semiconductor (the concentrations obtained by SIMS) are each set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor including an oxide semiconductor containing nitrogen as a semiconductor is likely to have normally-on characteristics. When nitrogen is contained in the oxide semiconductor, a trap state is sometimes formed. This might make the electrical characteristics of the transistor unstable. Therefore, the concentration of nitrogen in the oxide semiconductor, which is obtained using SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained using SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

The structures described in this embodiment can be used in an appropriate combination with any of the structures described in the other embodiments and the like.

### Embodiment 8

In this embodiment, electronic devices to which the semiconductor device of one embodiment of the present invention can be applied will be described.

The semiconductor device of one embodiment of the present invention can be used in a display portion of an electronic device. Thus, an electronic device with high display quality can be obtained. An electronic device with an extremely high resolution can be obtained. A highly reliable electronic device can be obtained.

Examples of electronic devices including the semiconductor device or the like of one embodiment of the present invention include display apparatuses of televisions, monitors, and the like, lighting devices, desktop or laptop personal computers, word processors, image reproduction devices which reproduce still images or moving images stored in recording media such as DVDs (Digital Versatile Discs), portable CD players, radios, tape recorders, headphone stereos, stereos, table clocks, wall clocks, cordless phone handsets, transceivers, car phones, cellular phones, portable information terminals, tablet terminals, portable game machines, stationary game machines such as pachinko machines, calculators, electronic notebooks, e-book readers, electronic translators, audio input devices, video cameras, digital still cameras, electric shavers, high-frequency heating appliances such as microwave ovens, electric rice cookers, electric washing machines, electric vacuum cleaners, water heaters, electric fans, hair dryers, air-conditioning systems such as air conditioners, humidifiers, and dehumidifiers, dishwashers, dish dryers, clothes dryers, futon dryers, electric refrigerators, electric freezers, electric refrigerator-freezers, freezers for preserving DNA, flashlights, tools such as chain saws, smoke detectors, and medical equipment such as dialyzers. Other examples include industrial equipment such as guide lights, traffic lights, conveyor belts, elevators, escalators, industrial robots, power storage systems, and power storage devices for leveling the amount of power supply and smart grid. In addition, moving objects and the like driven by fuel engines or electric motors using power from power storage units may also be included in the category of electronic devices. Examples of the moving objects include electric vehicles (EVs), hybrid electric vehicles (HEVs) that include both an internal-combustion engine and a motor, plug-in hybrid electric vehicles (PHEVs), tracked vehicles in which caterpillar tracks are substituted for wheels of these vehicles, motorized bicycles including motor-assisted bicycles, motorcycles, electric wheelchairs, golf carts, boats, ships, submarines, helicopters, aircraft, rockets, artificial satellites, space probes, planetary probes, and spacecraft.

The electronic device of one embodiment of the present invention may include a secondary battery (battery), and it is preferable that the secondary battery be capable of being charged by contactless power transmission.

Examples of the secondary battery include a lithium ion secondary battery, a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. When a signal is received by the antenna, an image, information, and the like can be displayed on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, electric power, radioactive rays, flow rate, humidity, a gradient, oscillation, odor, or infrared rays).

The electronic device of one embodiment of the present invention can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Furthermore, an electronic device including a plurality of display portions can have a function of displaying image information mainly on one display portion while displaying text information mainly on another display portion, a function of displaying a three-dimensional image by displaying images on a plurality of display portions with a parallax taken into account, or the like. Furthermore, an electronic device including an image receiving portion can have a function of taking a still image or a moving image, a function of automatically or manually correcting a taken image, a function of storing a taken image in a recording medium (an external recording medium or a recording medium incorporated in the electronic device), a function of displaying a taken image on a display portion, or the like. Note that functions of the electronic device of one embodiment of the present invention are not limited thereto, and the electronic devices can have a variety of functions.

The semiconductor device of one embodiment of the present invention can display high-resolution images. Thus, the light-emitting apparatus of one embodiment of the present invention can be suitably used especially for a portable electronic device, a wearable electronic device (wearable device), an e-book reader, and the like. In addition, the semiconductor device can be suitably used for xR devices such as a VR (Virtual Reality) device and an AR (Augmented Reality) device.

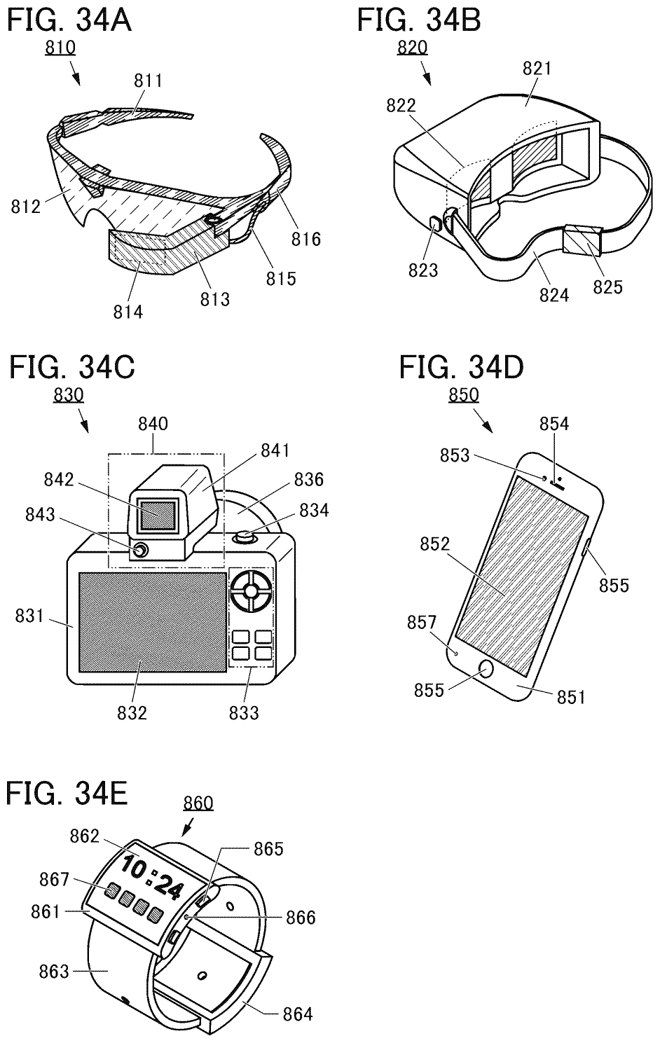

FIG. 34A illustrates an appearance of a head-mounted display 810. The head-mounted display 810 includes a mounting portion 811, a lens 812, a main body 813, a display portion 814, a cable 815, and the like. A battery 816 is incorporated in the mounting portion 811. The semiconductor device of one embodiment of the present invention can be used in the display portion 814.

The cable 815 supplies electric power from the battery 816 to the main body 813. The main body 813 includes a wireless receiver or the like and can display received image information, such as image data, on the display portion 814. The movement of the eyeball and/or the eyelid of a user is captured by a camera provided in the main body 813 and then the sight line of the user are calculated using the information to utilize the sight line of the user as an input means.

A plurality of electrodes may be provided in the mounting portion 811 at positions in contact with the user. The main body 813 may have a function of recognizing the user's sight line by sensing current flowing through the electrodes in accordance with the movement of the user's eyeball. The main body 813 may have a function of sensing current flowing through the electrodes to monitor the user's pulse. The mounting portion 811 may include various sensors such as a temperature sensor, a pressure sensor, and an acceleration sensor and may have a function of displaying the user's biological information on the display portion 814. The main body 813 may sense the movement of the user's head or the like to change an image displayed on the display portion 814 in synchronization with the movement.

FIG. 34B illustrates an appearance of a head-mounted display 820. The head-mounted display 820 is a goggles-type information processing device.

The head-mounted display 820 includes a housing 821, an operation button 823, a fixing band 824, and two display portions 822. Since the head-mounted display 820 includes the two display portions 822, the user's eyes can see their respective display portions. This allows a high-definition image to be displayed even when three-dimensional display using parallax or the like is performed. A battery 825 is provided for the fixing band 824. The battery 825 may be provided in the housing 821. However, the battery is preferably provided for the fixing band 824, whereby the center of gravity of the head-mounted display 820 is placed in the rear part and thus the user's feeling of wearing is enhanced. Note that besides the battery 825 a driver circuit or the like for driving the display portion 822 may be provided for the fixing band 824 so that the center of gravity of the head-mounted display 820 can be adjusted.

The operation button 823 has a function of a power button or the like. A button other than the operation button 823 may be included.

The semiconductor device of one embodiment of the present invention can be used in the display portion 822. The semiconductor device of one embodiment of the present invention has an extremely high resolution; thus, the pixels are less likely to be perceived by a user and a more realistic image can be displayed.

FIG. 34C illustrates an appearance of a camera 830 equipped with a finder 840.

The camera 830 includes a housing 831, a display portion 832, operation buttons 833, a shutter button 834, and the like. Furthermore, a detachable lens 836 is attached to the camera 830.

Although the lens 836 of the camera 830 here is detachable from the housing 831 for replacement, the lens 836 may be integrated with the housing.

The camera 830 can take images at the press of the shutter button 834. In addition, the display portion 832 has a function of a touch panel, and images can also be taken by the touch on the display portion 832.

The housing 831 of the camera 830 includes a mount including an electrode, so that the finder 840, a stroboscope, or the like can be connected to the housing.

The finder 840 includes a housing 841, a display portion 842, a button 843, and the like.

The housing 841 includes a mount for engagement with the mount of the camera 830 so that the finder 840 can be attached to the camera 830. The mount includes an electrode, and an image or the like received from the camera 830 through the electrode can be displayed on the display portion 842.

The button 843 functions as a power button. The on/off state of the display portion 842 can be switched with the button 843.

The semiconductor device of one embodiment of the present invention can be used in the display portion 832 of the camera 830 and the display portion 842 of the finder 840.

Although the camera 830 and the finder 840 are separate and detachable electronic devices in FIG. 34C, a finder including the semiconductor device of one embodiment of the present invention may be built into the housing 831 of the camera 830.

An information terminal 850 illustrated in FIG. 34D includes a housing 851, a display portion 852, a microphone 857, a speaker portion 854, a camera 853, an operation switch 855, and the like. The semiconductor device of one embodiment of the present invention can be used in the display portion 852. The display portion 852 functions as a touch panel. The information terminal 850 also includes an antenna, a battery, and the like inside the housing 851. The information terminal 850 can be used as, for example, a smartphone, a mobile phone, a tablet information terminal, a tablet personal computer, an e-book reader, or the like.

FIG. 34E illustrates an example of a watch-type information terminal. An information terminal 860 includes a housing 861, a display portion 862, a band 863, a buckle 864, an operation switch 865, an input/output terminal 866, and the like. In addition, the information terminal 860 includes an antenna, a battery, and the like inside the housing 861. The information terminal 860 is capable of executing a variety of applications such as mobile phone calls, e-mailing, viewing and editing texts, music reproduction, Internet communication, and a computer game.

In addition, the display portion 862 includes a touch sensor, and operation can be performed by touching the screen with a finger, a stylus, or the like. For example, with a touch on an icon 867 displayed on the display portion 862, an application can be started. The operation switches 865 can have a variety of functions such as time setting, power on/off operation, on/off operation of wireless communication, setting and cancellation of a silent mode, and setting and cancellation of a power saving mode. For example, the functions of the operation switches 865 can be set by the operation system incorporated in the information terminal 860.

The information terminal 860 can execute near field communication conformable to a communication standard. For example, mutual communication between the information terminal 860 and a headset capable of wireless communication enables hands-free calling. The information terminal 860 includes an input/output terminal 866, and can perform data transmission and reception with another information terminal through the input/output terminal 866. In addition, charging can be performed via the input/output terminal 866. Note that the charging operation may be performed by wireless power feeding without using the input/output terminal 866.

The structures described in this embodiment can be used in an appropriate combination with any of the structures described in the other embodiments and the like.

### REFERENCE NUMERALS

10: layer, 11: storage unit, 12: memory cell, 15: memory cell group, 19: terminal portion, 20: layer, 21: CPU, 22: GPU, 23: display portion driver circuit, 24: storage unit driver circuit, 25: super-resolution circuit, 26: sensor circuit, 27: communication circuit, 28: input/output circuit, 29: terminal portion, 30: layer, 31: display portion, 32: memory chip, 35: subpanel, 38: wire, 39: terminal portion, 40: sealing substrate, 42: cutout portion, 51: pixel circuit, 53: capacitor, 55: conductor, 60: layer, 61: light-emitting element, 71: control circuit, 72: timing controller, 73: serial-parallel conversion circuit, 74: latch circuit, 75: DAC, 76: amplifier circuit, 90: functional circuit

1. A semiconductor device comprising:
a first layer;
a second layer over the first layer; and
a third layer over the second layer,
wherein the first layer comprises a circuit including a first transistor,
wherein the second layer comprises pixel circuits each including a second transistor,
wherein the third layer comprises light-emitting elements,
wherein one of the pixel circuits is electrically connected to one of the light-emitting elements,
wherein the circuit is configured to control an operation of the pixel circuits, and
wherein the one of the pixel circuits is configured to control emission luminance of the one of the light-emitting elements.

2. The semiconductor device according to claim 1,
wherein the first transistor is a Si transistor, and
wherein the second transistor is a Si transistor.

3. The semiconductor device according to claim 2, comprising a region wherein the first layer and the second layer include regions that are connected to each other by Cu—Cu bonding.

4. The semiconductor device according to claim 1,
wherein the first transistor is a Si transistor, and
wherein the second transistor is an OS transistor.

5. The semiconductor device according to claim 1,
wherein the circuit comprises at least one of a CPU, a GPU, a super-resolution circuit, a sensor circuit, a communication circuit, and an input/output circuit.

6. The semiconductor device according to claim 1,
wherein each of the light-emitting elements is an organic EL element.

7. The semiconductor device according to claim 6,
wherein each of the light-emitting elements comprises a tandem structure.

8. The semiconductor device according to claim 1,
wherein in a region including the pixel circuits and the light-emitting elements, a diagonal size of the region is greater than or equal to 0.5 inches and less than or equal to 2.0 inches.

9. A semiconductor device comprising:
a first layer;
a second layer over the first layer; and
a first member over the second layer,
wherein the first layer comprises a circuit,
wherein the second layer comprises a display portion including pixels and storage units,
wherein each of the pixels comprises a pixel circuit and a light-emitting element over the pixel circuit,
wherein the storage units are arranged along at least part of an outer periphery of the display portion, and
wherein the display portion and the storage units are covered with the first member.

10. The semiconductor device according to claim 9,
wherein the storage units are arranged in a sealing region.

11. The semiconductor device according to claim 9,
wherein a diagonal size of the display portion is greater than or equal to 0.5 inches and less than or equal to 2.0 inches.

12. The semiconductor device according to claim 9,
wherein each of the storage units comprises a DRAM.

13. The semiconductor device according to claim 9,
wherein the light-emitting element is an organic EL element.

14. The semiconductor device according to claim 9,
wherein the light-emitting element comprises a tandem structure.

15. The semiconductor device according to claim 9,
wherein the first member comprises a light-transmitting property.

16. A semiconductor device comprising:
a first layer;
a second layer over the first layer; and
a third layer over the second layer,
wherein the first layer comprises a storage unit including memory cells,
wherein the second layer comprises a circuit,
wherein the third layer comprises a display portion including pixels,
wherein the circuit comprises a storage unit driver circuit and a display portion driver circuit, and
wherein each of the pixels comprises a pixel circuit and a light-emitting element over the pixel circuit.

17. The semiconductor device according to claim 16,
wherein each of the memory cells comprises a first transistor,
wherein the circuit comprises a second transistor,
wherein the pixel circuit comprises a third transistor, and
wherein a composition of a first semiconductor layer included in the first transistor and a composition of a second semiconductor layer included in the second transistor are different from a composition of a third semiconductor layer included in the third transistor.

18. The semiconductor device according to claim 16,
wherein the storage unit comprises a DRAM.

19. The semiconductor device according to claim 16,
wherein the light-emitting element is an organic EL element.

20. The semiconductor device according to claim 19,
wherein the light-emitting element comprises a tandem structure.
